(19) United States
(12) Patent Application Publication
(10) Pub. No.: US 2025/0127052 A1
(43) Pub. Date: Apr. 17, 2025

(54) BORON COMPOUND AND ORGANIC LIGHT-EMITTING DEVICE INCLUDING SAME

(71) Applicant: UNIVERSITY-INDUSTRY COOPERATION GROUP OF KYUNG HEE UNIVERSITY, Yongin-si, Gyeonggi-do (KR)

(72) Inventors: Jang Hyuk KWON, Seongnam-si (KR); Ju Young LEE, Suwon-si (KR); Rayappa Naveen KENKERA, Seoul (KR); Braveenth RAMANASKANDA, Seoul (KR); Soon Jae HWANG, Seoul (KR)

(73) Assignee: UNIVERSITY-INDUSTRY COOPERATION GROUP OF KYUNG HEE UNIVERSITY, Yongin-si, Gyeonggi-do (KR)

(21) Appl. No.: 18/035,854

(22) PCT Filed: Oct. 20, 2021
(86) PCT No.: PCT/KR2021/014660

§ 371 Date: May 8, 2023

(30) Foreign Application Priority Data
Nov. 9, 2020 (KR) 10-2020-0148459

(51) Int. Cl. H10K 85/60; C07F 5/02; C09K 11/02; C09K 11/06; H10K 50/12; H10K 101/20; H10K 101/30

(52) U.S. Cl. CPC H10K 85/658; C07F 5/027; C09K 11/02; C09K 11/06; C09K 2211/1007; C09K 2211/1014; C09K 2211/1022; H10K 50/12; H10K 2101/20; H10K 2101/30

(57) ABSTRACT

The present specification relates to a boron compound represented by chemical formula 1 and an organic light-emitting device including the same, wherein the compound has an emission spectrum with a narrow full width at half maximum, compared to a delayed fluorescence material of the prior art, and excellent internal quantum efficiency, and thus has high color purity and high efficiency characteristics.

### TECHNICAL FIELD

The present invention relates to a compound and an organic light-emitting device including the same, and more specifically, to a compound having excellent color characteristics or a compound having excellent color characteristics while exhibiting thermally activated delayed fluorescence (TADF) characteristics, and an organic light-emitting device including the same.

### BACKGROUND ART

Organic luminescence refers to a phenomenon in which electrical energy is converted into light energy using organic materials. An organic light-emitting device (OLED) is manufactured by interposing an organic material between an anode and a cathode using such organic luminescence, and has a characteristic of emitting light when electrical energy is applied. An organic light-emitting device includes multiple organic layers to improve efficiency and stability, and generally includes a hole injection layer (HIL), a hole transport layer (HTL), a light-emitting layer, and an electron transport layer (ETL) and an electron injection layer (EIL).

Materials used in organic layers may be classified into light-emitting materials and charge transfer materials according to their functions, and the light-emitting materials may be classified into fluorescent materials using a fluorescence phenomenon derived from a singlet excited state of electrons and phosphorescent materials using a phosphorescence phenomenon derived from a triplet excited state of electrons according to a light-emitting mechanism. In addition, the light-emitting material may be divided into blue, green, and red light-emitting materials according to the light-emitting color, and phosphorescent materials of all colors except for blue have been developed and used in the industry. However, in the case of blue materials, only fluorescent materials are used due to limitations in lifetime and color properties, and a blue phosphorescent material using a triplet using a heavy metal such as iridium or platinum, and a delayed fluorescence material using a triplet only as pure organic materials by making the energy difference between a singlet and triplet small are being developed. When a phosphorescent material using heavy metals is used, although high efficiency can be achieved, but due to the heavy metal for realizing phosphorescence, there is a limitation in that charges transfer between a metal and an organic material to emit light, and a full width at half maximum is wide.

Therefore, interest in materials with a narrow full width at half maximum is increasing, and research is underway on various color gamuts such as blue, green, yellow, orange, red and the like.

### Technical Problem

The present invention is to solve the problems of the related art, one object of the description is to provide a compound with excellent color purity.

Another object of the present invention is to provide an organic light-emitting device including a compound having excellent color purity.

Still another object of the present invention is to provide a delayed fluorescence or phosphorescence photosensitive hyperfluorescent device using a compound having high efficiency and excellent color purity.

### Technical Solution

An aspect of the present invention provides a boron compound represented by the following Formula 1.

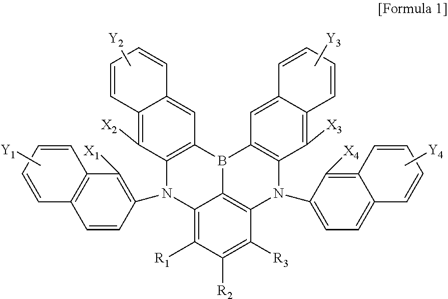

In Formula 1,
Y₁ to Y₄ each independently represent hydrogen, deuterium, a nitrile group, a substituted or unsubstituted alkyl group, a substituted or unsubstituted cycloalkyl group, a substituted or unsubstituted alkoxy group, a substituted or unsubstituted silyl group, a substituted or unsubstituted amine group, a substituted or unsubstituted aryl group, a substituted or unsubstituted heteroaryl group, a substituted or unsubstituted diarylamino group, a substituted or unsubstituted diheteroarylamino group, or a substituted or unsubstituted arylheteroarylamino group;
X₁ to X₄ each independently represent hydrogen or are mutually bonded to form a ring;
R₁ to R₃ each independently represent hydrogen, deuterium, a nitrile group, a halogen group, a substituted or unsubstituted alkyl group, a substituted or unsubstituted cycloalkyl group, a substituted or unsubstituted alkoxy group, a substituted or unsubstituted silyl group, a substituted or unsubstituted amine group, a substituted or unsubstituted aryl group, a substituted or unsubstituted heteroaryl group, a substituted or unsubstituted diarylamino group, a substituted or unsubstituted diheteroarylamino group, or a substituted or unsubstituted arylheteroarylamino group, or a ring structure formed by mutually bonding R₁ and R₂ or R₂ and R₃.

In an embodiment, at least one of R₁ to R₃ is represented by one of the following Formulas 2 to 3.

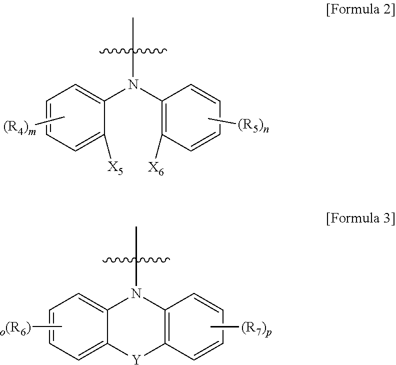

In Formula 2 or 3,
X₅ to X₆ each independently represent hydrogen or are mutually bonded to form a ring;
R₄ to R₇ each independently represent hydrogen, deuterium, a nitrile group, a halogen group, a substituted or unsubstituted aromatic ring, a substituted or unsubstituted alkyl group, a substituted or unsubstituted cycloalkyl group, a substituted or unsubstituted alkoxy group, a substituted or unsubstituted silyl group, a substituted or unsubstituted amine group, a substituted or unsubstituted aryl group, a substituted or unsubstituted heteroaryl group, a substituted or unsubstituted diarylamino group, a substituted or unsubstituted diheteroarylamino group, or a substituted or unsubstituted arylheteroarylamino group;
Y is sulfur, oxygen, carbon to which one or more alkyl or aryl groups are bonded;
m, n, o and p each independently represent an integer of 0 to 4.

In an embodiment, the compound may be represented by one of the following Formulas 1-1 to 1-132.

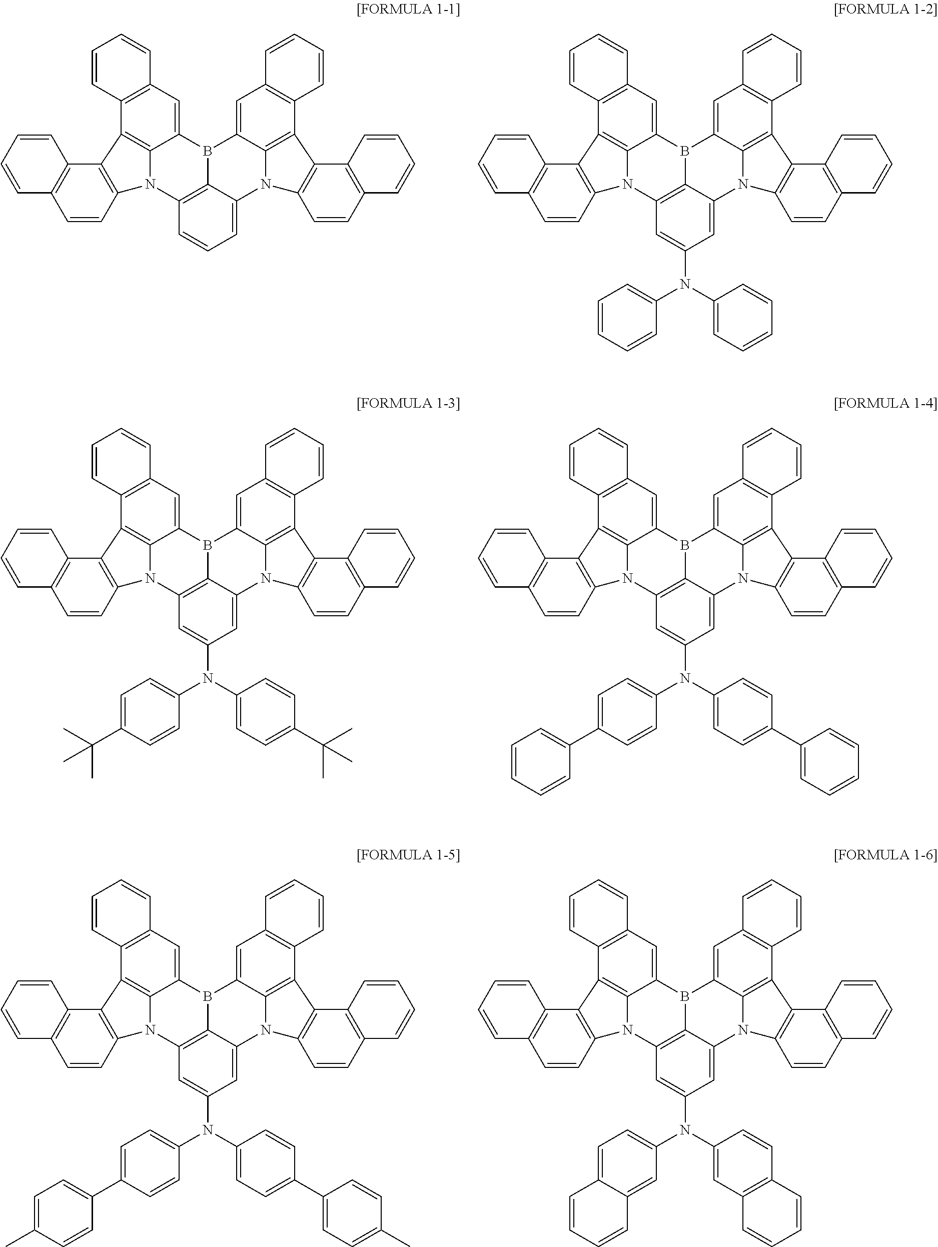

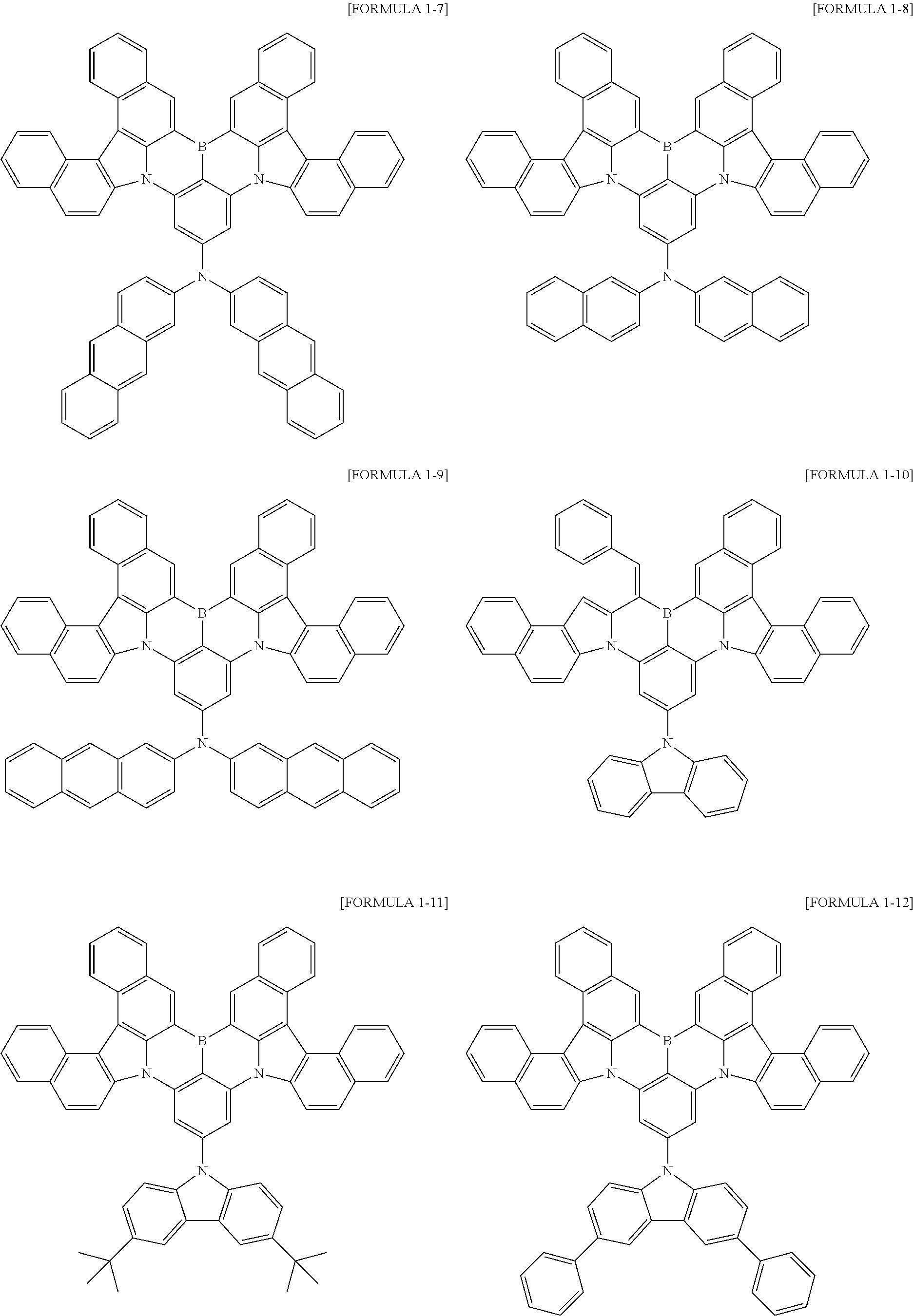

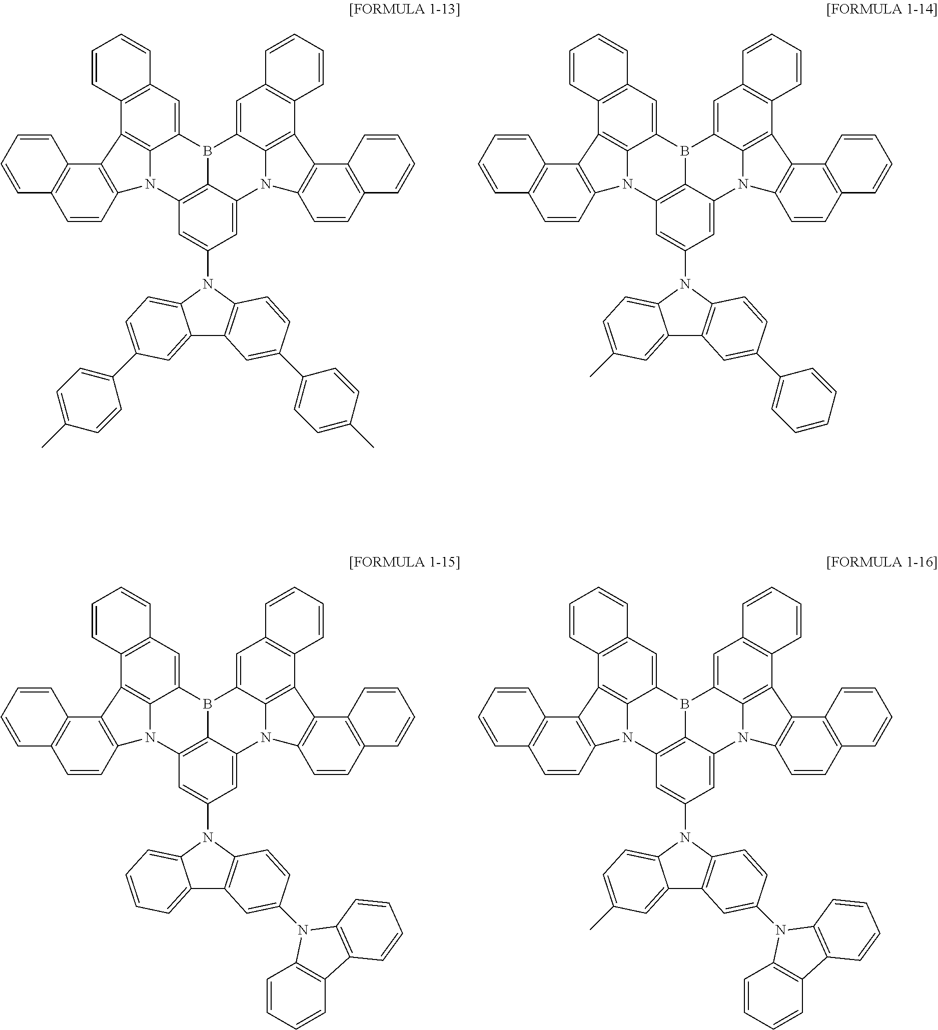

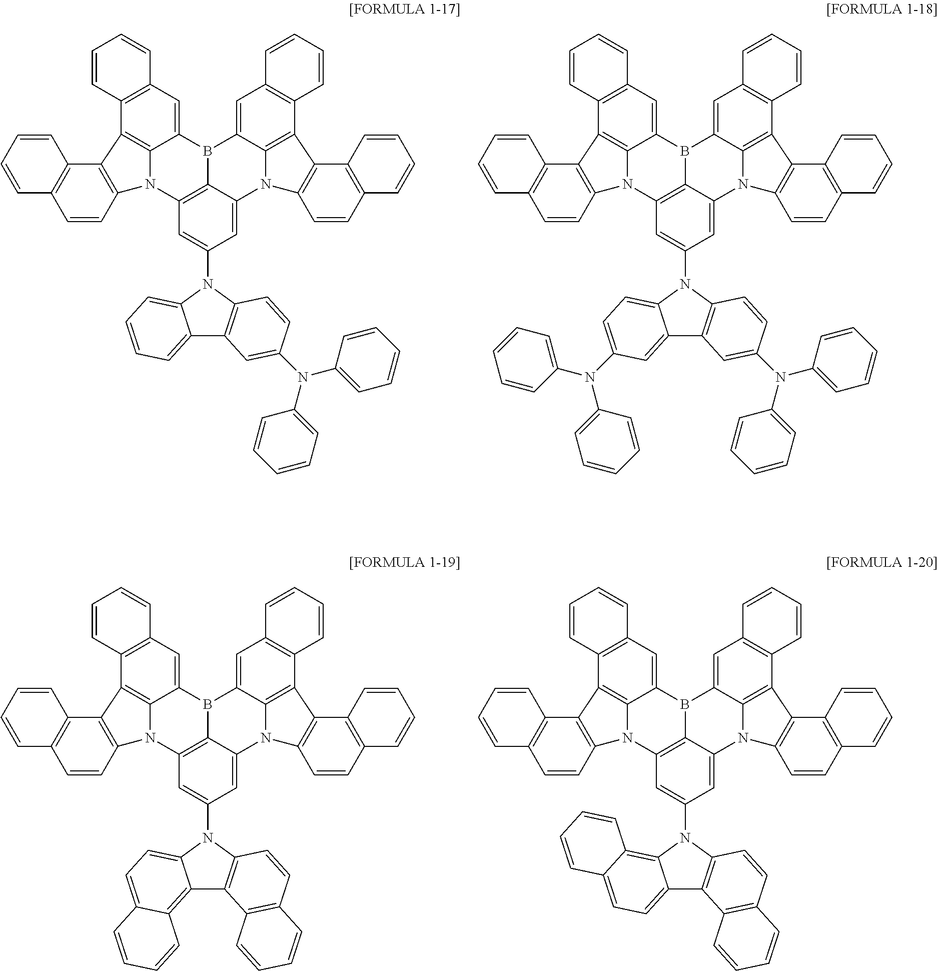

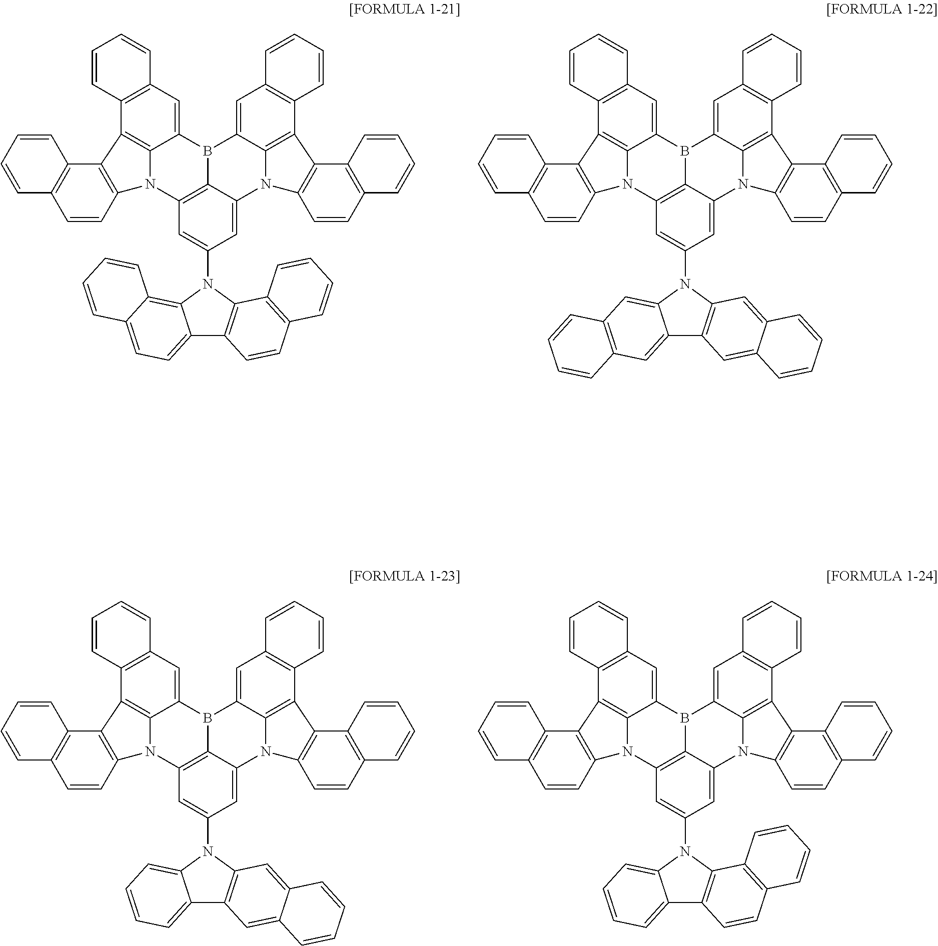 [SMILES: c1ccc2c(c1)ccc1c2c2c3ccccc3cc3c2n1-c1cc(-n2c4c5ccccc5ccc4c4ccc5ccccc5c42)cc2c1B3c1cc3ccccc3c3c4c5ccccc5ccc4n-2c13 ; c1ccc2cc3c(cc2c1)c1cc2ccccc2cc1n3-c1cc2c3c(c1)-n1c4ccc5ccccc5c4c4c5ccccc5cc(c41)B3c1cc3ccccc3c3c4c5ccccc5ccc4n-2c13 ; c1ccc2cc3c(cc2c1)c1ccccc1n3-c1cc2c3c(c1)-n1c4ccc5ccccc5c4c4c5ccccc5cc(c41)B3c1cc3ccccc3c3c4c5ccccc5ccc4n-2c13 ; c1ccc2c(c1)ccc1c2c2c3ccccc3cc3c2n1-c1cc(-n2c4ccccc4c4ccc5ccccc5c42)cc2c1B3c1cc3ccccc3c3c4c5ccccc5ccc4n-2c13]

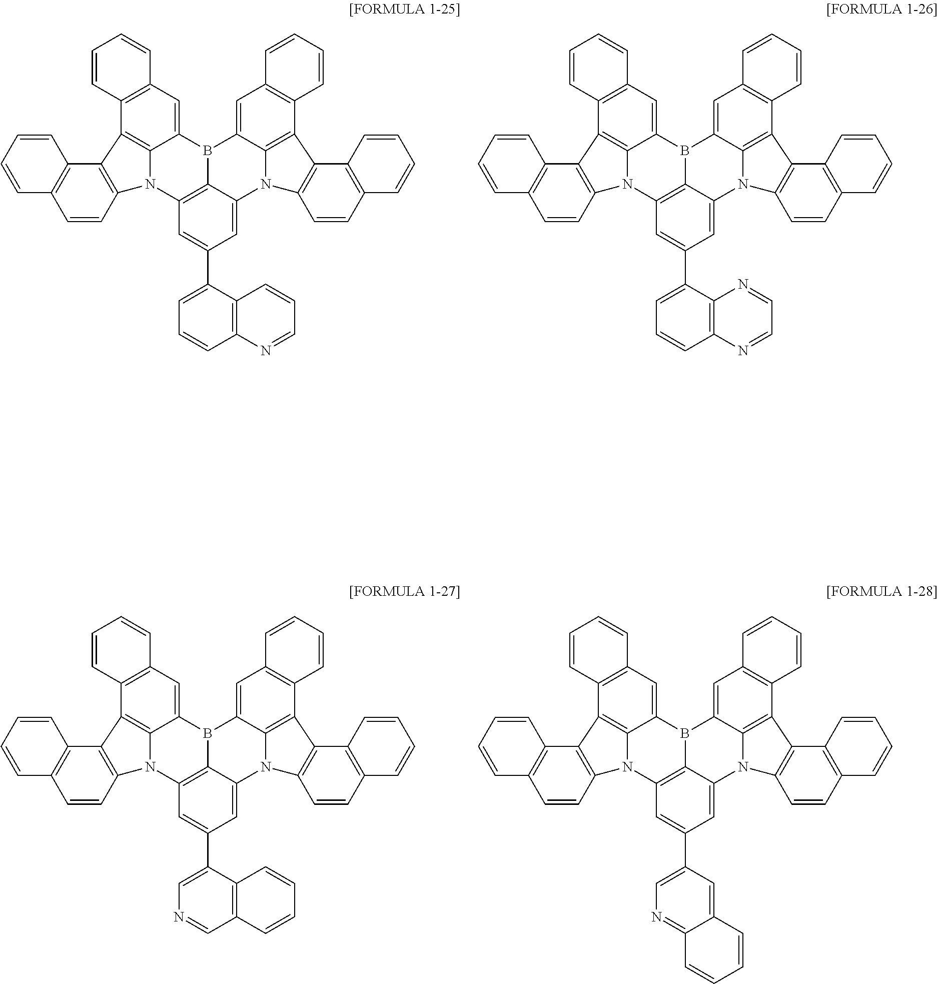 [SMILES: c1ccc2c(c1)ccc1c2c2c3ccccc3cc3c2n1-c1cc(-c2cccc4ncccc24)cc2c1B3c1cc3ccccc3c3c4c5ccccc5ccc4n-2c13 ; c1ccc2c(c1)ccc1c2c2c3ccccc3cc3c2n1-c1cc(-c2cccc4nccnc24)cc2c1B3c1cc3ccccc3c3c4c5ccccc5ccc4n-2c13 ; c1ccc2c(-c3cc4c5c(c3)-n3c6ccc7ccccc7c6c6c7ccccc7cc(c63)B5c3cc5ccccc5c5c6c7ccccc7ccc6n-4c35)cncc2c1 ; c1ccc2ncc(-c3cc4c5c(c3)-n3c6ccc7ccccc7c6c6c7ccccc7cc(c63)B5c3cc5ccccc5c5c6c7ccccc7ccc6n-4c35)cc2c1]

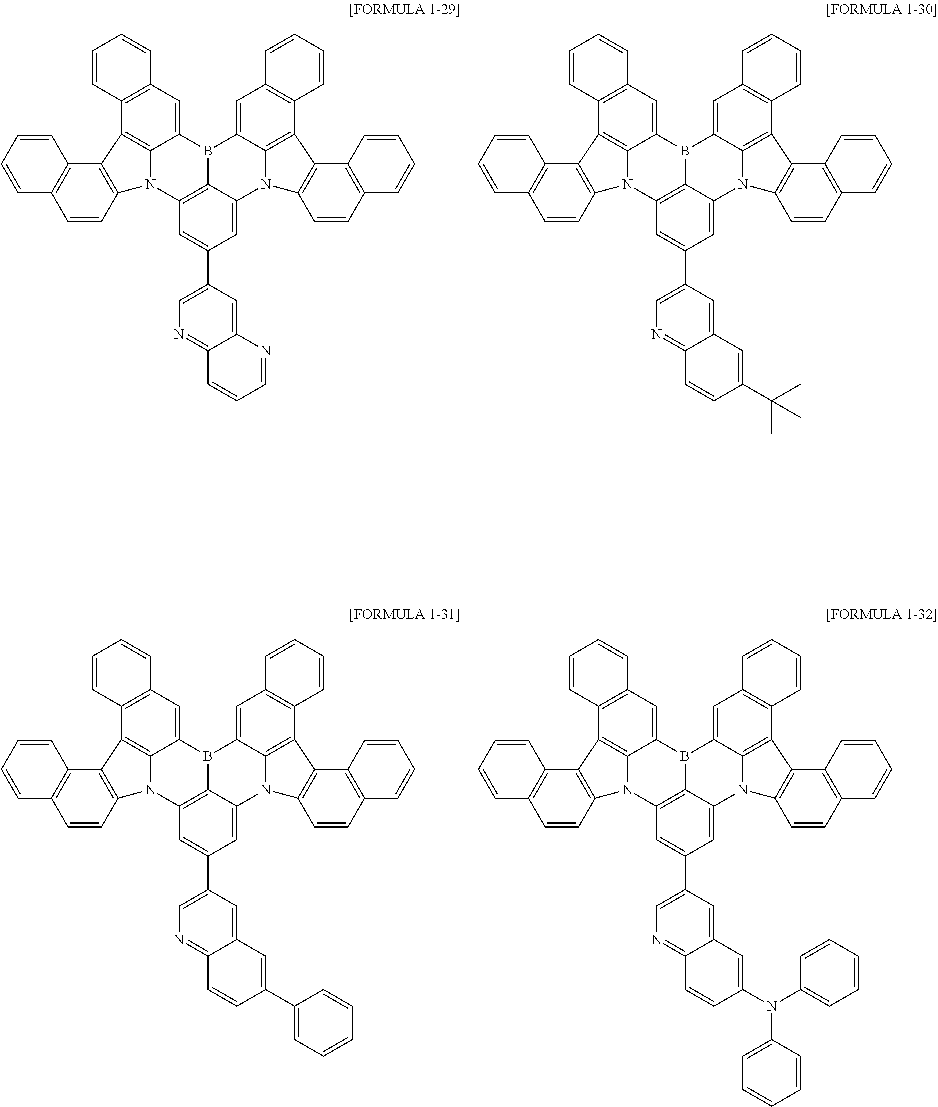 [SMILES: c1ccc2c(c1)ccc1c2c2c3ccccc3cc3c2n1-c1cc(-c2cnc4cccnc4c2)cc2c1B3c1cc3ccccc3c3c4c5ccccc5ccc4n-2c13 ; CC(C)(C)c1ccc2ncc(-c3cc4c5c(c3)-n3c6ccc7ccccc7c6c6c7ccccc7cc(c63)B5c3cc5ccccc5c5c6c7ccccc7ccc6n-4c35)cc2c1 ; c1ccc(-c2ccc3ncc(-c4cc5c6c(c4)-n4c7ccc8ccccc8c7c7c8ccccc8cc(c74)B6c4cc6ccccc6c6c7c8ccccc8ccc7n-5c46)cc3c2)cc1 ; c1ccc(N(c2ccccc2)c2ccc3ncc(-c4cc5c6c(c4)-n4c7ccc8ccccc8c7c7c8ccccc8cc(c74)B6c4cc6ccccc6c6c7c8ccccc8ccc7n-5c46)cc3c2)cc1]

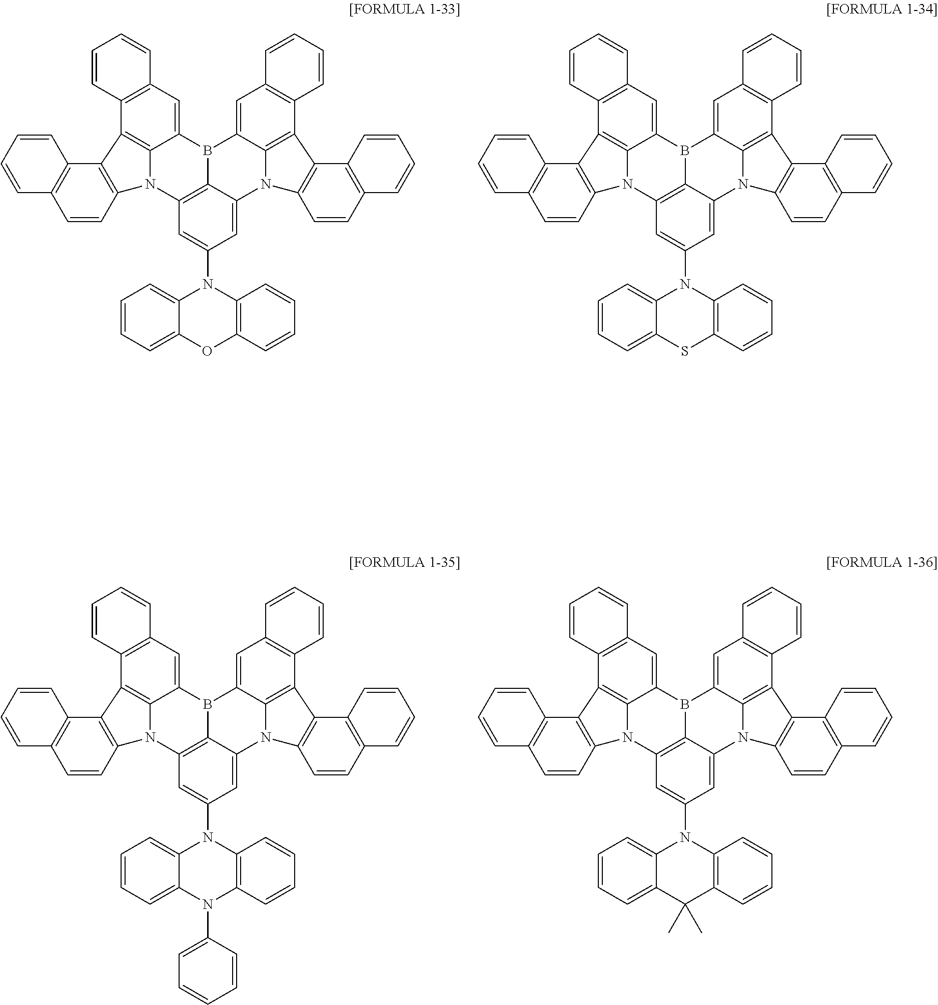 [SMILES: c1ccc2c(c1)Oc1ccccc1N2c1cc2c3c(c1)-n1c4ccc5ccccc5c4c4c5ccccc5cc(c41)B3c1cc3ccccc3c3c4c5ccccc5ccc4n-2c13 ; c1ccc2c(c1)Sc1ccccc1N2c1cc2c3c(c1)-n1c4ccc5ccccc5c4c4c5ccccc5cc(c41)B3c1cc3ccccc3c3c4c5ccccc5ccc4n-2c13 ; c1ccc(N2c3ccccc3N(c3cc4c5c(c3)-n3c6ccc7ccccc7c6c6c7ccccc7cc(c63)B5c3cc5ccccc5c5c6c7ccccc7ccc6n-4c35)c3ccccc32)cc1 ; CC1(C)c2ccccc2N(c2cc3c4c(c2)-n2c5ccc6ccccc6c5c5c6ccccc6cc(c52)B4c2cc4ccccc4c4c5c6ccccc6ccc5n-3c24)c2ccccc21]

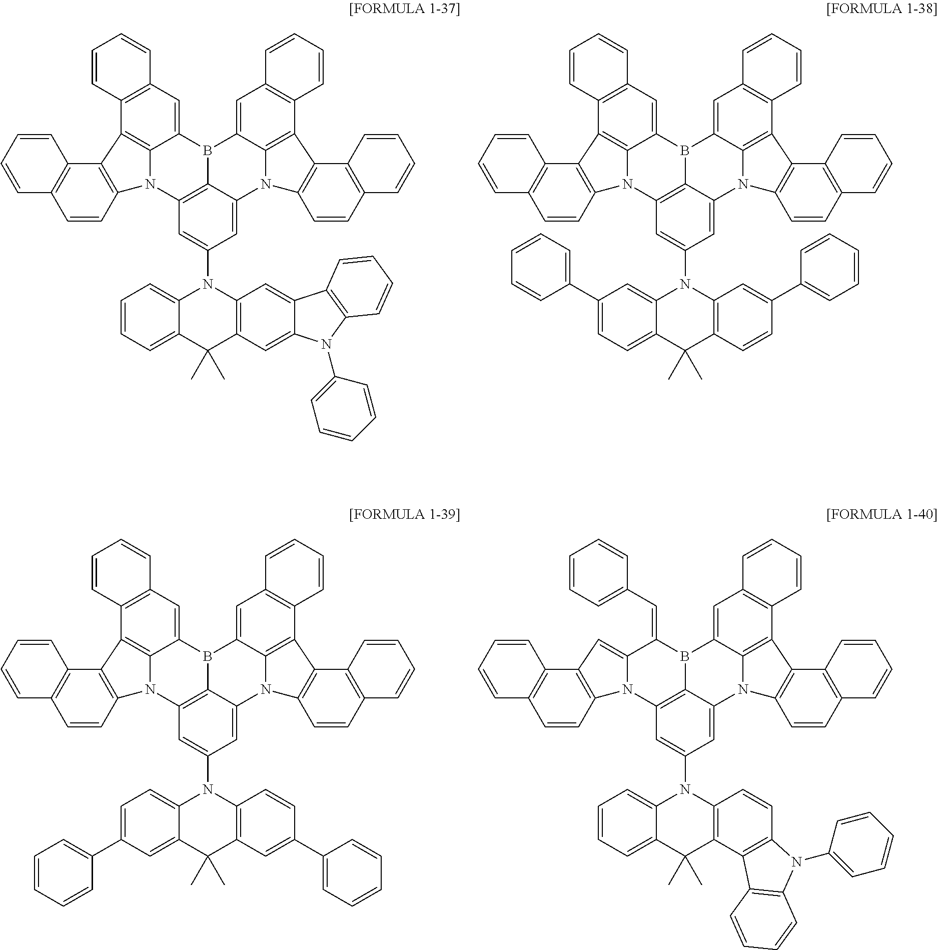

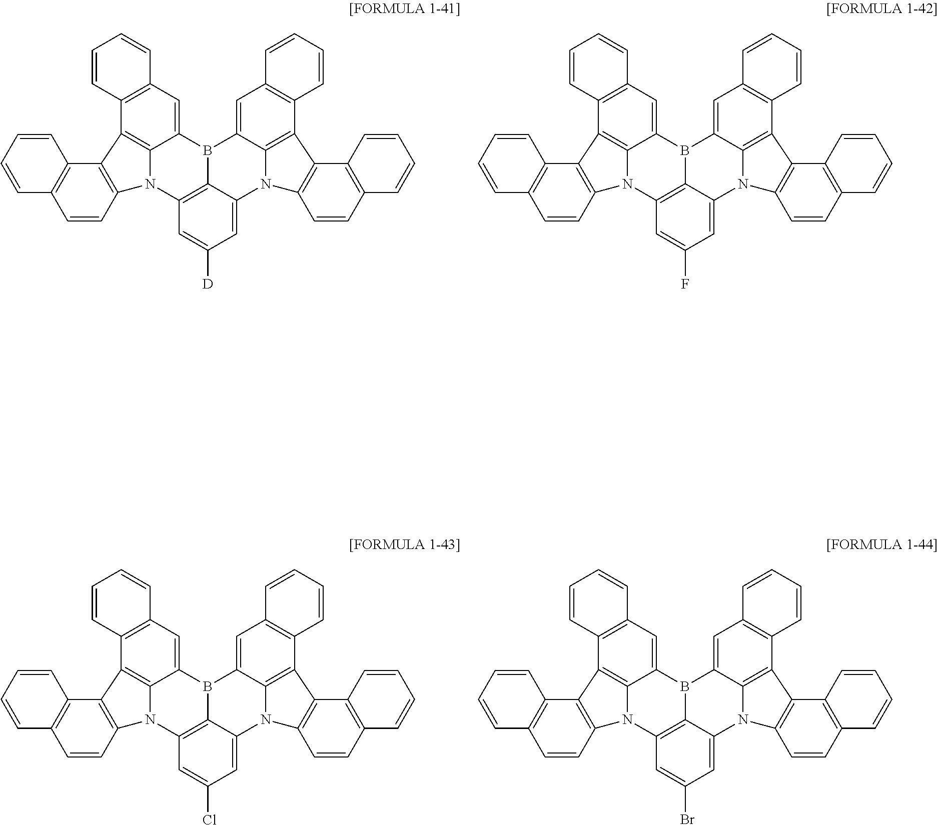 [SMILES: [2H]c1cc2c3c(c1)-n1c4ccc5ccccc5c4c4c5ccccc5cc(c41)B3c1cc3ccccc3c3c4c5ccccc5ccc4n-2c13 ; Fc1cc2c3c(c1)-n1c4ccc5ccccc5c4c4c5ccccc5cc(c41)B3c1cc3ccccc3c3c4c5ccccc5ccc4n-2c13 ; Clc1cc2c3c(c1)-n1c4ccc5ccccc5c4c4c5ccccc5cc(c41)B3c1cc3ccccc3c3c4c5ccccc5ccc4n-2c13 ; Brc1cc2c3c(c1)-n1c4ccc5ccccc5c4c4c5ccccc5cc(c41)B3c1cc3ccccc3c3c4c5ccccc5ccc4n-2c13]

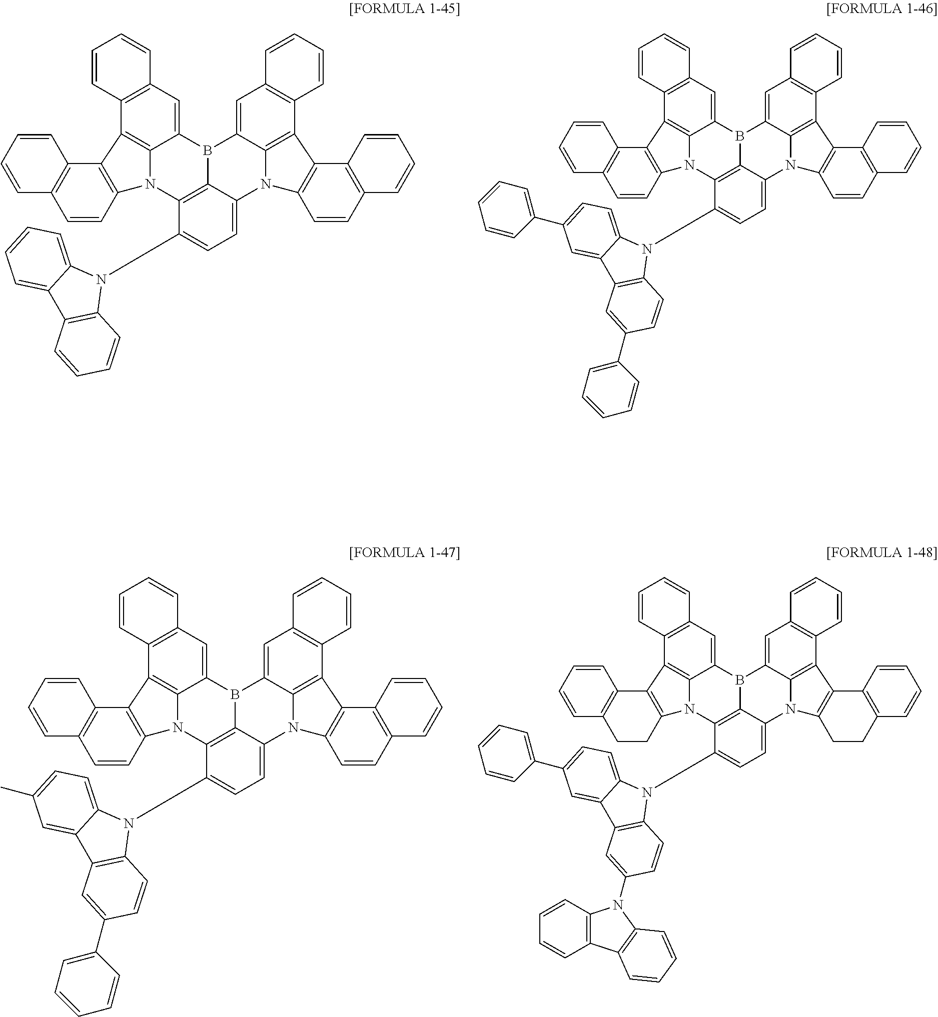 [SMILES: c1ccc2c(c1)ccc1c2c2c3ccccc3cc3c2n1-c1ccc(-n2c4ccccc4c4ccccc42)c2c1B3c1cc3ccccc3c3c4c5ccccc5ccc4n-2c13 ; c1ccc(-c2ccc3c(c2)c2cc(-c4ccccc4)ccc2n3-c2ccc3c4c2-n2c5ccc6ccccc6c5c5c6ccccc6cc(c52)B4c2cc4ccccc4c4c5c6ccccc6ccc5n-3c24)cc1 ; Cc1ccc2c(c1)c1cc(-c3ccccc3)ccc1n2-c1ccc2c3c1-n1c4ccc5ccccc5c4c4c5ccccc5cc(c41)B3c1cc3ccccc3c3c4c5ccccc5ccc4n-2c13 ; c1ccc(-c2ccc3c(c2)c2cc(-n4c5ccccc5c5ccccc54)ccc2n3-c2ccc3c4c2-n2c5c(c6c7ccccc7cc(c62)B4c2cc4ccccc4c4c6c(n-3c24)CCc2ccccc2-6)-c2ccccc2CC5)cc1]

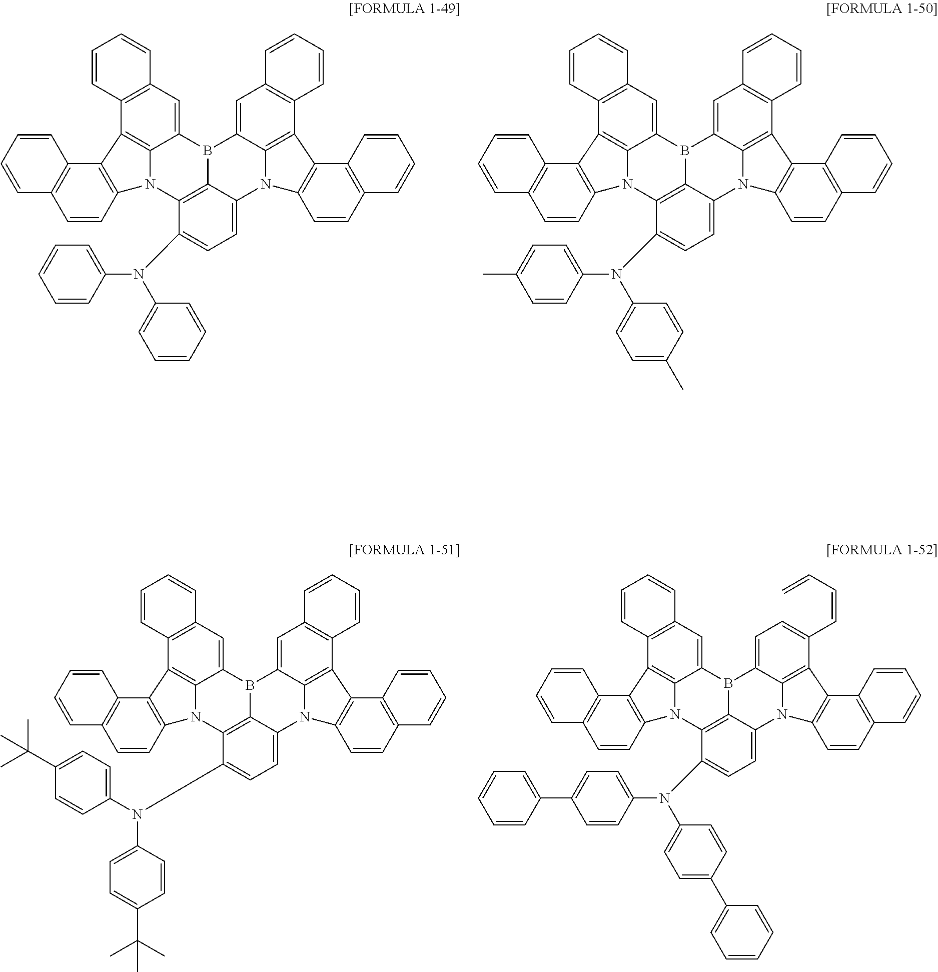 [SMILES: c1ccc(N(c2ccccc2)c2ccc3c4c2-n2c5ccc6ccccc6c5c5c6ccccc6cc(c52)B4c2cc4ccccc4c4c5c6ccccc6ccc5n-3c24)cc1 ; Cc1ccc(N(c2ccc(C)cc2)c2ccc3c4c2-n2c5ccc6ccccc6c5c5c6ccccc6cc(c52)B4c2cc4ccccc4c4c5c6ccccc6ccc5n-3c24)cc1 ; CC(C)(C)c1ccc(N(c2ccc(C(C)(C)C)cc2)c2ccc3c4c2-n2c5ccc6ccccc6c5c5c6ccccc6cc(c52)B4c2cc4ccccc4c4c5c6ccccc6ccc5n-3c24)cc1 ; C=C/C=C\c1ccc2c3c1c1c4ccccc4ccc1n3-c1ccc(N(c3ccc(-c4ccccc4)cc3)c3ccc(-c4ccccc4)cc3)c3c1B2c1cc2ccccc2c2c4c5ccccc5ccc4n-3c12]

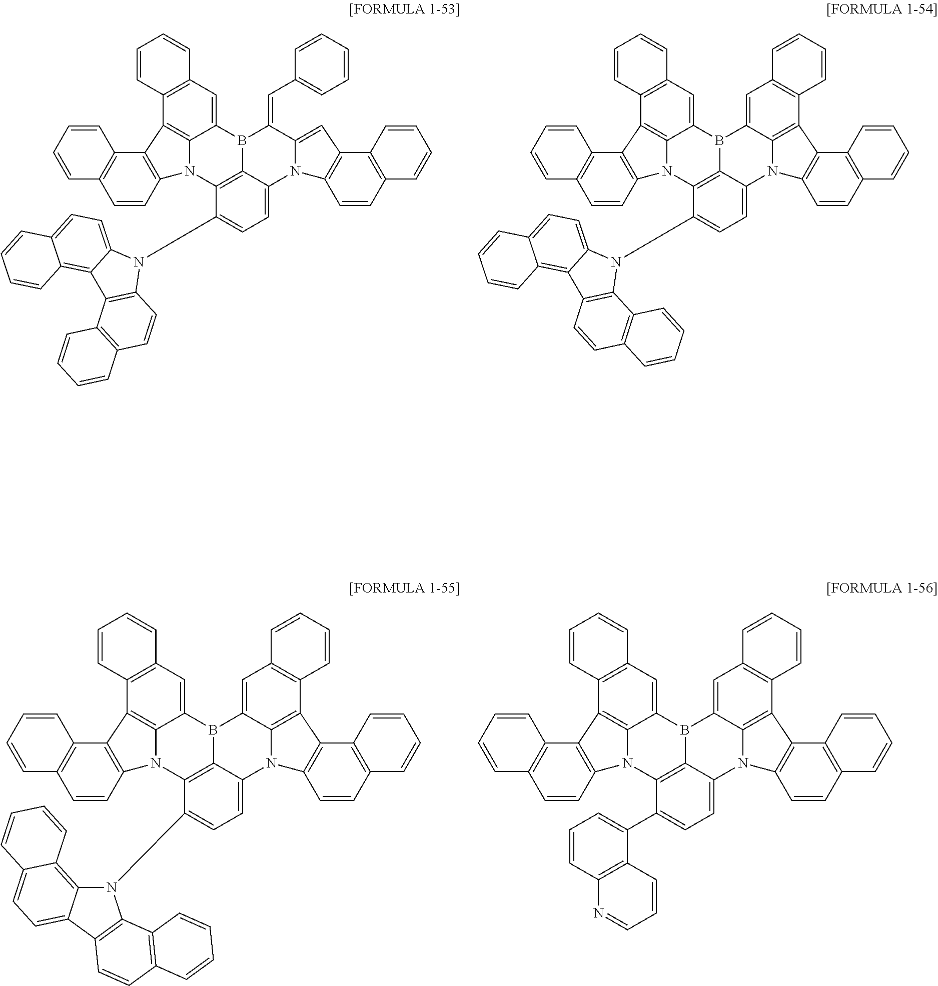 [SMILES: C(=C1\B2c3c(ccc(-n4c5ccc6ccccc6c5c5c6ccccc6ccc54)c3-n3c4ccc5ccccc5c4c4c5ccccc5cc2c43)-n2c1cc1c3ccccc3ccc12)/c1ccccc1 ; c1ccc2c(c1)ccc1c2c2c3ccccc3cc3c2n1-c1ccc(-n2c4ccc5ccccc5c4c4ccc5ccccc5c42)c2c1B3c1cc3ccccc3c3c4c5ccccc5ccc4n-2c13 ; c1ccc2c(c1)ccc1c2c2c3ccccc3cc3c2n1-c1ccc(-n2c4c5ccccc5ccc4c4ccc5ccccc5c42)c2c1B3c1cc3ccccc3c3c4c5ccccc5ccc4n-2c13 ; c1ccc2c(c1)ccc1c2c2c3ccccc3cc3c2n1-c1ccc(-c2cccc4ncccc24)c2c1B3c1cc3ccccc3c3c4c5ccccc5ccc4n-2c13]

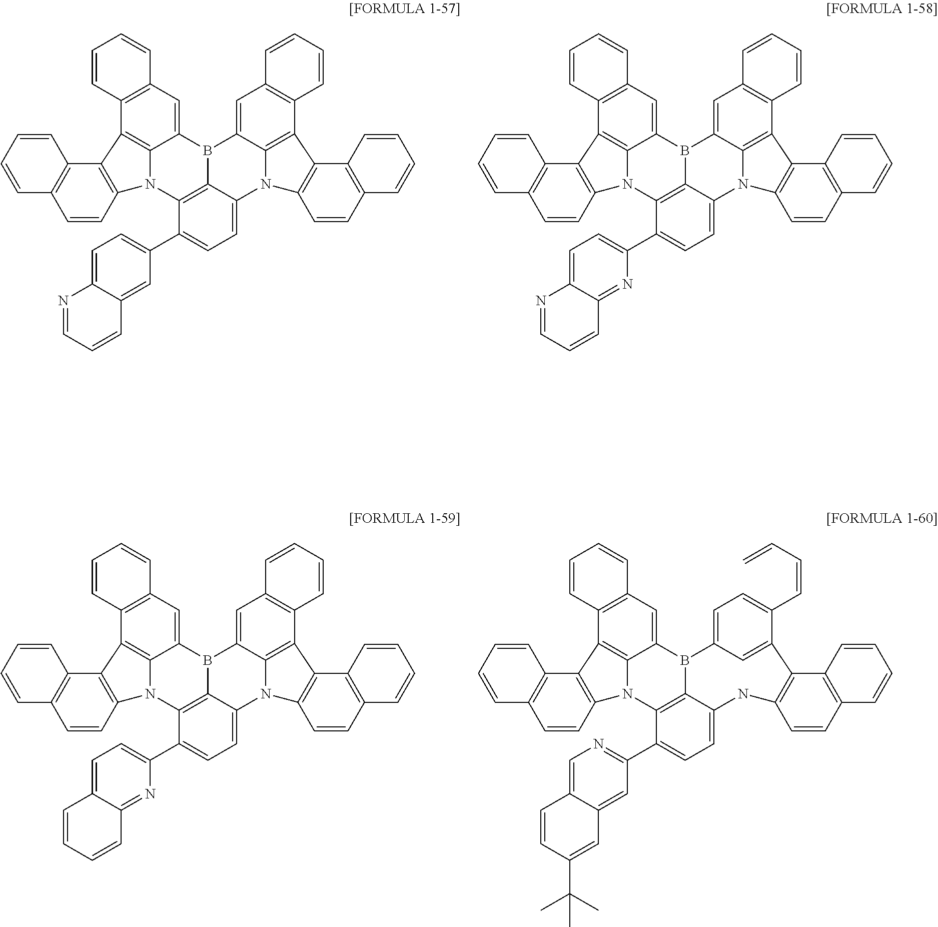 [SMILES: c1cnc2ccc(-c3ccc4c5c3-n3c6ccc7ccccc7c6c6c7ccccc7cc(c63)B5c3cc5ccccc5c5c6c7ccccc7ccc6n-4c35)cc2c1 ; c1ccc2c(c1)ccc1c2c2c3ccccc3cc3c2n1-c1ccc(-c2ccc4ncccc4n2)c2c1B3c1cc3ccccc3c3c4c5ccccc5ccc4n-2c13 ; c1ccc2nc(-c3ccc4c5c3-n3c6ccc7ccccc7c6c6c7ccccc7cc(c63)B5c3cc5ccccc5c5c6c7ccccc7ccc6n-4c35)ccc2c1 ; C=C/C=C\c1ccc2cc1-c1c(ccc3ccccc13)Nc1ccc(-c3cc4cc(C(C)(C)C)ccc4cn3)c3c1B2c1cc2ccccc2c2c4c5ccccc5ccc4n-3c12]

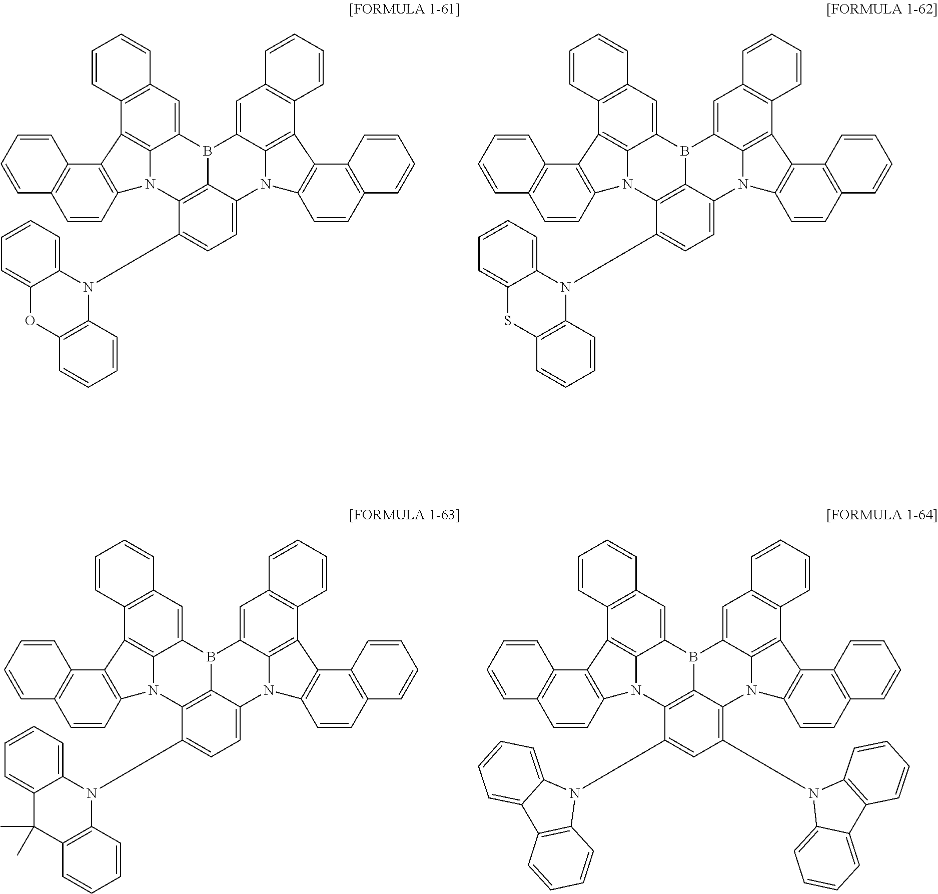 [SMILES: c1ccc2c(c1)Oc1ccccc1N2c1ccc2c3c1-n1c4ccc5ccccc5c4c4c5ccccc5cc(c41)B3c1cc3ccccc3c3c4c5ccccc5ccc4n-2c13 ; c1ccc2c(c1)Sc1ccccc1N2c1ccc2c3c1-n1c4ccc5ccccc5c4c4c5ccccc5cc(c41)B3c1cc3ccccc3c3c4c5ccccc5ccc4n-2c13 ; CC1(C)c2ccccc2N(c2ccc3c4c2-n2c5ccc6ccccc6c5c5c6ccccc6cc(c52)B4c2cc4ccccc4c4c5c6ccccc6ccc5n-3c24)c2ccccc21 ; c1ccc2c(c1)ccc1c2c2c3ccccc3cc3c2n1-c1c(-n2c4ccccc4c4ccccc42)cc(-n2c4ccccc4c4ccccc42)c2c1B3c1cc3ccccc3c3c4c5ccccc5ccc4n-2c13]

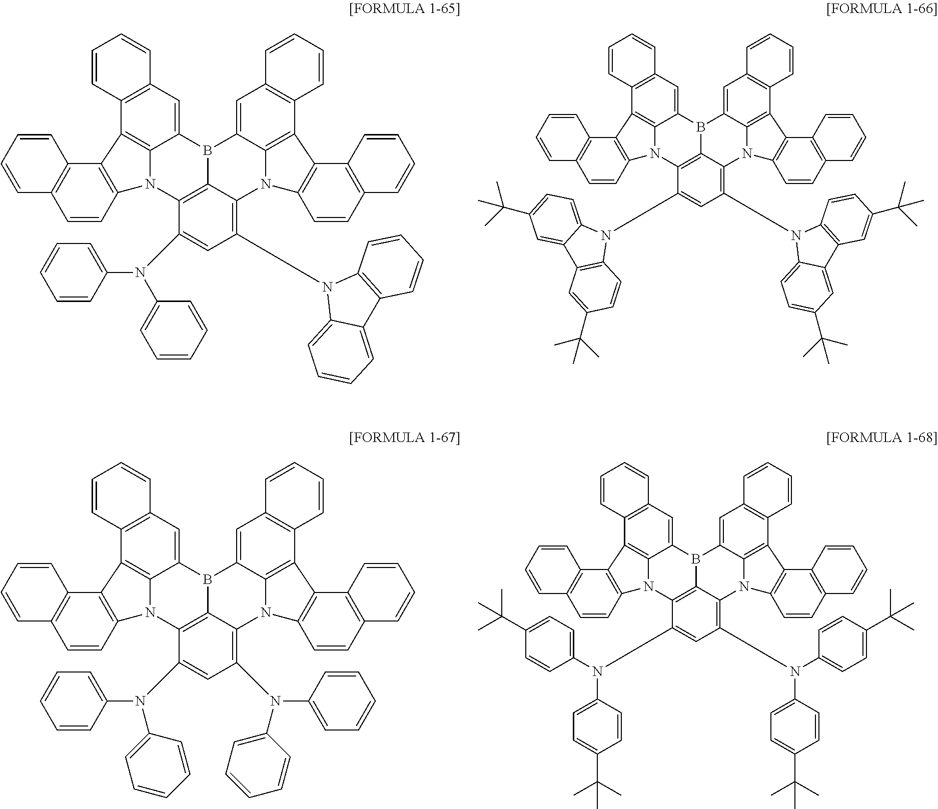

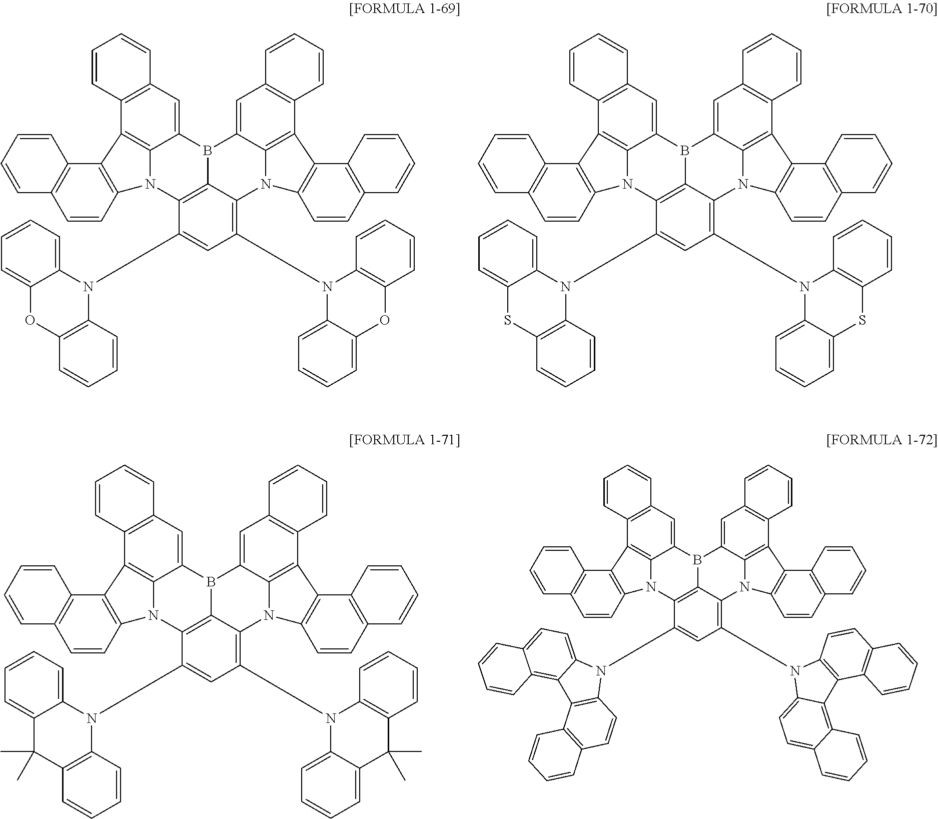

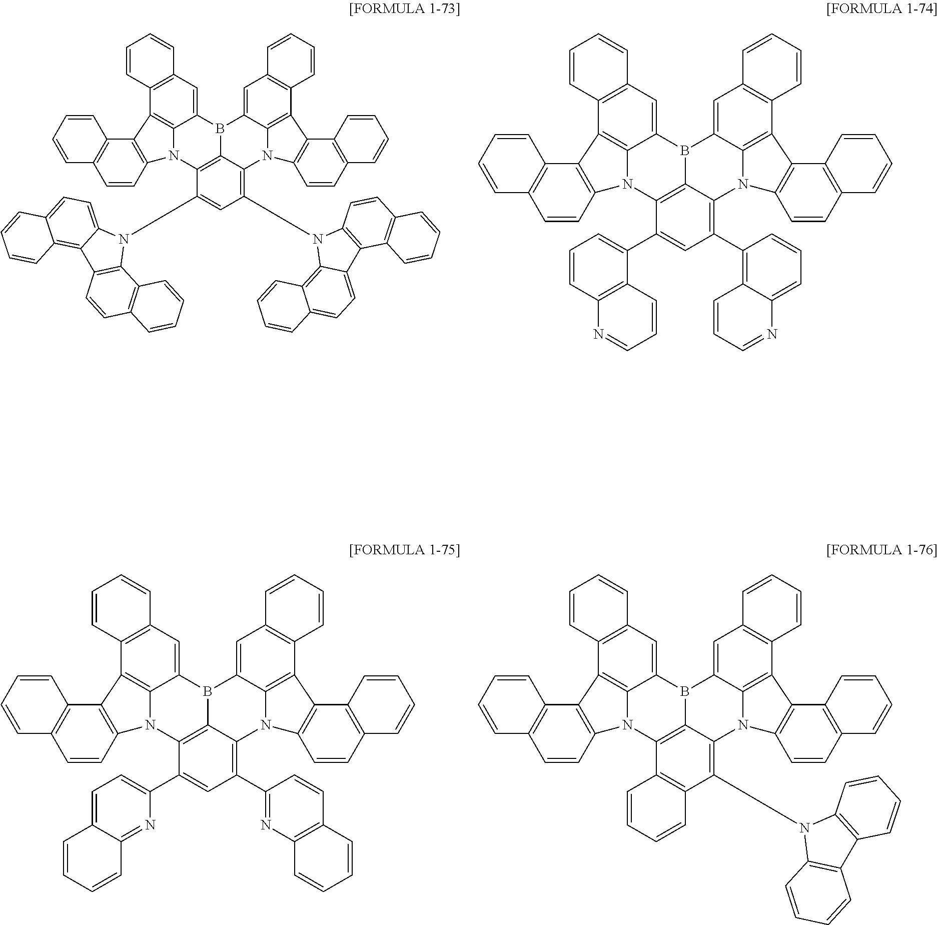 [SMILES: c1ccc2c(c1)ccc1c2c2c3ccccc3cc3c2n1-c1c(-n2c4ccc5ccccc5c4c4ccc5ccccc5c42)cc(-n2c4ccc5ccccc5c4c4ccc5ccccc5c42)c2c1B3c1cc3ccccc3c3c4c5ccccc5ccc4n-2c13 ; c1ccc2c(c1)ccc1c2c2c3ccccc3cc3c2n1-c1c(-c2cccc4ncccc24)cc(-c2cccc4ncccc24)c2c1B3c1cc3ccccc3c3c4c5ccccc5ccc4n-2c13 ; c1ccc2nc(-c3cc(-c4ccc5ccccc5n4)c4c5c3-n3c6ccc7ccccc7c6c6c7ccccc7cc(c63)B5c3cc5ccccc5c5c6c7ccccc7ccc6n-4c35)ccc2c1 ; c1ccc2c(c1)ccc1c2c2c3ccccc3cc3c2n1-c1c2c(c4ccccc4c1-n1c4ccccc4c4ccccc41)-n1c4ccc5ccccc5c4c4c5ccccc5cc(c41)B23]

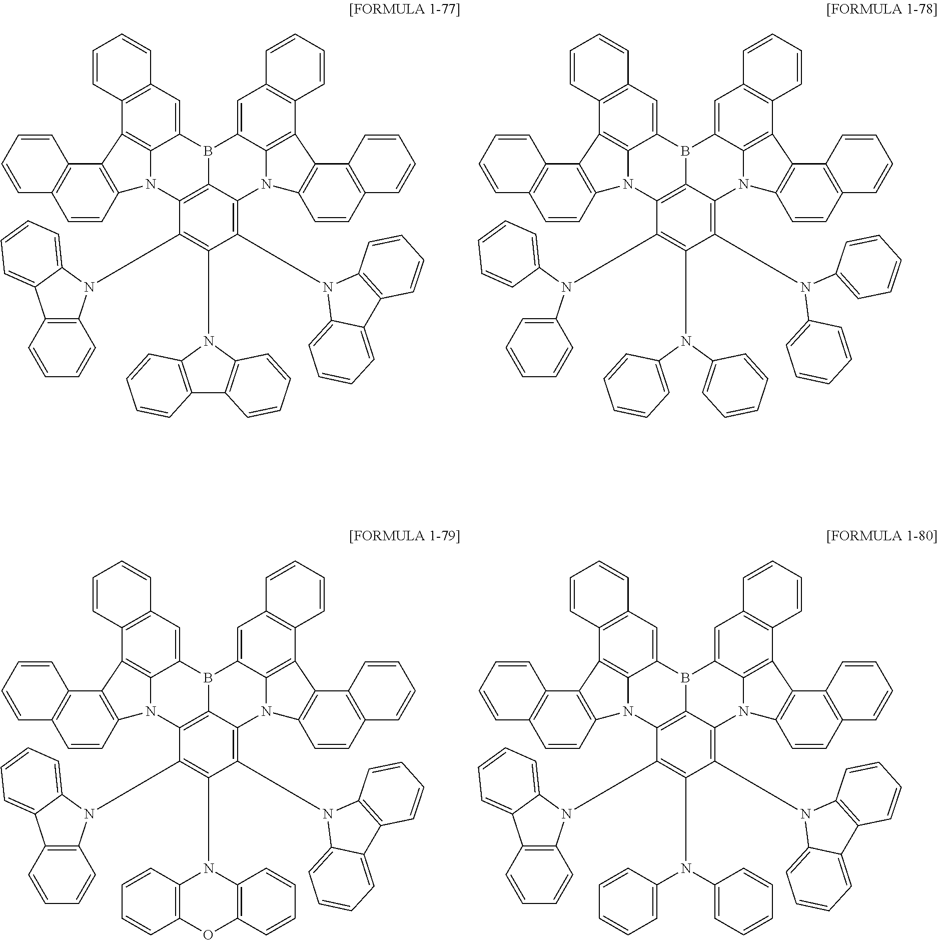

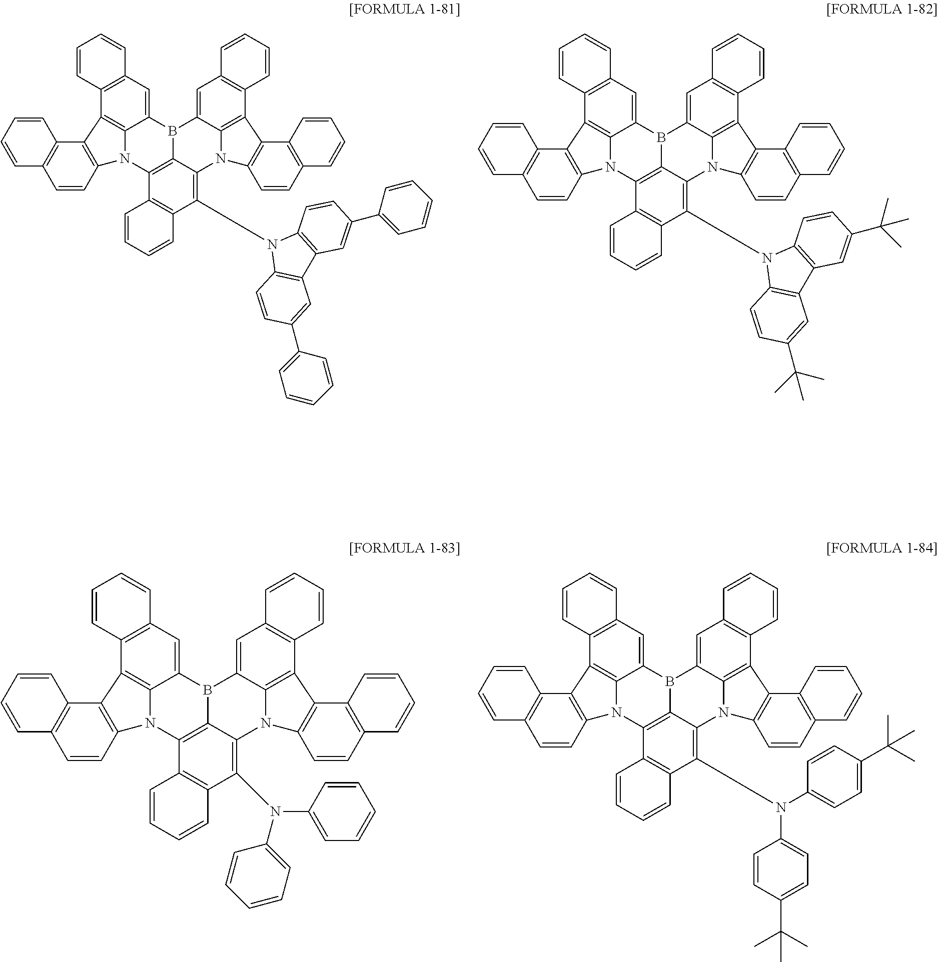

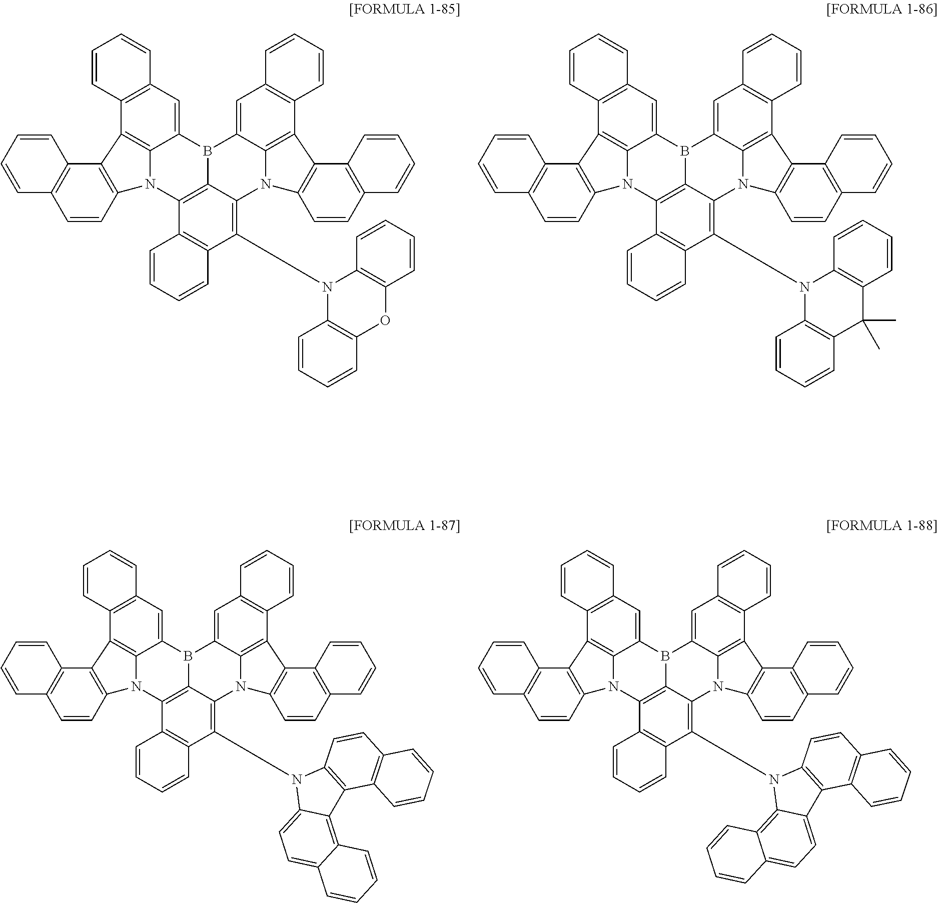 [SMILES: c1ccc2c(c1)Oc1ccccc1N2c1c2c3c(c4ccccc14)-n1c4ccc5ccccc5c4c4c5ccccc5cc(c41)B3c1cc3ccccc3c3c4c5ccccc5ccc4n-2c13 ; CC1(C)c2ccccc2N(c2c3c4c(c5ccccc25)-n2c5ccc6ccccc6c5c5c6ccccc6cc(c52)B4c2cc4ccccc4c4c5c6ccccc6ccc5n-3c24)c2ccccc21 ; c1ccc2c(c1)ccc1c2c2c3ccccc3ccc2n1-c1c2c3c(c4ccccc14)-n1c4ccc5ccccc5c4c4c5ccccc5cc(c41)B3c1cc3ccccc3c3c4c5ccccc5ccc4n-2c13 ; c1ccc2c(c1)ccc1c2c2c3ccccc3cc3c2n1-c1c2c(c4ccccc4c1-n1c4ccc5ccccc5c4c4ccc5ccccc5c41)-n1c4ccc5ccccc5c4c4c5ccccc5cc(c41)B23]

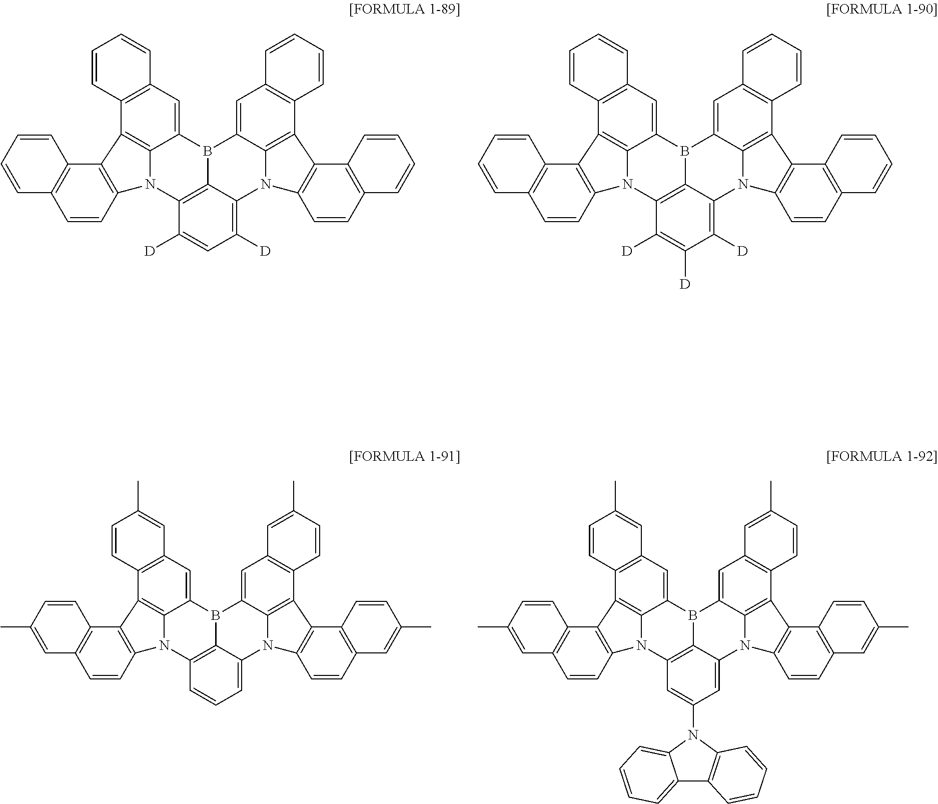

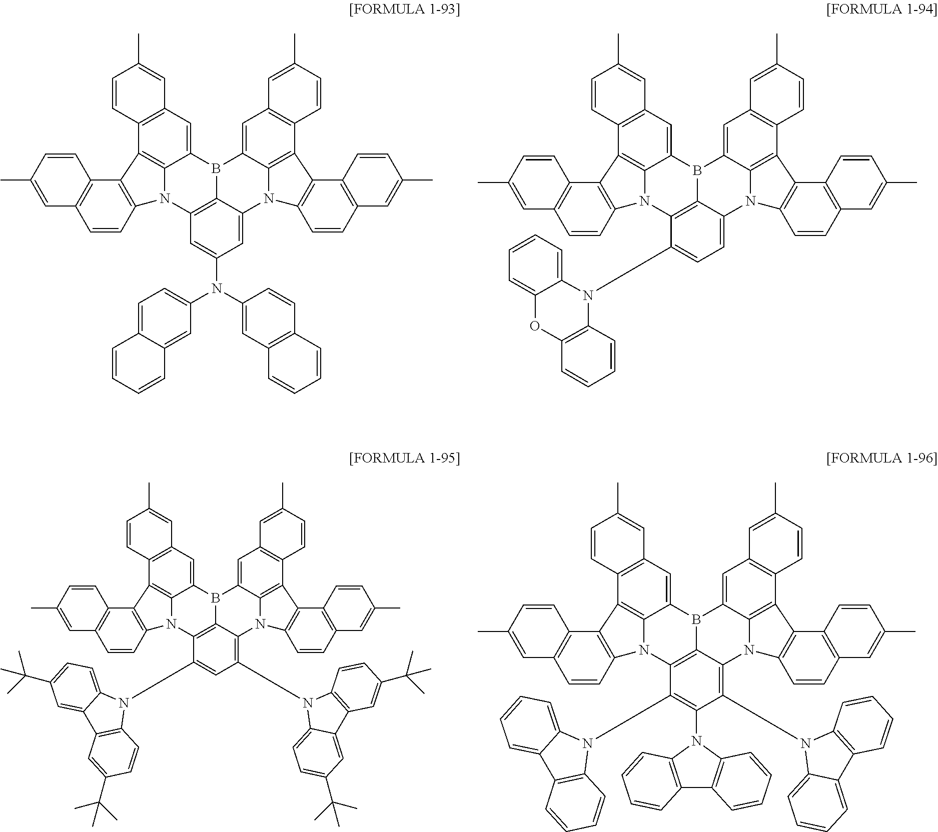

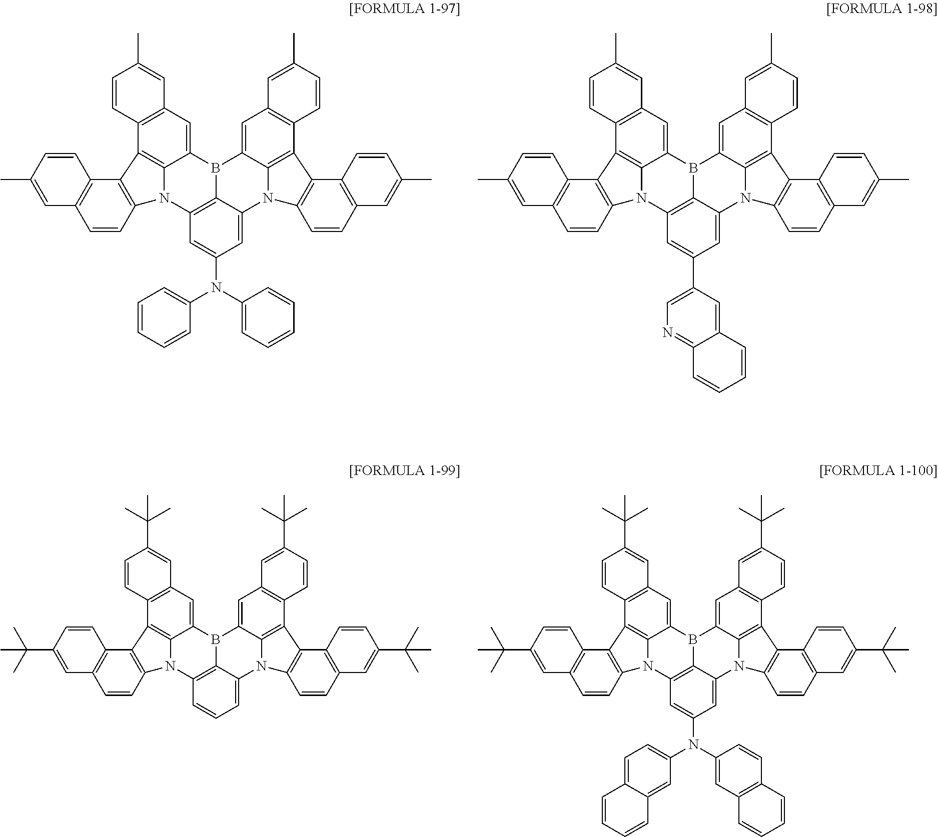

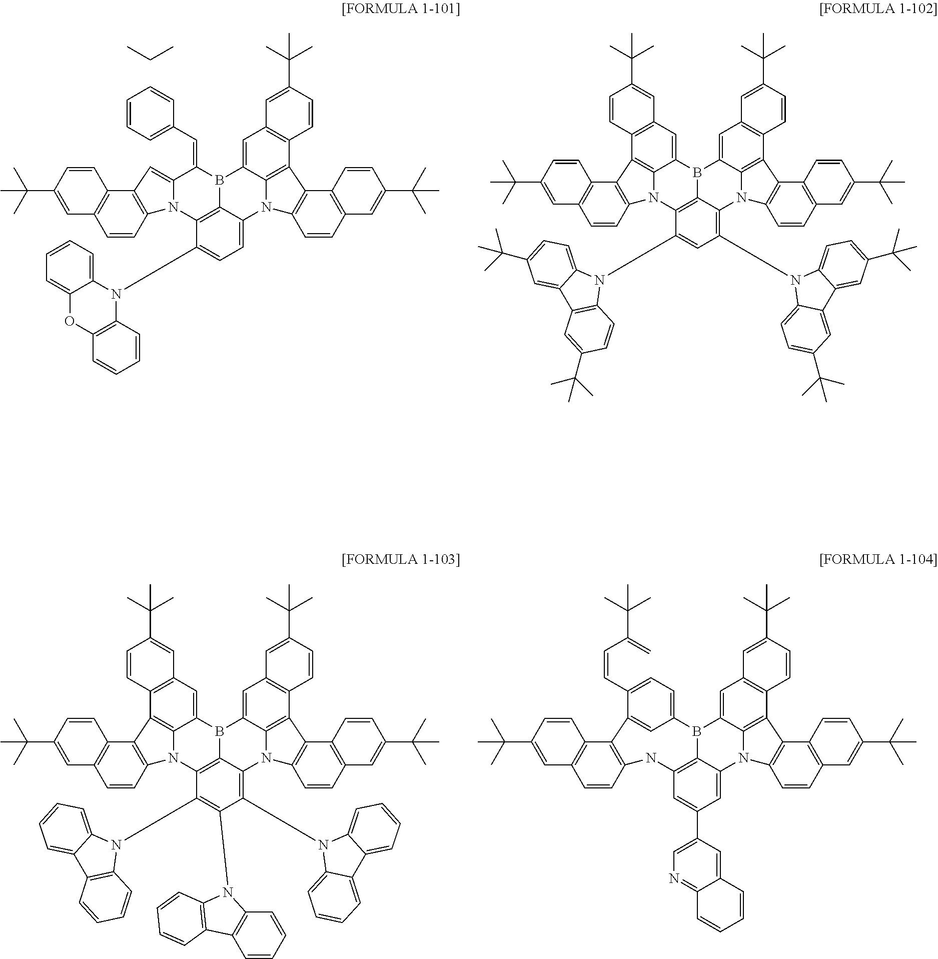

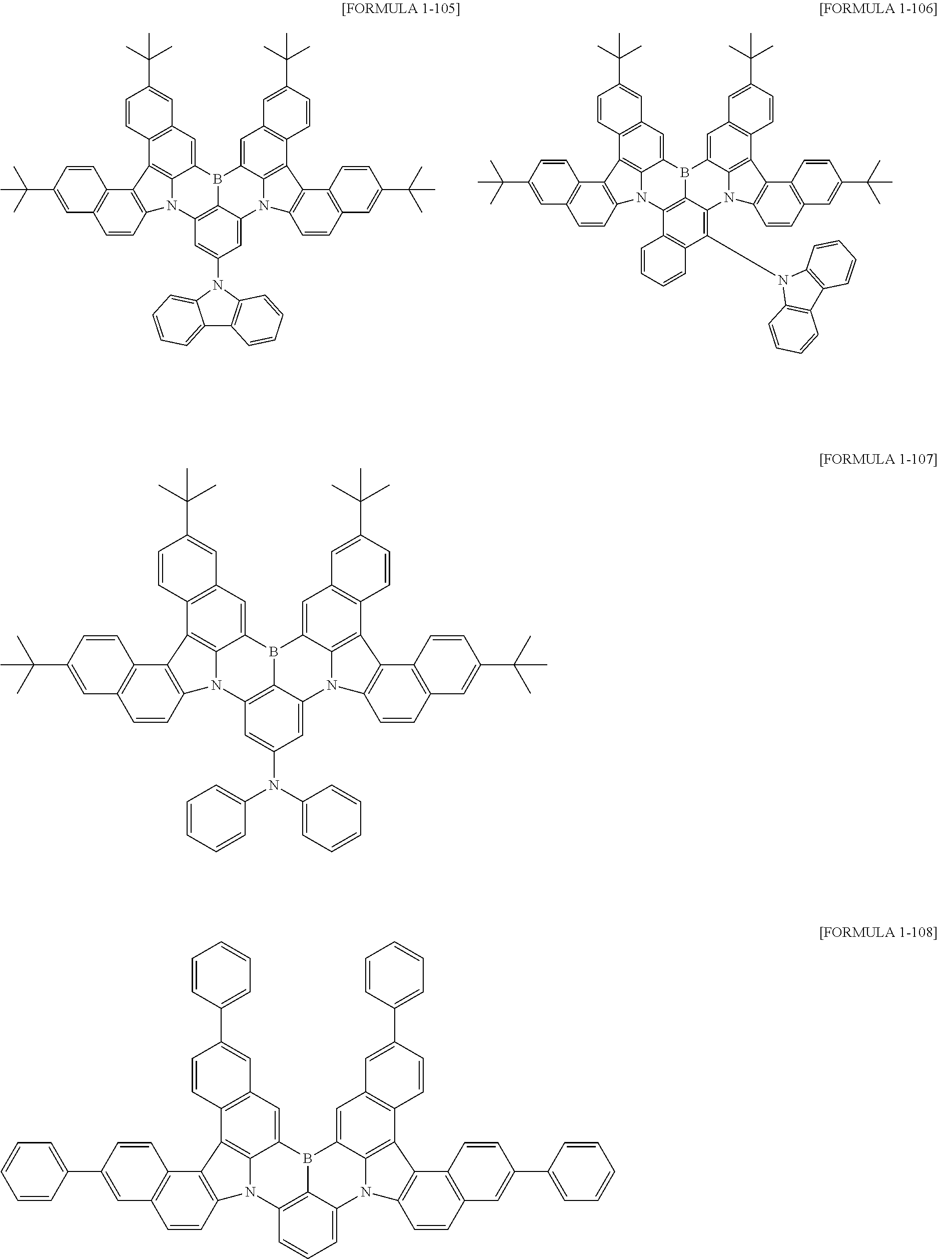

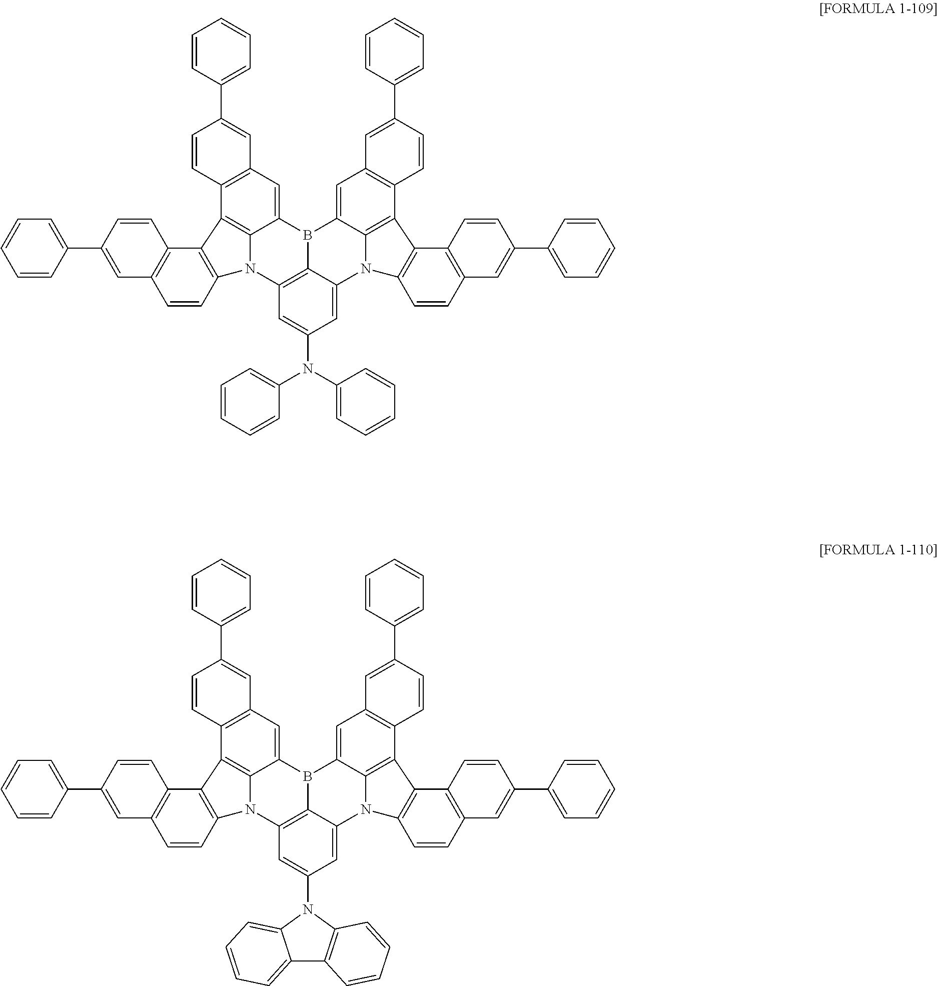 [SMILES: c1ccc(-c2ccc3c(ccc4c3c3c5ccc(-c6ccccc6)cc5cc5c3n4-c3cc(N(c4ccccc4)c4ccccc4)cc4c3B5c3cc5cc(-c6ccccc6)ccc5c5c6c7ccc(-c8ccccc8)cc7ccc6n-4c35)c2)cc1 ; c1ccc(-c2ccc3c(ccc4c3c3c5ccc(-c6ccccc6)cc5cc5c3n4-c3cc(-n4c6ccccc6c6ccccc64)cc4c3B5c3cc5cc(-c6ccccc6)ccc5c5c6c7ccc(-c8ccccc8)cc7ccc6n-4c35)c2)cc1]

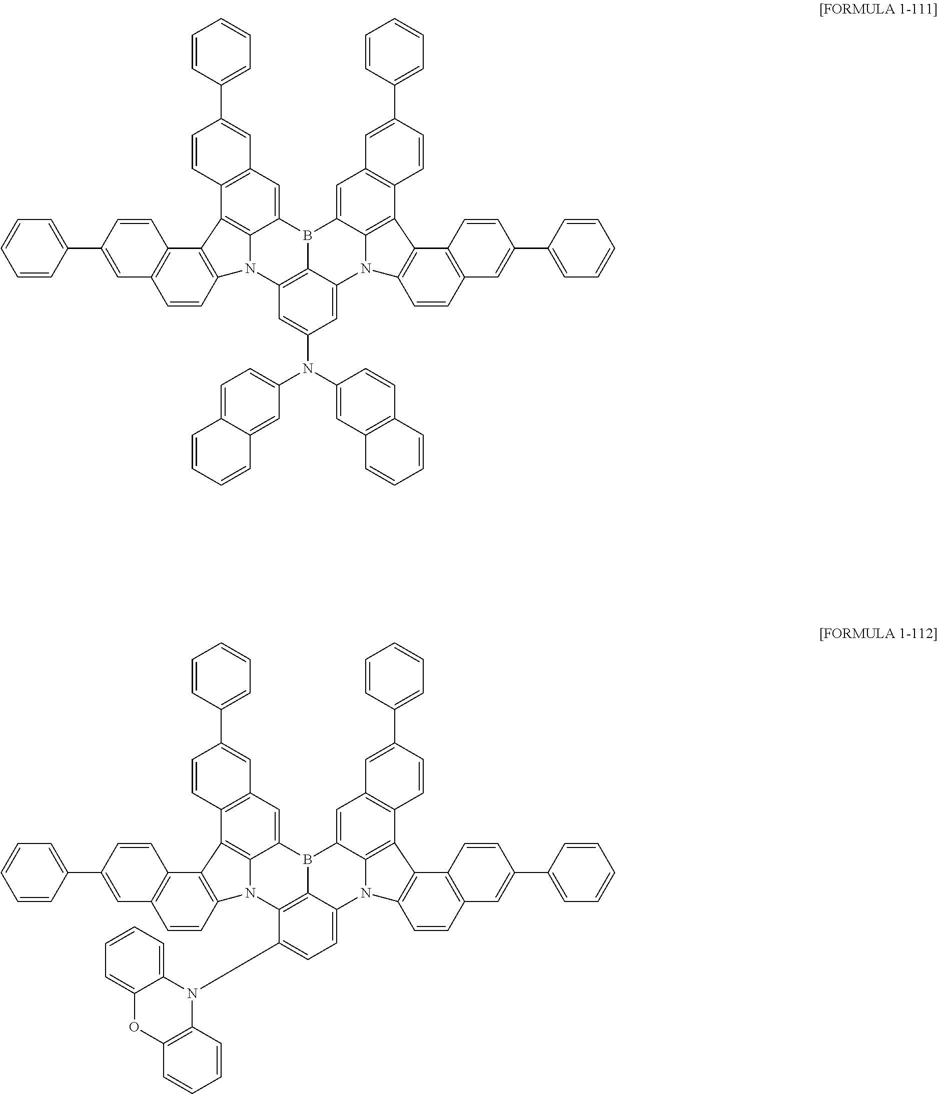 [SMILES: c1ccc(-c2ccc3c(ccc4c3c3c5ccc(-c6ccccc6)cc5cc5c3n4-c3cc(N(c4ccc6ccccc6c4)c4ccc6ccccc6c4)cc4c3B5c3cc5cc(-c6ccccc6)ccc5c5c6c7ccc(-c8ccccc8)cc7ccc6n-4c35)c2)cc1 ; c1ccc(-c2ccc3c(ccc4c3c3c5ccc(-c6ccccc6)cc5cc5c3n4-c3ccc(N4c6ccccc6Oc6ccccc64)c4c3B5c3cc5cc(-c6ccccc6)ccc5c5c6c7ccc(-c8ccccc8)cc7ccc6n-4c35)c2)cc1]

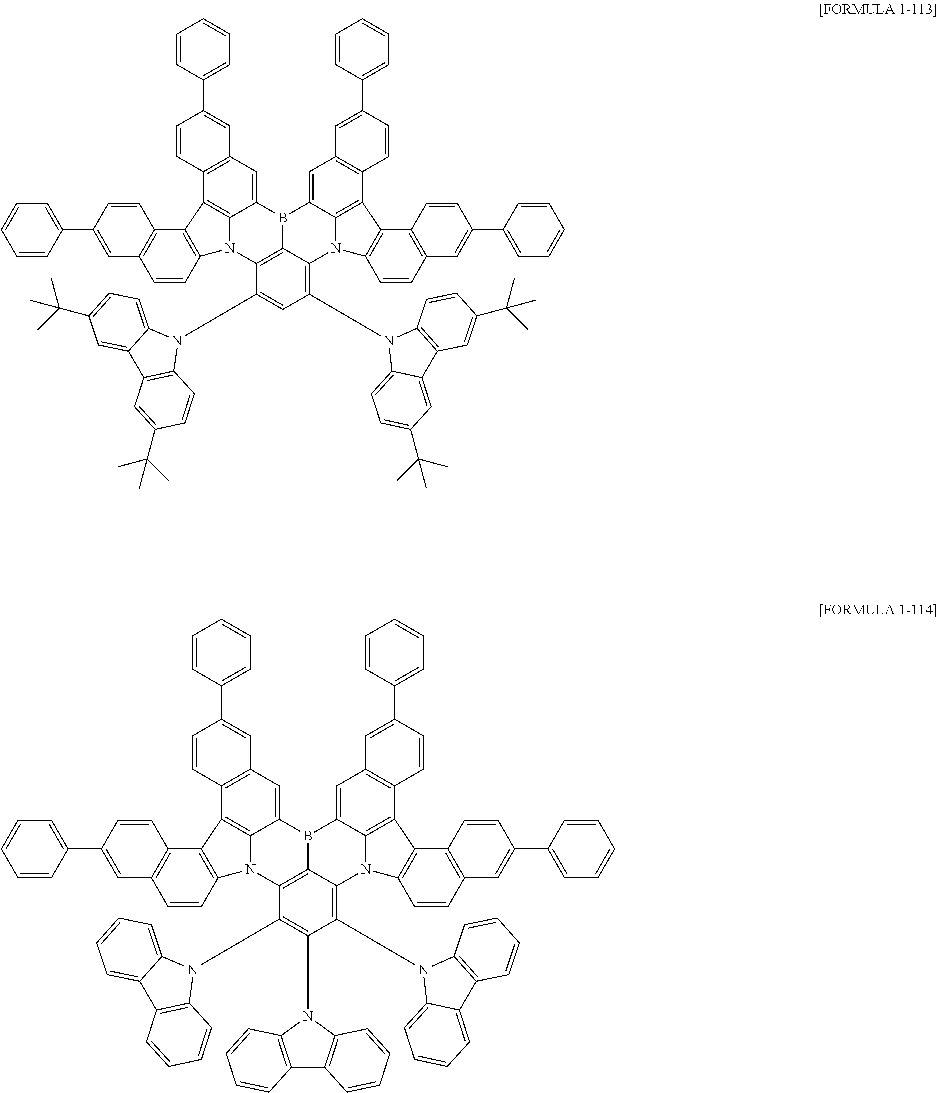 [SMILES: CC(C)(C)c1ccc2c(c1)c1cc(C(C)(C)C)ccc1n2-c1cc(-n2c3ccc(C(C)(C)C)cc3c3cc(C(C)(C)C)ccc32)c2c3c1-n1c4ccc5cc(-c6ccccc6)ccc5c4c4c5ccc(-c6ccccc6)cc5cc(c41)B3c1cc3cc(-c4ccccc4)ccc3c3c4c5ccc(-c6ccccc6)cc5ccc4n-2c13 ; c1ccc(-c2ccc3c(ccc4c3c3c5ccc(-c6ccccc6)cc5cc5c3n4-c3c4c(c(-n6c7ccccc7c7ccccc76)c(-n6c7ccccc7c7ccccc76)c3-n3c6ccccc6c6ccccc63)-n3c6ccc7cc(-c8ccccc8)ccc7c6c6c7ccc(-c8ccccc8)cc7cc(c63)B45)c2)cc1]

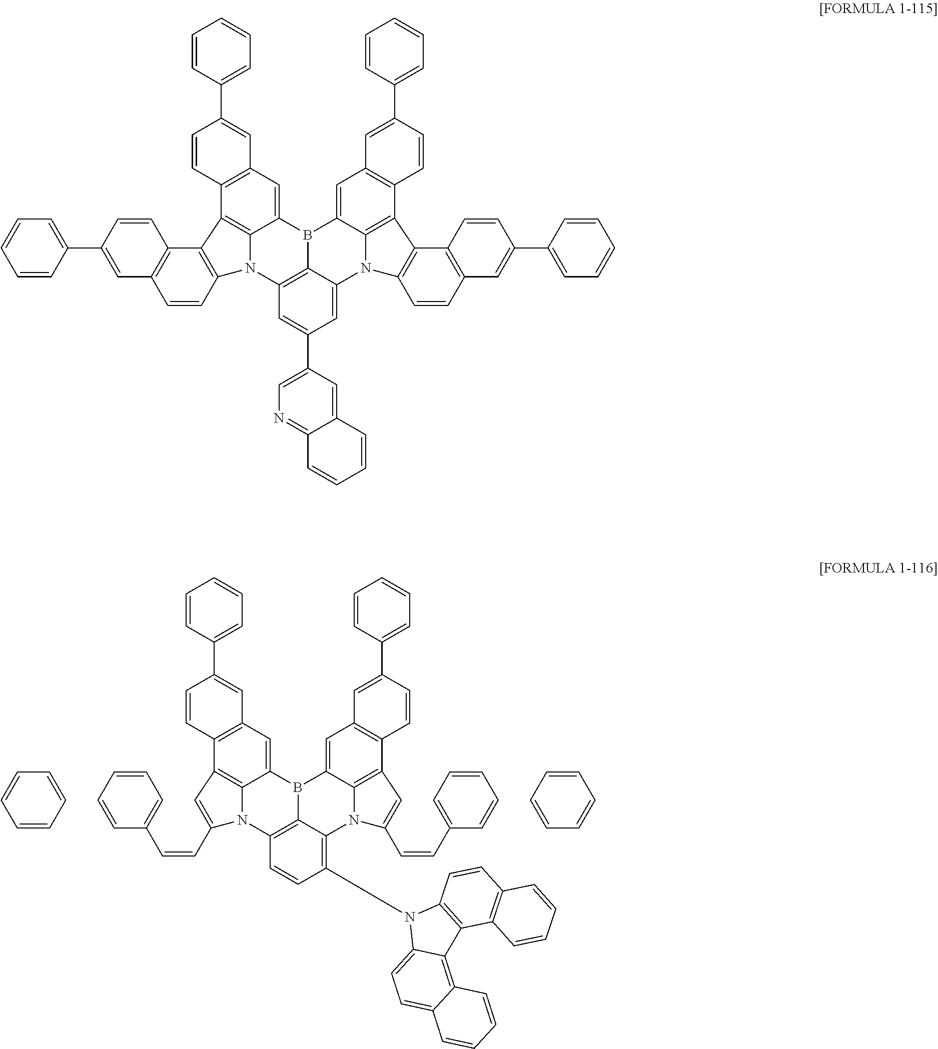

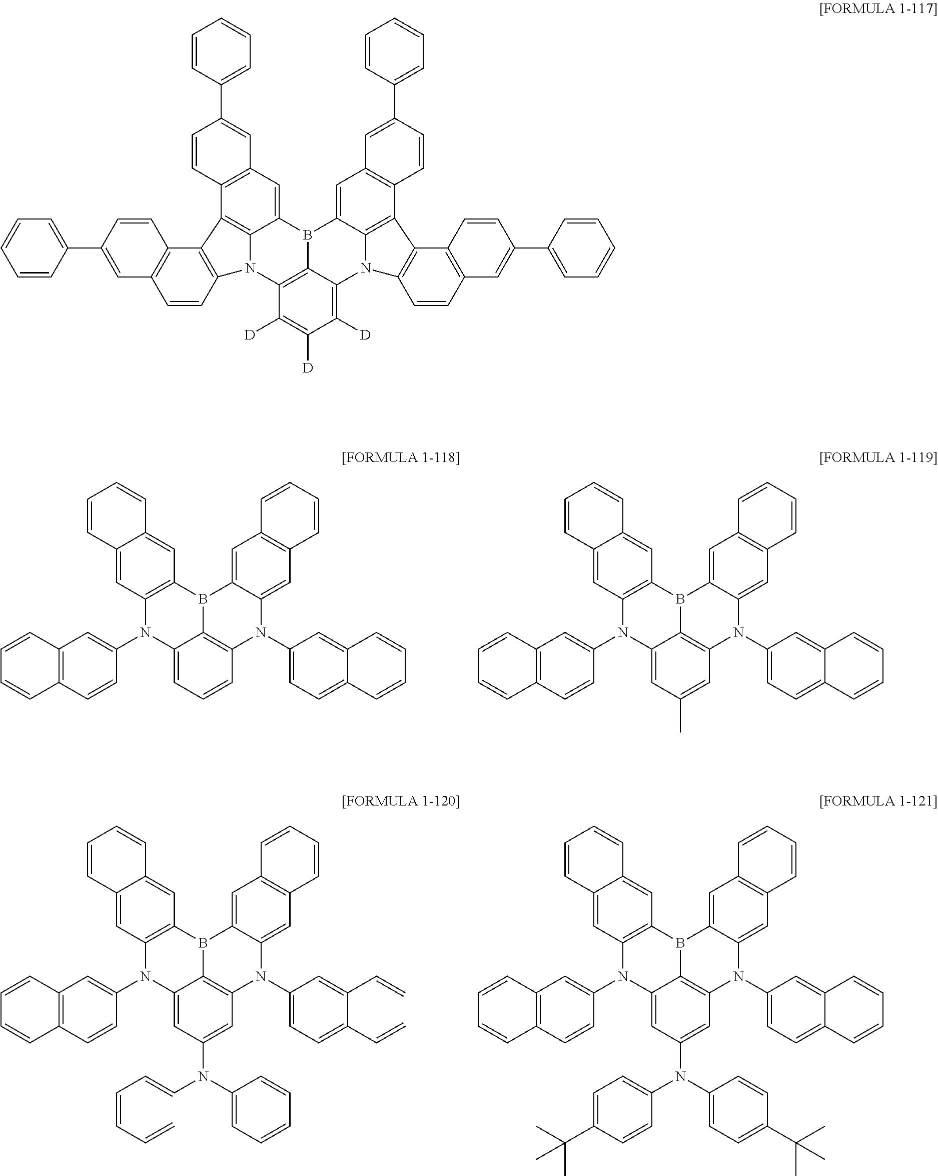

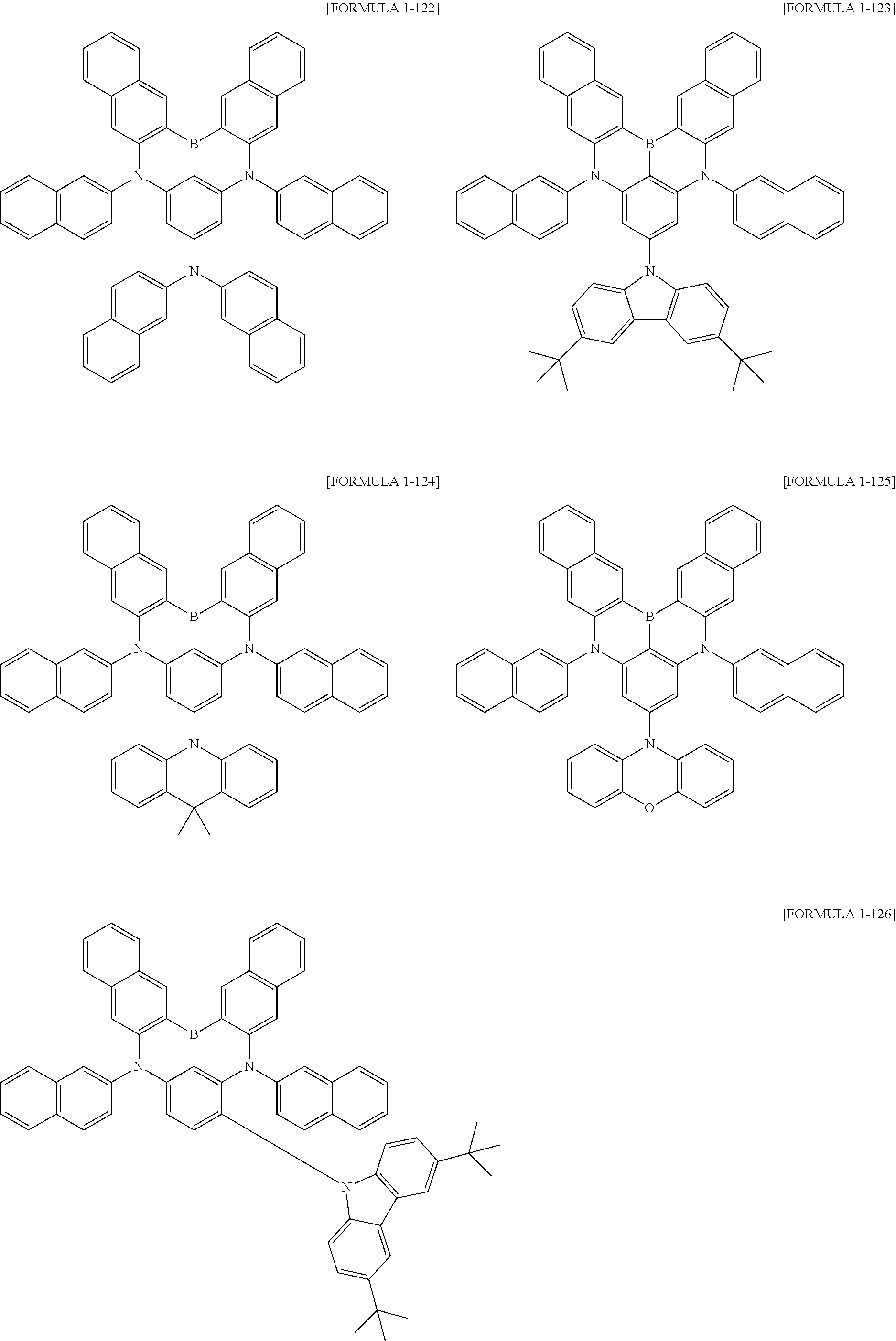

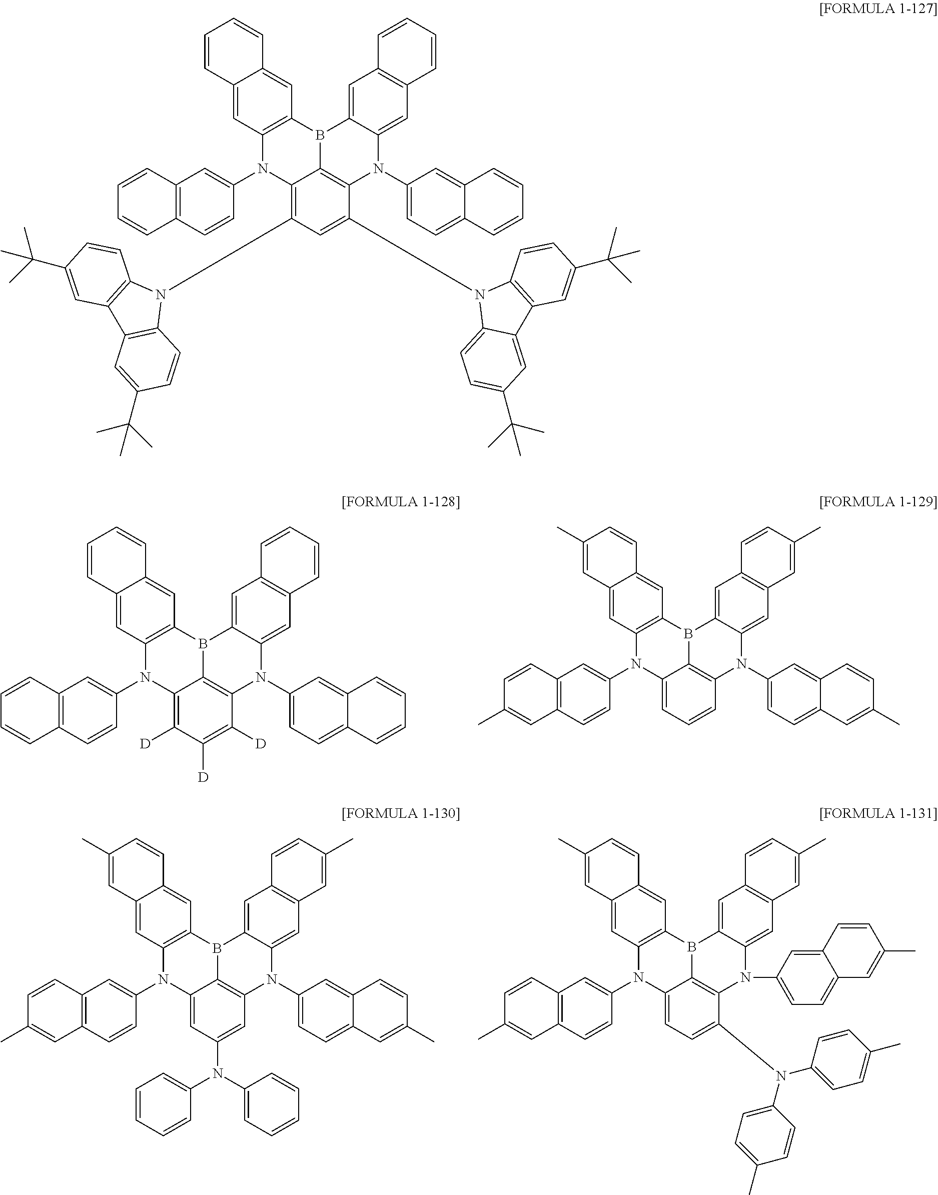

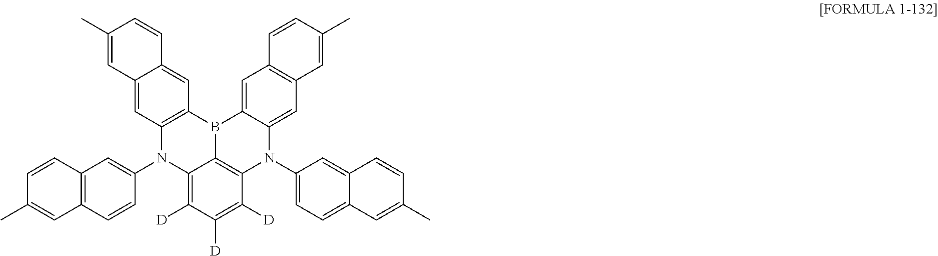

In an embodiment, the boron compound may have an emission spectrum with a peak at 450 to 600 nm.

In an embodiment, the boron compound may have a full width at half maximum of an emission spectrum of 40 nm or less.

In an embodiment, the compound may have a photoluminescence quantum yield of 0.90 or more.

Another aspect of the present invention provides an organic light-emitting device, which includes: a first electrode; a second electrode provided to face the first electrode; and one or more organic material layers interposed between the first electrode and the second electrode, wherein the one or more organic material layers include at least one of the above-described boron compounds.

In an embodiment, the first electrode may be an anode, the second electrode may be a cathode, and the organic material layer may include: a light-emitting layer containing at least one of the above-described compounds; a hole transport region interposed between the first electrode and the light-emitting layer and including at least one of a hole injection layer, a hole transport layer, and an electron blocking layer; and an electron transport region interposed between the light-emitting layer and the second electrode and including at least one of a hole blocking layer, an electron transport layer, and an electron injection layer.

In an embodiment, the organic light-emitting device may have a maximum external quantum efficiency of 20% or more.

In an embodiment, the organic material layer may include one or more host compounds; a delayed fluorescent or phosphorescent compound; and a light-emitting layer containing at least one of the above-described boron compounds.

### Advantageous Effects

According to an aspect of the present invention, it is possible to provide a compound having a narrow full width at half maximum and excellent color purity.

According to another aspect of the present invention, it is possible to provide an organic light-emitting diode including the above-described compound.

In addition, according to another aspect of the present invention, it is possible to provide a delayed fluorescence or phosphorescence photosensitive hyperfluorescent device by using a compound having a narrow full width at half maximum, excellent color purity, and a small singlet-triplet energy gap.

The effects of an aspect of the present invention are not limited to the above-mentioned effects, and it should be understood that the effects of the present invention include all effects that could be inferred from the configuration of the invention described in the detailed description of the invention or the appended claims.

### DESCRIPTION OF DRAWINGS

FIG. 1 is a graph showing the characteristics of a boron compound according to an embodiment of the present invention.

FIG. 2 is a graph showing the characteristics of a boron compound according to another embodiment of the present invention.

FIG. 3 is a graph showing the characteristics of a boron compound according to still another embodiment of the present invention.

FIG. 4 is a graph showing the characteristics of an organic light-emitting device including a boron compound according to an embodiment of the present invention.

FIG. 5 is a graph showing the characteristics of an organic light-emitting device including a boron compound according to another embodiment of the present invention.

### MODES OF THE INVENTION

Hereinafter, aspects of the present invention will be described with reference to the accompanying drawings. However, the present invention may be implemented in various different forms, and thus is not limited to the embodiments described herein. In addition, in order to clearly explain an aspect of the present invention in the drawings, portions that are not related to the present invention are omitted, and like reference numerals are used to refer to like elements throughout the specification.

Throughout the specification, it will be understood that when a portion is referred to as being “connected” to another portion, it can be “directly connected to” the other portion, or “indirectly connected to” the other portion with another member interposed therebetween. Also, when a component “includes” an element, it should be understood that the component does not exclude another element but may further include another element, unless otherwise stated.

When a numerical value is presented herein, the value has the precision of the significant digit provided in accordance with the standard rules in chemistry for significant digits unless its specific range is stated otherwise. For example, the numerical value 10 includes the range of 5.0 to 14.9 and the numerical value 10.0 includes the range of 9.50 to 10.49.

Hereinafter, embodiments of the present invention will be described in detail with reference to the accompanying drawings.

### Boron Compounds for Organic Light-Emitting Devices

An aspect of the present invention provides a boron compound represented by the following Formula 1.

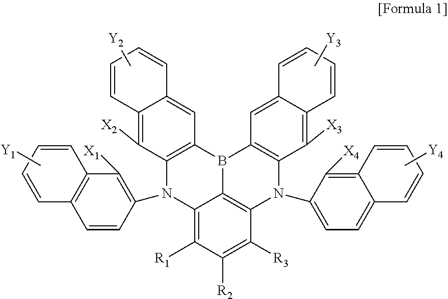

In Formula 1, Y₁ to Y₄ may each independently represent hydrogen, deuterium, a nitrile group, a substituted or unsubstituted alkyl group, a substituted or unsubstituted cycloalkyl group, a substituted or unsubstituted alkoxy group, a substituted or unsubstituted silyl group, a substituted or unsubstituted amine group, a substituted or unsubstituted aryl group, a substituted or unsubstituted heteroaryl group, a substituted or unsubstituted diarylamino group, a substituted or unsubstituted diheteroarylamino group, or a substituted or unsubstituted arylheteroarylamino group, X₁ to X₄ may each independently represent hydrogen or are mutually bonded to form a ring; R₁ to R₃ may each independently represent hydrogen, deuterium, a nitrile group, a halogen group, a substituted or unsubstituted alkyl group, a substituted or unsubstituted cycloalkyl group, a substituted or unsubstituted alkoxy group, a substituted or unsubstituted silyl group, a substituted or unsubstituted amine group, a substituted or unsubstituted aryl group, a substituted or unsubstituted heteroaryl group, a substituted or unsubstituted diarylamino group, a substituted or unsubstituted diheteroarylamino group, or a substituted or unsubstituted arylheteroarylamino group, or a ring structure formed by mutually bonding R₁ and R₂ or R₂ and R₃.

Each of X₁ to X₄ may be hydrogen, or X₁ and X₂ or X₃ and X₄ may be mutually bonded to form a ring.

The alkyl group may represent a straight or branched alkyl group having 1 to 10 carbon atoms, an unsubstituted alkyl group may be an alkyl group composed of only carbon and hydrogen, and a substituted alkyl group may represent an alkyl group in which at least one carbon atom constituting the alkyl group is substituted with an atom other than a carbon atom. Examples of the substituted atoms include nitrogen, sulfur, oxygen, silicon, halogen elements and the like, but are not limited thereto.

The cycloalkyl group may represent an alkyl group containing at least one cyclic structure and having 1 to 10 carbon atoms, an unsubstituted cycloalkyl group may be an alkyl group composed of only carbon and hydrogen, and a substituted cycloalkyl group may represent a cycloalkyl group in which at least one carbon atom constituting the cycloalkyl group is substituted with an atom other than a carbon atom. Examples of the substituted atoms include nitrogen, sulfur, oxygen, silicon, halogen elements and the like, but are not limited thereto.

The alkoxy group may represent a functional group in which oxygen is bonded to a terminal of a straight or branched alkyl group having 1 to 10 carbon atoms, an unsubstituted alkoxy group may be a functional group in which oxygen is bonded to a terminal of an alkyl group composed of only carbon and hydrogen, and a substituted alkoxy group may represent an alkoxy group in which at least one carbon atom constituting the alkoxy group is substituted with an atom other than a carbon atom. Examples of the substituted atoms include nitrogen, sulfur, oxygen, silicon, halogen elements and the like, but are not limited thereto.

The silyl group may represent a functional group in which silicon is bonded to a terminal of a straight or branched alkyl group having 1 to 10 carbon atoms, an unsubstituted silyl group may be a functional group in which silicon is bonded to a terminal of an alkyl group composed of only carbon and hydrogen, and a substituted silyl group may represent a silyl group in which at least one carbon atom constituting the silyl group is substituted with an atom other than a carbon atom. Examples of the substituted atoms include nitrogen, sulfur, oxygen, silicon, halogen elements and the like, but are not limited thereto.

The amine group may represent a functional group in which nitrogen is bonded to a terminal of a straight or branched alkyl group having 1 to 10 carbon atoms, an unsubstituted amine group may be a functional group in which nitrogen is bonded to a terminal of an alkyl group composed of only carbon and hydrogen, and a substituted amine group may represent a amine group in which at least one carbon atom constituting the amine group is substituted with an atom other than a carbon atom. Examples of the substituted atoms include nitrogen, sulfur, oxygen, silicon, halogen elements and the like, but are not limited thereto.

The aryl group may represent a functional group containing at least one aromatic structure and having 1 to 10 carbon atoms, an unsubstituted aryl group may be an aryl group composed of only carbon and hydrogen, and a substituted aryl group may represent an aryl group in which at least one carbon atom constituting the aryl group is substituted with another atom. Examples of the substituted atoms include nitrogen, sulfur, oxygen, silicon, halogen elements and the like, but are not limited thereto.

The heteroaryl group may represent a functional group having 1 to 10 carbon atoms and containing at least one aromatic structure in which at least one carbon is substituted with another atom, an unsubstituted heteroaryl group may be a functional group in which a substituted aromatic structure is composed of only carbon and hydrogen, and a substituted heteroaryl group may represent a functional group in which a substituted aromatic structure is connected by a structure including at least one atom other than carbon and hydrogen. Examples of the atoms include nitrogen, sulfur, oxygen, silicon, halogen elements and the like, but are not limited thereto.

The diarylamino group may represent a functional group in which two aryl groups are bonded to a nitrogen atom, an unsubstituted diarylamino group may be a functional group in which both of the two aryl groups are unsubstituted, and a substituted diarylamino group may represent a functional group in which at least one of the two aryl groups is substituted.

The diheteroarylamino group may represent a functional group in which both aryl groups of the diarylamino group are changed to heteroaryl groups, an unsubstituted diheteroarylamino group may be a functional group in which both of the two heteroaryl groups are unsubstituted, and a substituted diheteroarylamino group may represent a functional group in which at least one of the two heteroaryl groups is substituted.

The arylheteroarylamino group may represent a functional group in which one aryl group of the diarylamino group is a heteroaryl group, and an unsubstituted arylheteroarylamino group is a functional group in which both a heteroaryl group and an aryl group are unsubstituted, and a substituted arylheteroarylamino group may represent at least one of an aryl group and a heteroaryl group is substituted.

In the case of fluorescent materials, 75% of the triplet energy is lost using only singlet energy, and thus an organic light-emitting device using a phosphorescent material inducing intersystem crossing (ISC) converting a singlet to a triplet has been attempted to address the problem of the fluorescent material. However, conventional phosphorescent materials have a problem in that the electroluminescence spectrum is broadened due to luminescence through charge transfer between heavy metals and organic materials.

As in the above-described compound, when electron-deficient boron atoms and electron-rich nitrogen atoms are alternately arranged, a multi-resonance structure by which the HOMO and LUMO are separated may be formed. At this time, since boron and nitrogen are tightly connected in a cycle structure, a change in molecular structure is small in a light-emitting state, so that luminescent properties with a narrow half-width may be realized.

Unlike existing fluorescence in which 75% of the triplet energy is lost using only singlet energy, in delayed fluorescence, molecules are designed to reduce the singlet-triplet energy gap, inducing reverse intersystem crossing (RISC) converting a triplet to a singlet using only thermal energy at room temperature, so that the energies of both the singlet energy and the triplet energy can be utilized. Therefore, since the triplet can be used without a heavy metal material like a phosphorescent material, the efficiency of the material is higher than that of the fluorescent material, and fluorescence emission can be realized via the triplet.

Existing delayed fluorescent materials have a problem in that a donor unit and an acceptor unit are separated, and the connection therebetween is not fixed, so that an electroluminescence spectrum is widened due to molecular motion such as rotation and vibration.

On the other hand, since the boron compound includes a multi-resonance structure with small overlap between the HOMO and LUMO, delayed fluorescence properties may be more easily implemented, and excellent color purity may be realized by forming a narrow full width at half maximum.

In addition, when the light-emitting layer includes the boron compound and the delayed fluorescent dopant, phosphorescent dopant, or fluorescent dopant, all singlet energy may be transferred to the fluorescent dopant to realize higher efficiency than that of existing fluorescent dopant devices and high color purity of the fluorescence dopant, and in the present specification, the device is referred to as a delayed fluorescence photosensitive or phosphorescence photosensitive hyperfluorescent device.

On the other hand, the boron compound may include a multi-resonance structure by which the HOMO and LUMO are separated through a structure in which electron-deficient atoms and electron-rich atoms are alternately arranged. In the multi-resonance structure, overlap between the HOMO and the LUMO is small, and thus reverse intersystem crossing (RISC) is easily induced by thermal energy at room temperature to realize delayed fluorescence properties, and a full width at half maximum becomes narrow to realize excellent color purity.

For example, since boron atoms are relatively electron-deficient, carbon atoms in a benzene ring directly connected thereto may be HOMO-activated, and nitrogen atoms may be relatively electron-abundant so that carbon atoms in a benzene ring directly connected thereto may be LUMO-activated. That is, the benzene ring connected to the boron atom may have a resonance structure in which HOMO-LUMO are repeated, and the benzene ring connected to the nitrogen atom may have a resonance structure in which LUMO-HOMO is repeated, so that the resonance structures are mutually disposed. The compound may form multiple resonance structures through an opposite resonance effect by alternately arranging resonance structures that are mutually disposed.

The compound has a small Stoke's shift because a boron-nitrogen cycle structure is firmly fixed, and thus may realize a narrow full width at half maximum and high color purity. Further, the compound may further improve luminous efficiency by isolating only the resonance form without separating the structure implementing the HOMO-LUMO.

The boron compound may include a structure derived from dibenzocarbazole. The dibenzocarbazole-derived structure may include multiple resonance structures to maximize multi-resonance effects.

The boron compound may realize desired physical properties by including a substituent structure of R₁ to R₃. At least one of R₁ to R₃ may be represented by one of the following Formulas 2 to 3.

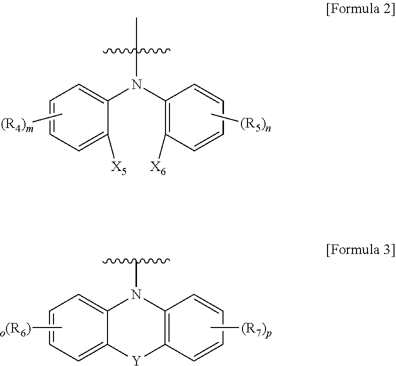

In Formula 2 or 3, R₄ to R₇ each independently represent hydrogen, deuterium, a nitrile group, a halogen group, a substituted or unsubstituted aromatic ring, a substituted or unsubstituted alkyl group, a substituted or unsubstituted cycloalkyl group, a substituted or unsubstituted alkoxy group, a substituted or unsubstituted silyl group, a substituted or unsubstituted amine group, a substituted or unsubstituted aryl group, a substituted or unsubstituted heteroaryl group, a substituted or unsubstituted diarylamino group, a substituted or unsubstituted diheteroarylamino group, or a substituted or unsubstituted arylheteroarylamino group, X₅ to X₆ may each independently represent hydrogen or are mutually bonded to form a ring, Y is sulfur, oxygen, carbon to which one or more alkyl or aryl groups are bonded, and m, n, o and p each independently represent an integer of 0 to 4.

The compound represented by Formula 2 may have a structure derived from a diphenylamine-based compound or a structure derived from a carbazole-based compound in which hydrogen is bonded to each benzene ring.

The compound represented by Formula 3 may have a structure derived from an acridine-based compound, a phenothiazine-based compound, or a phenoxazine-based compound.

The structures of Formulas 2 and 3 may have properties similar to a type of electron acceptor by including a nitrogen atom directly connected to the benzene ring of Formula 1. The substituent structure may further stabilize a LUMO structure to shift the emission spectrum of the compound.

The compound may be represented by one of the following Formulas 1-1 to 1-132.

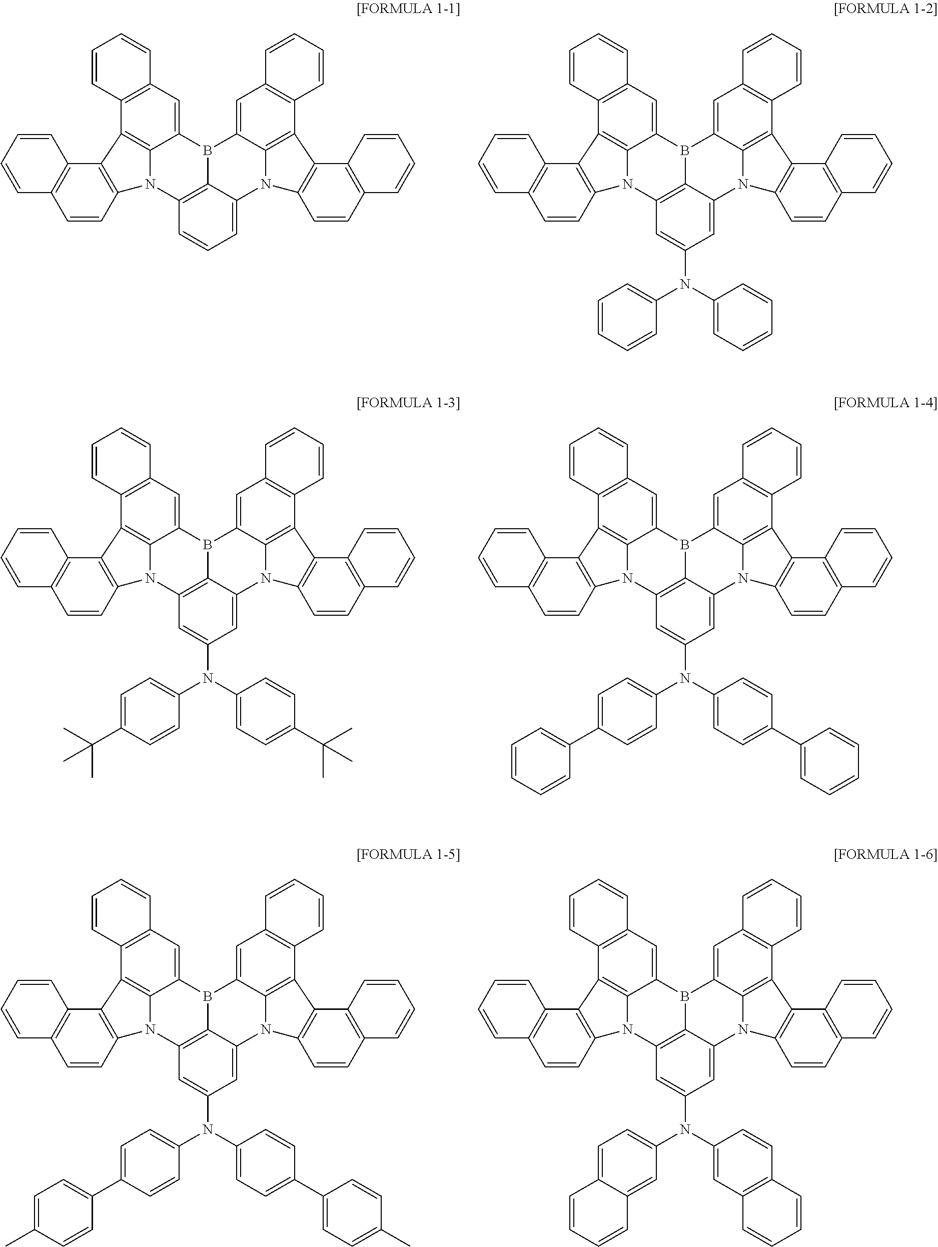

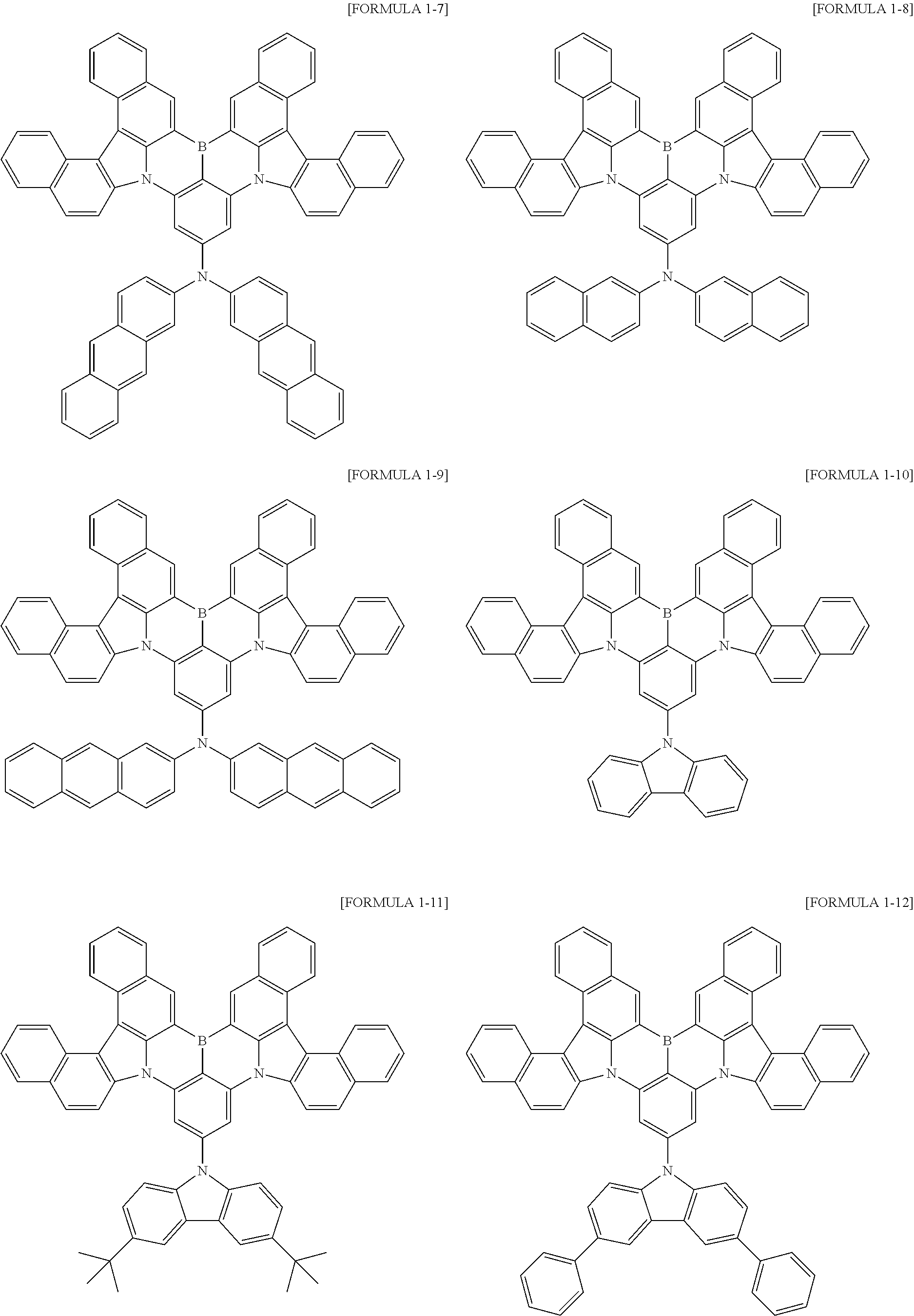

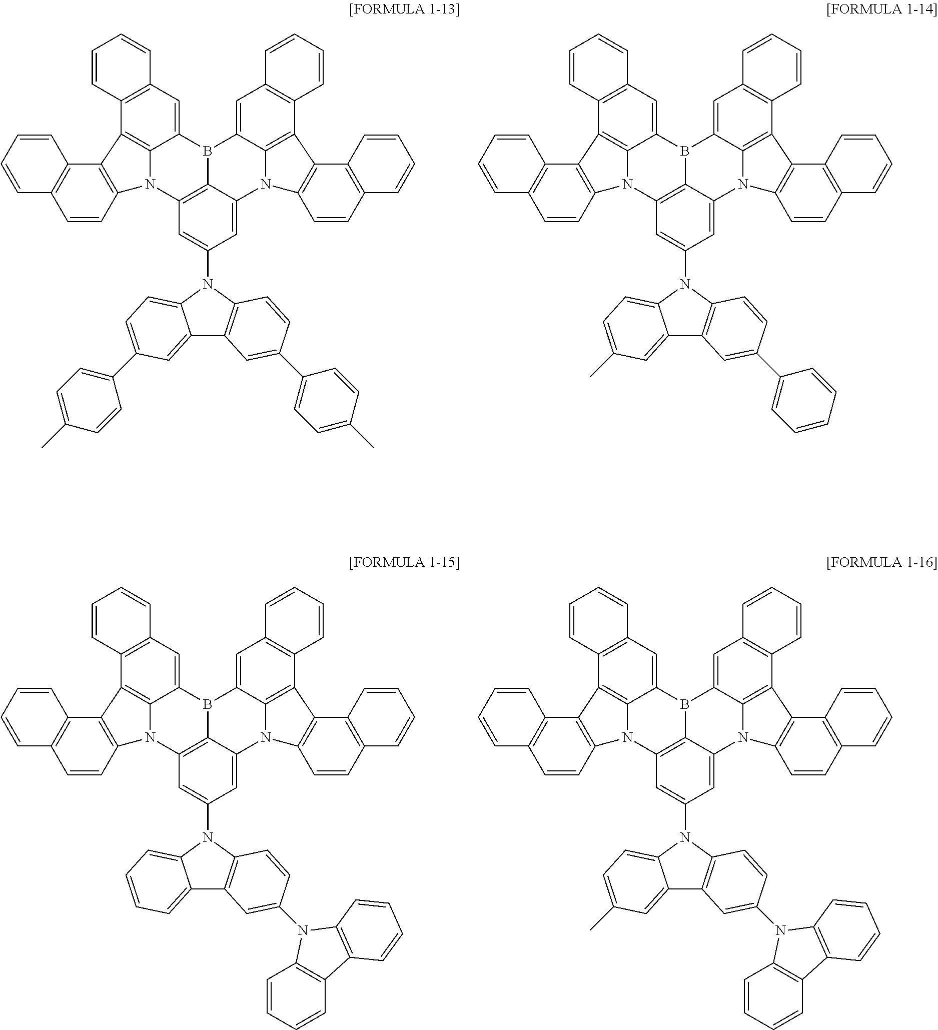

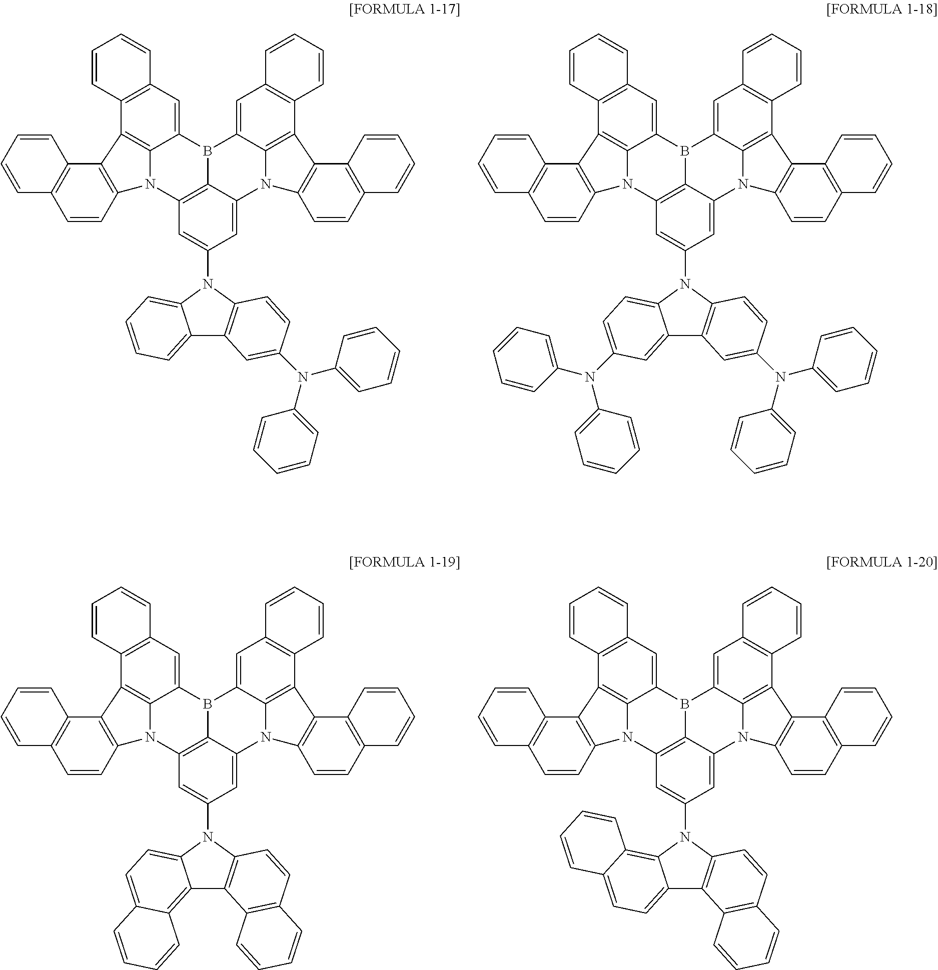

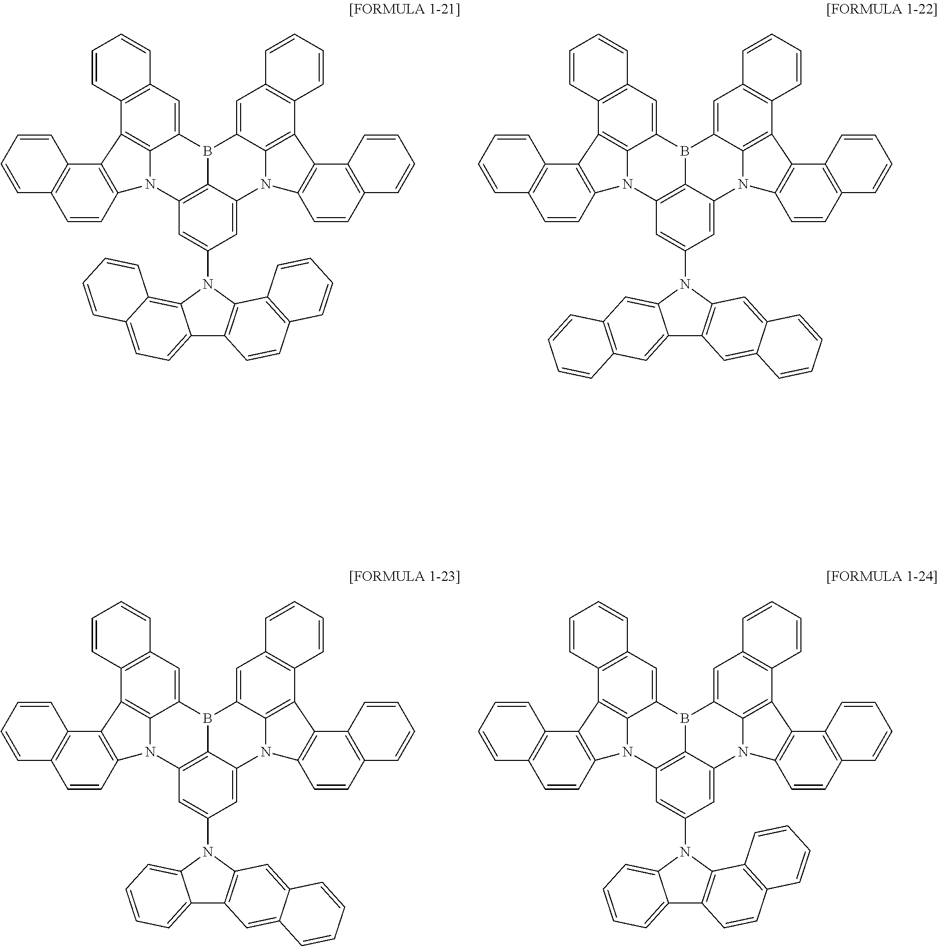 [SMILES: c1ccc2c(c1)ccc1c2c2c3ccccc3cc3c2n1-c1cc(-n2c4c5ccccc5ccc4c4ccc5ccccc5c42)cc2c1B3c1cc3ccccc3c3c4c5ccccc5ccc4n-2c13 ; c1ccc2cc3c(cc2c1)c1cc2ccccc2cc1n3-c1cc2c3c(c1)-n1c4ccc5ccccc5c4c4c5ccccc5cc(c41)B3c1cc3ccccc3c3c4c5ccccc5ccc4n-2c13 ; c1ccc2cc3c(cc2c1)c1ccccc1n3-c1cc2c3c(c1)-n1c4ccc5ccccc5c4c4c5ccccc5cc(c41)B3c1cc3ccccc3c3c4c5ccccc5ccc4n-2c13 ; c1ccc2c(c1)ccc1c2c2c3ccccc3cc3c2n1-c1cc(-n2c4ccccc4c4ccc5ccccc5c42)cc2c1B3c1cc3ccccc3c3c4c5ccccc5ccc4n-2c13]

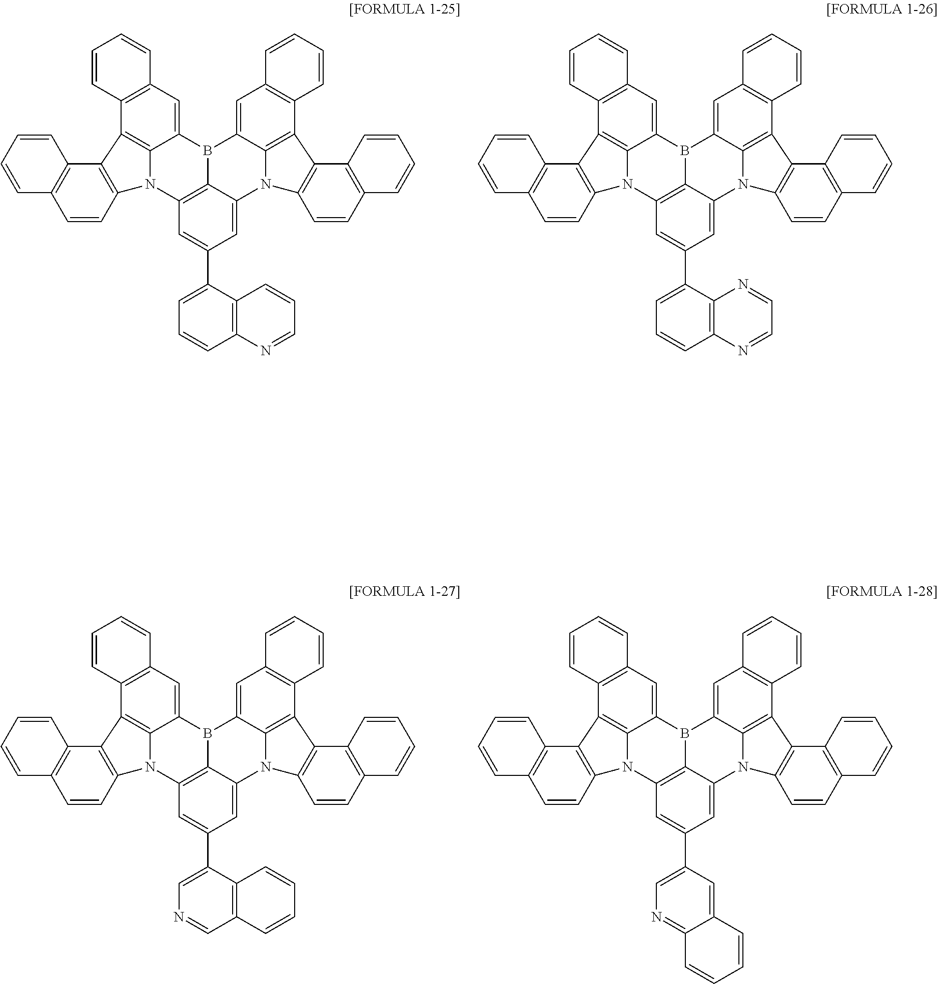 [SMILES: c1ccc2c(c1)ccc1c2c2c3ccccc3cc3c2n1-c1cc(-c2cccc4ncccc24)cc2c1B3c1cc3ccccc3c3c4c5ccccc5ccc4n-2c13 ; c1ccc2c(c1)ccc1c2c2c3ccccc3cc3c2n1-c1cc(-c2cccc4nccnc24)cc2c1B3c1cc3ccccc3c3c4c5ccccc5ccc4n-2c13 ; c1ccc2c(-c3cc4c5c(c3)-n3c6ccc7ccccc7c6c6c7ccccc7cc(c63)B5c3cc5ccccc5c5c6c7ccccc7ccc6n-4c35)cncc2c1 ; c1ccc2ncc(-c3cc4c5c(c3)-n3c6ccc7ccccc7c6c6c7ccccc7cc(c63)B5c3cc5ccccc5c5c6c7ccccc7ccc6n-4c35)cc2c1]

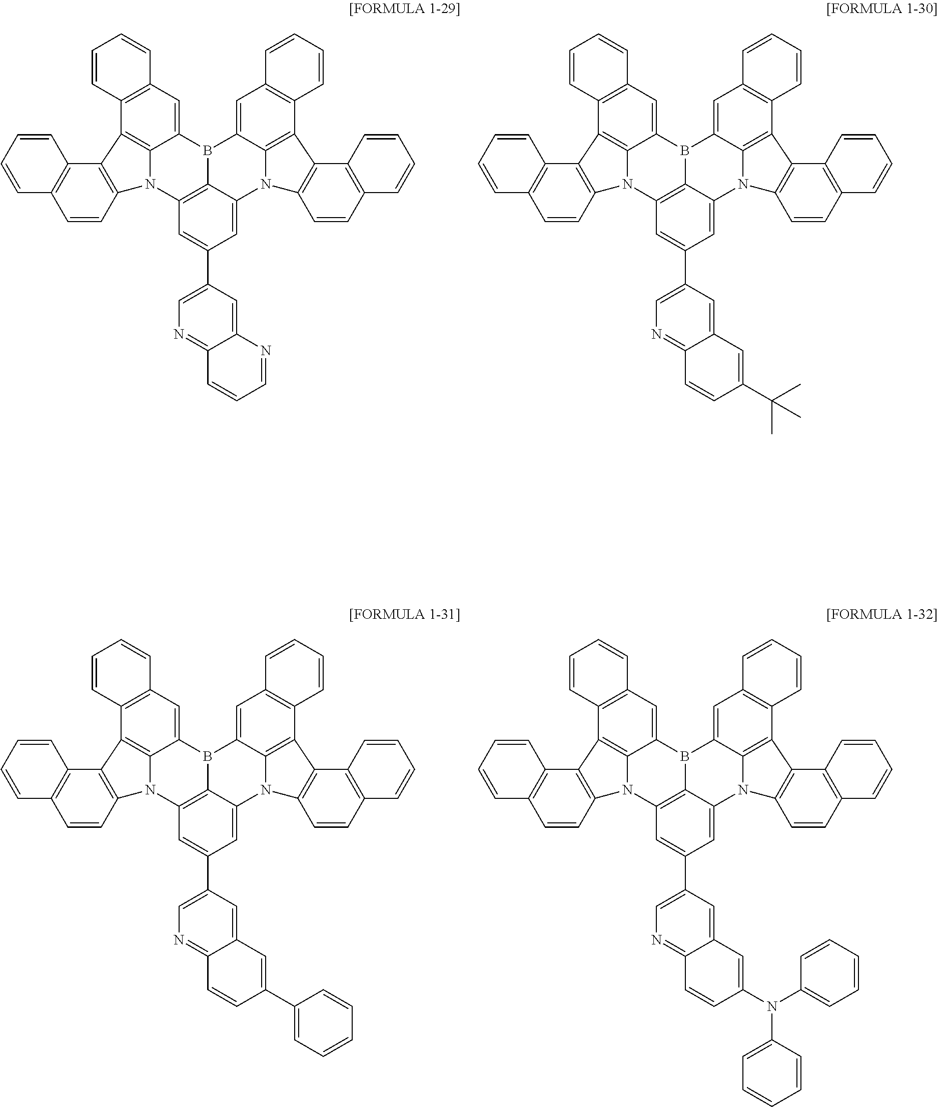 [SMILES: c1ccc2c(c1)ccc1c2c2c3ccccc3cc3c2n1-c1cc(-c2cnc4cccnc4c2)cc2c1B3c1cc3ccccc3c3c4c5ccccc5ccc4n-2c13 ; CC(C)(C)c1ccc2ncc(-c3cc4c5c(c3)-n3c6ccc7ccccc7c6c6c7ccccc7cc(c63)B5c3cc5ccccc5c5c6c7ccccc7ccc6n-4c35)cc2c1 ; c1ccc(-c2ccc3ncc(-c4cc5c6c(c4)-n4c7ccc8ccccc8c7c7c8ccccc8cc(c74)B6c4cc6ccccc6c6c7c8ccccc8ccc7n-5c46)cc3c2)cc1 ; c1ccc(N(c2ccccc2)c2ccc3ncc(-c4cc5c6c(c4)-n4c7ccc8ccccc8c7c7c8ccccc8cc(c74)B6c4cc6ccccc6c6c7c8ccccc8ccc7n-5c46)cc3c2)cc1]

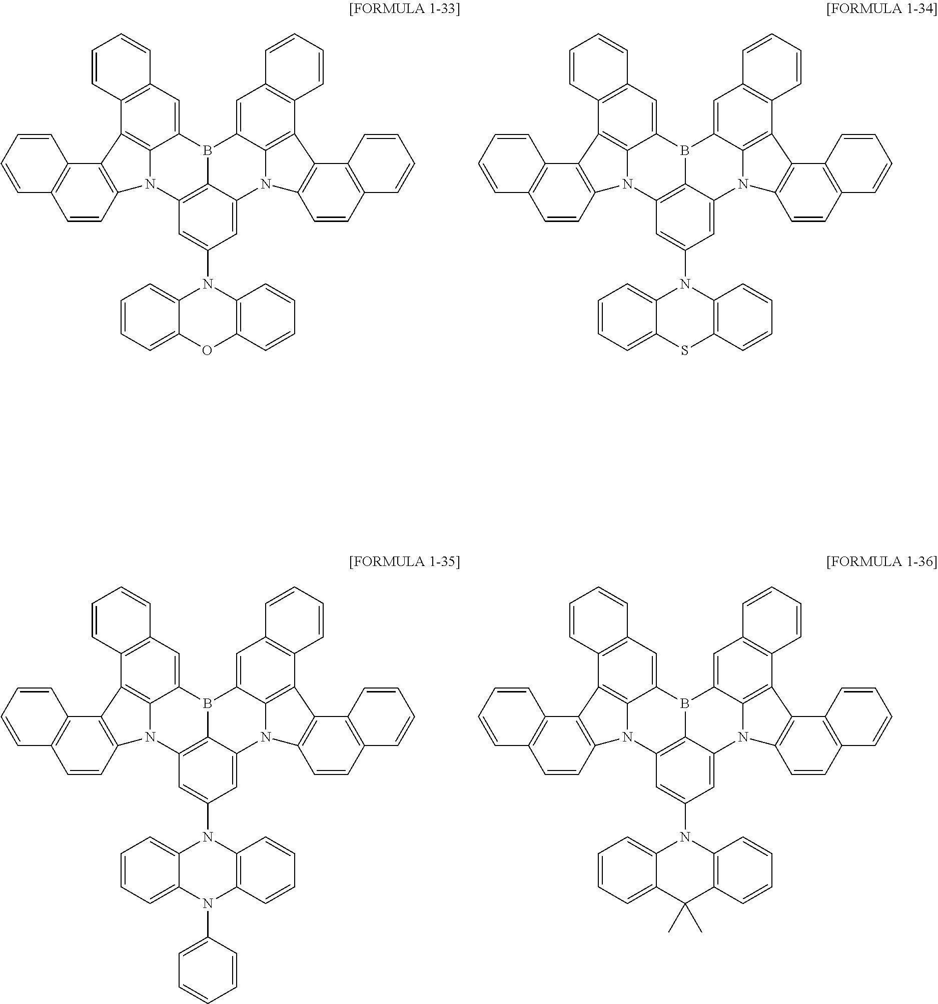 [SMILES: c1ccc2c(c1)Oc1ccccc1N2c1cc2c3c(c1)-n1c4ccc5ccccc5c4c4c5ccccc5cc(c41)B3c1cc3ccccc3c3c4c5ccccc5ccc4n-2c13 ; c1ccc2c(c1)Sc1ccccc1N2c1cc2c3c(c1)-n1c4ccc5ccccc5c4c4c5ccccc5cc(c41)B3c1cc3ccccc3c3c4c5ccccc5ccc4n-2c13 ; c1ccc(N2c3ccccc3N(c3cc4c5c(c3)-n3c6ccc7ccccc7c6c6c7ccccc7cc(c63)B5c3cc5ccccc5c5c6c7ccccc7ccc6n-4c35)c3ccccc32)cc1 ; CC1(C)c2ccccc2N(c2cc3c4c(c2)-n2c5ccc6ccccc6c5c5c6ccccc6cc(c52)B4c2cc4ccccc4c4c5c6ccccc6ccc5n-3c24)c2ccccc21]

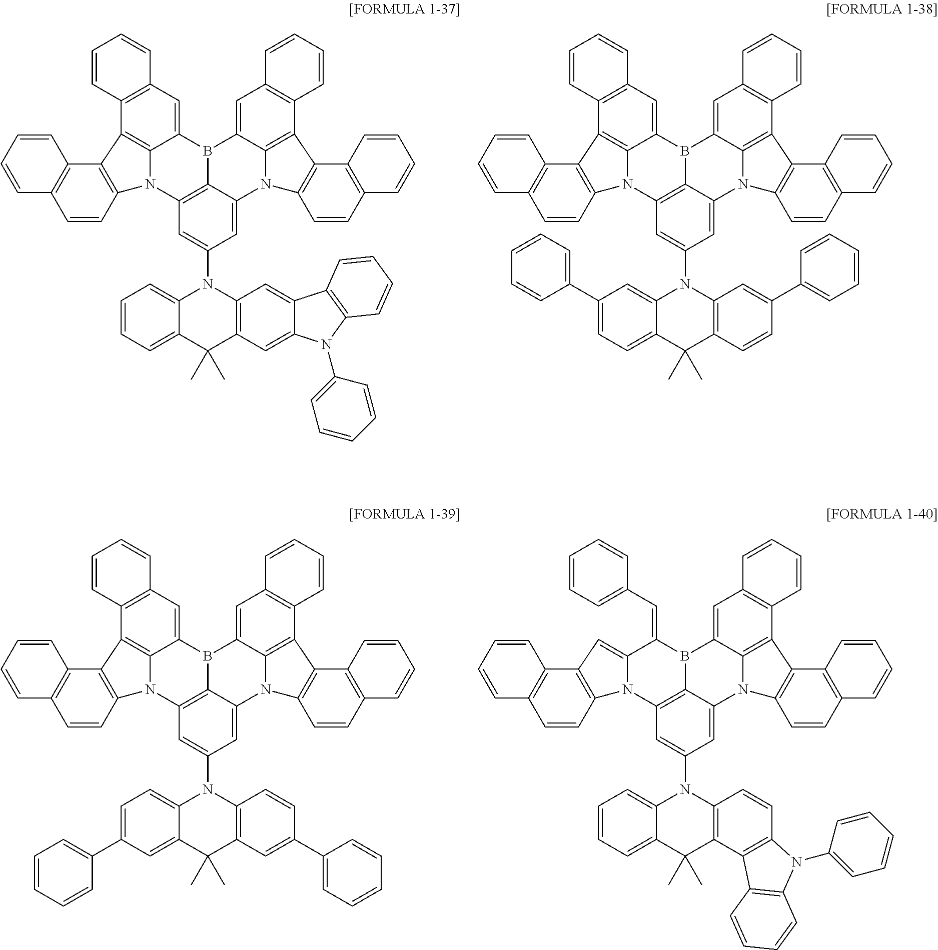

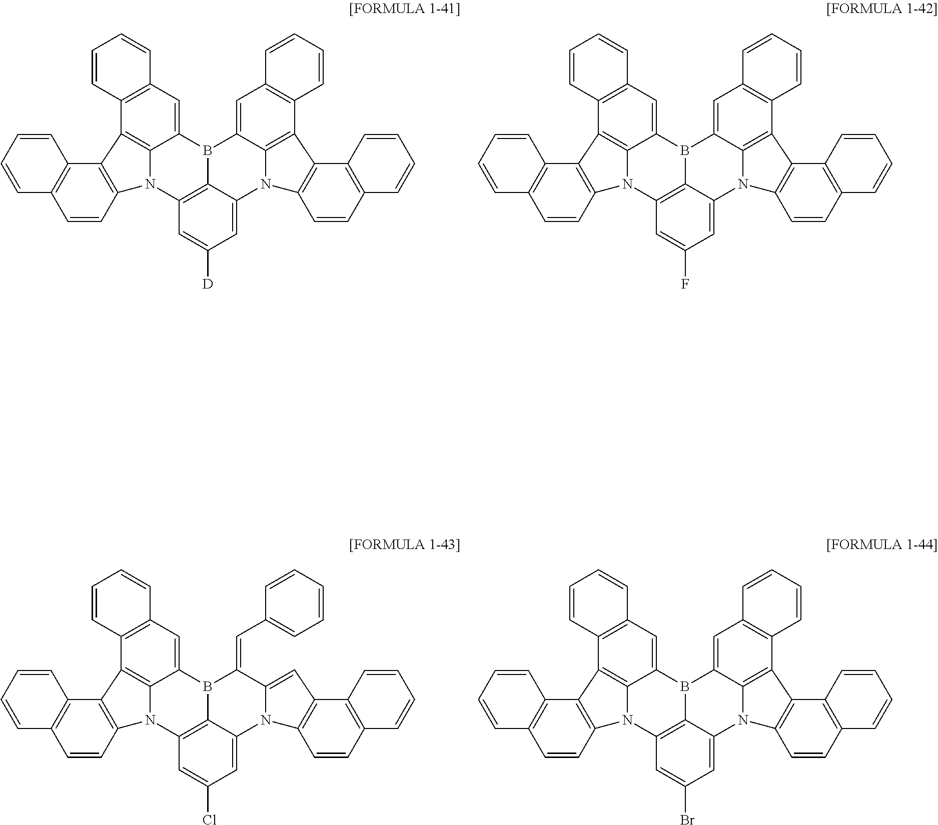 [SMILES: [2H]c1cc2c3c(c1)-n1c4ccc5ccccc5c4c4c5ccccc5cc(c41)B3c1cc3ccccc3c3c4c5ccccc5ccc4n-2c13 ; Fc1cc2c3c(c1)-n1c4ccc5ccccc5c4c4c5ccccc5cc(c41)B3c1cc3ccccc3c3c4c5ccccc5ccc4n-2c13 ; Clc1cc2c3c(c1)-n1c4ccc5ccccc5c4c4c5ccccc5cc(c41)B3/C(=C/c1ccccc1)c1cc3c4ccccc4ccc3n1-2 ; Brc1cc2c3c(c1)-n1c4ccc5ccccc5c4c4c5ccccc5cc(c41)B3c1cc3ccccc3c3c4c5ccccc5ccc4n-2c13]

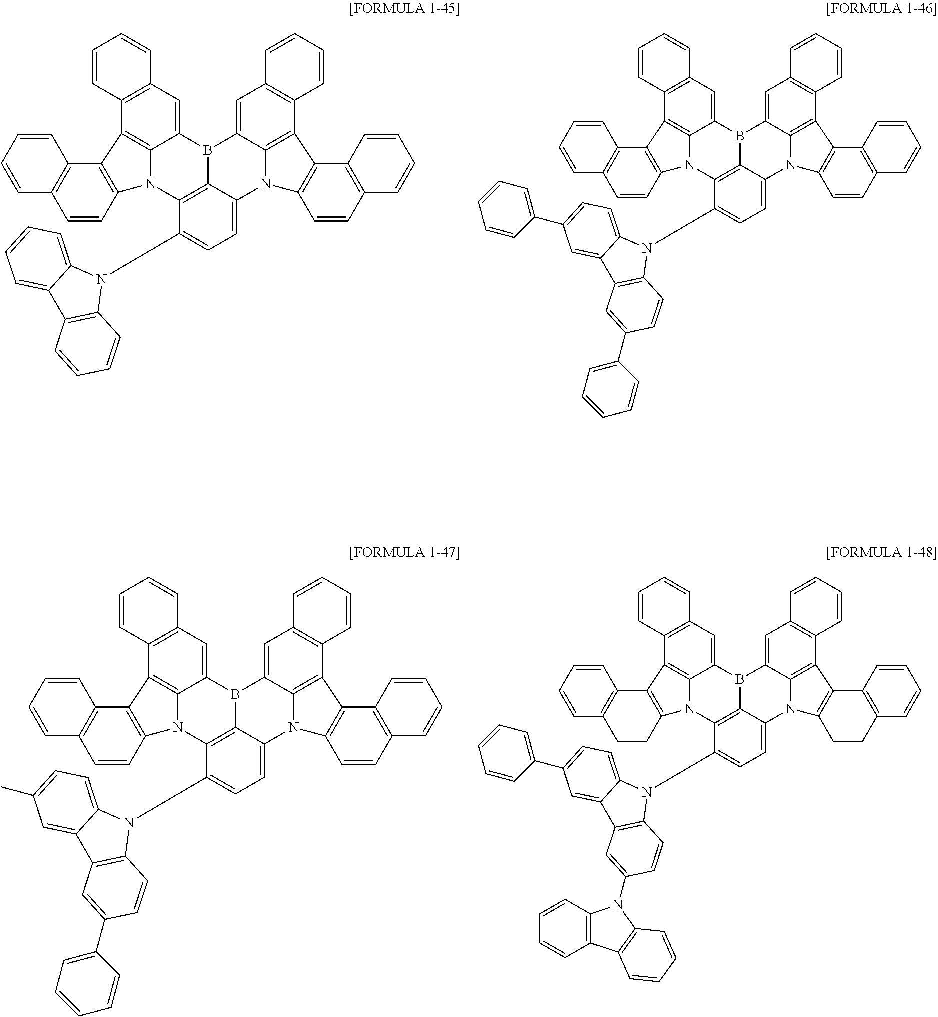 [SMILES: c1ccc2c(c1)ccc1c2c2c3ccccc3cc3c2n1-c1ccc(-n2c4ccccc4c4ccccc42)c2c1B3c1cc3ccccc3c3c4c5ccccc5ccc4n-2c13 ; c1ccc(-c2ccc3c(c2)c2cc(-c4ccccc4)ccc2n3-c2ccc3c4c2-n2c5ccc6ccccc6c5c5c6ccccc6cc(c52)B4c2cc4ccccc4c4c5c6ccccc6ccc5n-3c24)cc1 ; Cc1ccc2c(c1)c1cc(-c3ccccc3)ccc1n2-c1ccc2c3c1-n1c4ccc5ccccc5c4c4c5ccccc5cc(c41)B3c1cc3ccccc3c3c4c5ccccc5ccc4n-2c13 ; c1ccc(-c2ccc3c(c2)c2cc(-n4c5ccccc5c5ccccc54)ccc2n3-c2ccc3c4c2-n2c5c(c6c7ccccc7cc(c62)B4c2cc4ccccc4c4c6c(n-3c24)CCc2ccccc2-6)-c2ccccc2CC5)cc1]

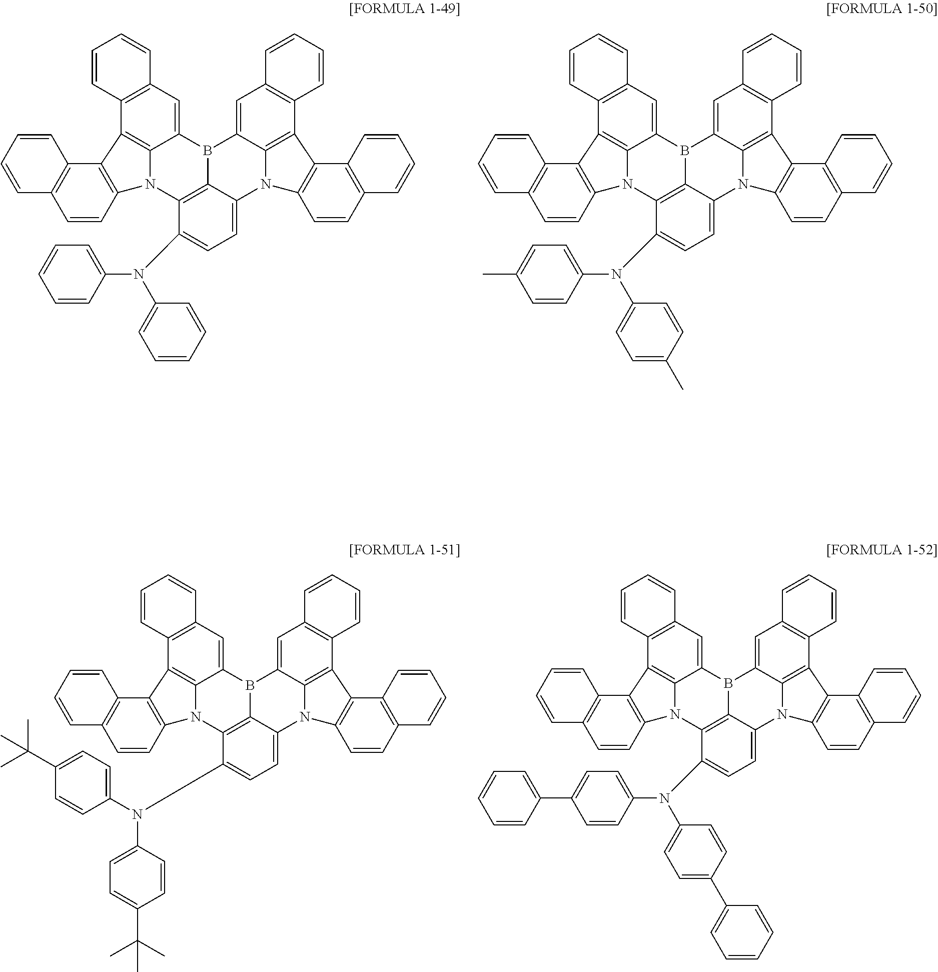 [SMILES: c1ccc(N(c2ccccc2)c2ccc3c4c2-n2c5ccc6ccccc6c5c5c6ccccc6cc(c52)B4c2cc4ccccc4c4c5c6ccccc6ccc5n-3c24)cc1 ; Cc1ccc(N(c2ccc(C)cc2)c2ccc3c4c2-n2c5ccc6ccccc6c5c5c6ccccc6cc(c52)B4c2cc4ccccc4c4c5c6ccccc6ccc5n-3c24)cc1 ; CC(C)(C)c1ccc(N(c2ccc(C(C)(C)C)cc2)c2ccc3c4c2-n2c5ccc6ccccc6c5c5c6ccccc6cc(c52)B4c2cc4ccccc4c4c5c6ccccc6ccc5n-3c24)cc1 ; c1ccc(-c2ccc(N(c3ccc(-c4ccccc4)cc3)c3ccc4c5c3-n3c6ccc7ccccc7c6c6c7ccccc7cc(c63)B5c3cc5ccccc5c5c6c7ccccc7ccc6n-4c35)cc2)cc1]

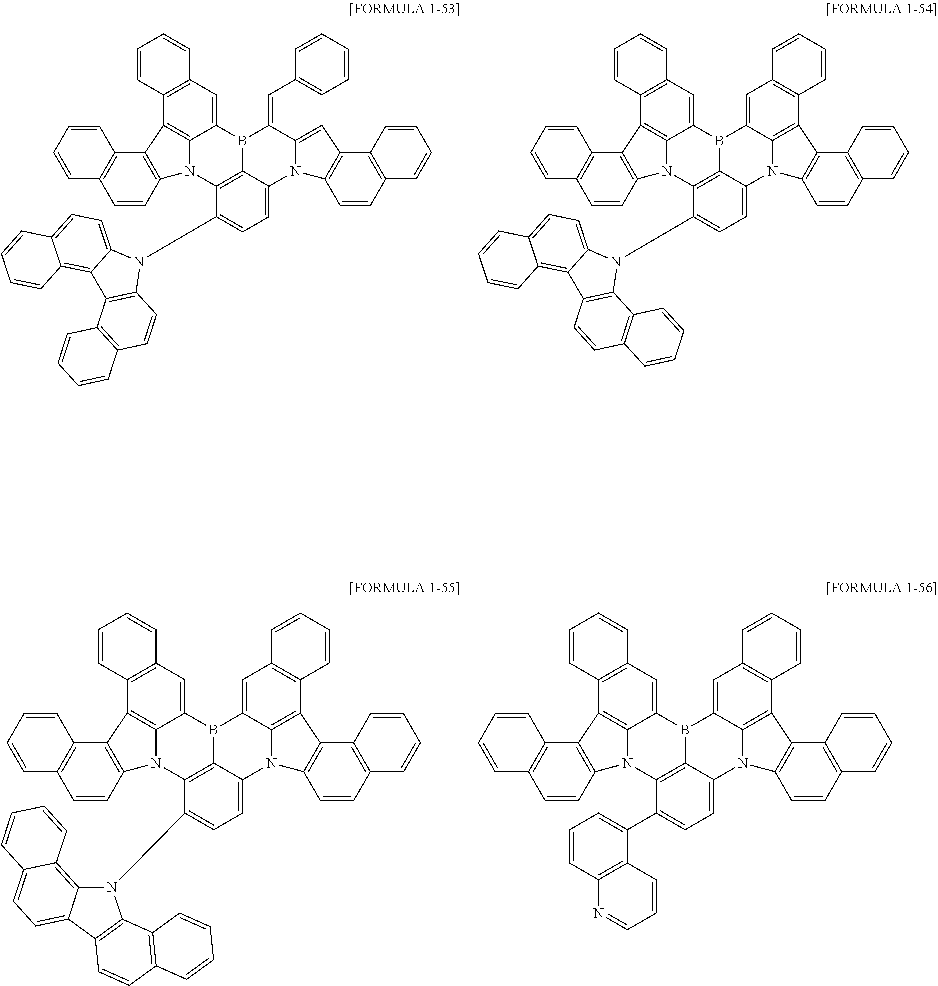 [SMILES: C(=C1\B2c3c(ccc(-n4c5ccc6ccccc6c5c5c6ccccc6ccc54)c3-n3c4ccc5ccccc5c4c4c5ccccc5cc2c43)-n2c1cc1c3ccccc3ccc12)/c1ccccc1 ; c1ccc2c(c1)ccc1c2c2c3ccccc3cc3c2n1-c1ccc(-n2c4ccc5ccccc5c4c4ccc5ccccc5c42)c2c1B3c1cc3ccccc3c3c4c5ccccc5ccc4n-2c13 ; c1ccc2c(c1)ccc1c2c2c3ccccc3cc3c2n1-c1ccc(-n2c4c5ccccc5ccc4c4ccc5ccccc5c42)c2c1B3c1cc3ccccc3c3c4c5ccccc5ccc4n-2c13 ; c1ccc2c(c1)ccc1c2c2c3ccccc3cc3c2n1-c1ccc(-c2cccc4ncccc24)c2c1B3c1cc3ccccc3c3c4c5ccccc5ccc4n-2c13]

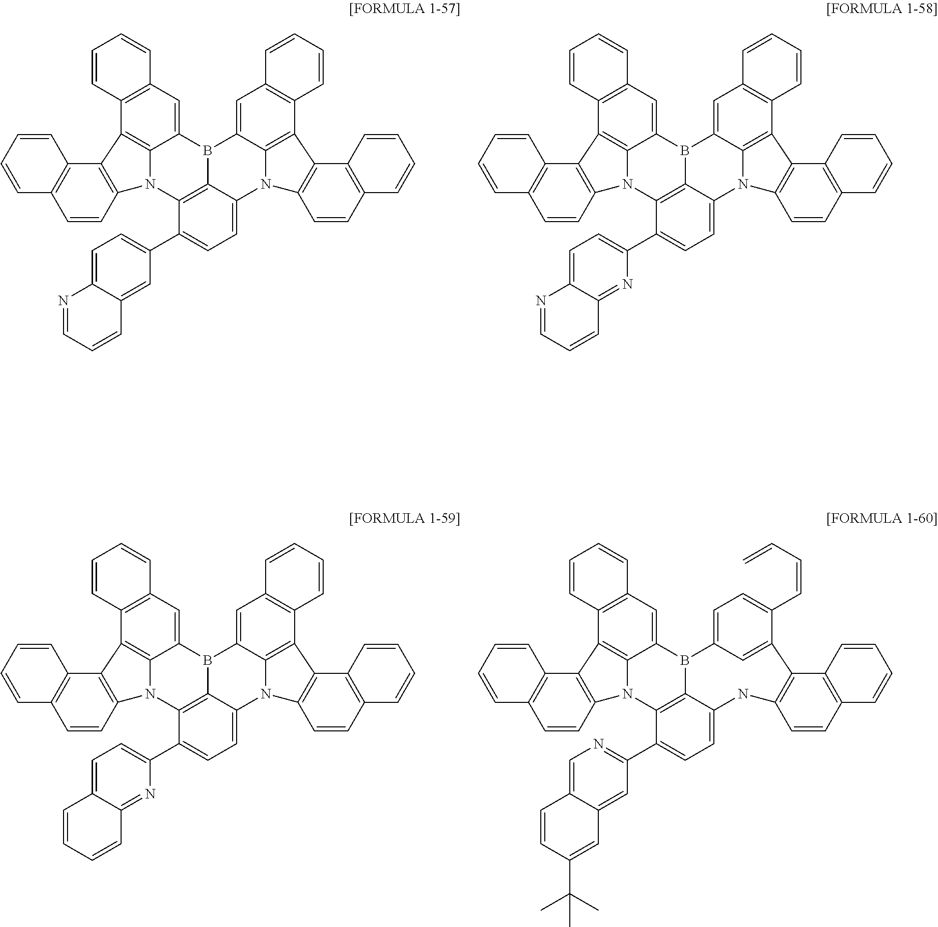 [SMILES: c1cnc2ccc(-c3ccc4c5c3-n3c6ccc7ccccc7c6c6c7ccccc7cc(c63)B5c3cc5ccccc5c5c6c7ccccc7ccc6n-4c35)cc2c1 ; c1ccc2c(c1)ccc1c2c2c3ccccc3cc3c2n1-c1ccc(-c2ccc4ncccc4n2)c2c1B3c1cc3ccccc3c3c4c5ccccc5ccc4n-2c13 ; c1ccc2nc(-c3ccc4c5c3-n3c6ccc7ccccc7c6c6c7ccccc7cc(c63)B5c3cc5ccccc5c5c6c7ccccc7ccc6n-4c35)ccc2c1 ; C=C/C=C\c1ccc2cc1-c1c(ccc3ccccc13)Nc1ccc(-c3cc4cc(C(C)(C)C)ccc4cn3)c3c1B2c1cc2ccccc2c2c4c5ccccc5ccc4n-3c12]

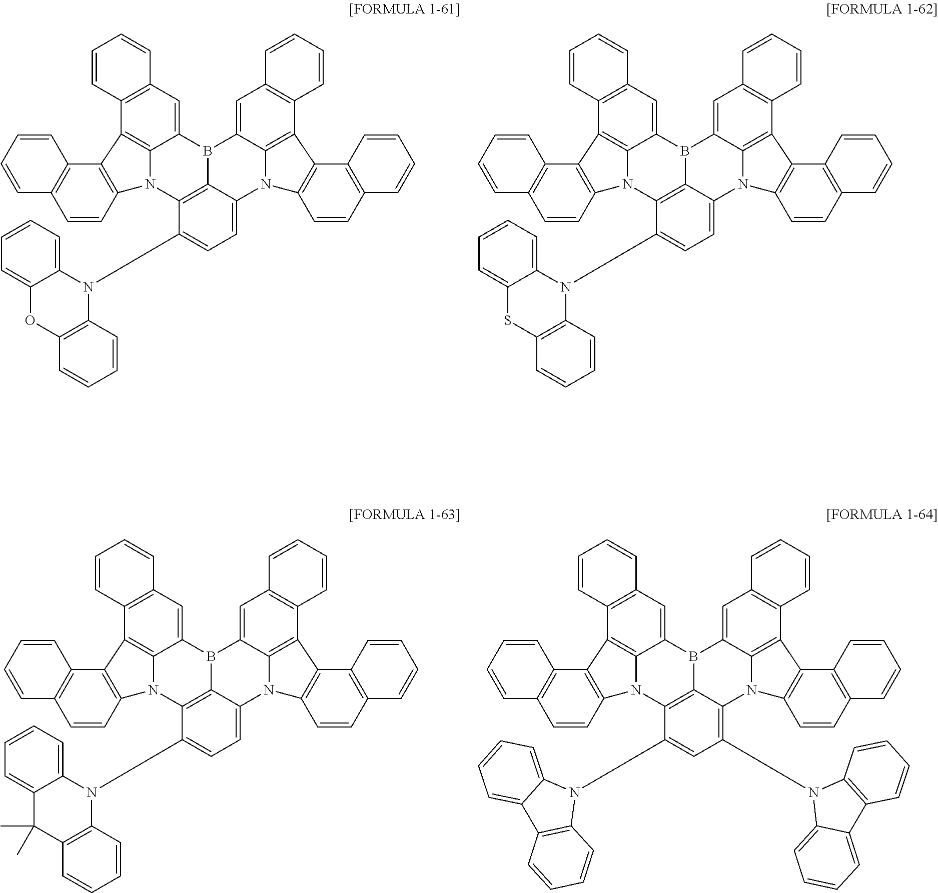 [SMILES: c1ccc2c(c1)Oc1ccccc1N2c1ccc2c3c1-n1c4ccc5ccccc5c4c4c5ccccc5cc(c41)B3c1cc3ccccc3c3c4c5ccccc5ccc4n-2c13 ; c1ccc2c(c1)Sc1ccccc1N2c1ccc2c3c1-n1c4ccc5ccccc5c4c4c5ccccc5cc(c41)B3c1cc3ccccc3c3c4c5ccccc5ccc4n-2c13 ; CC1(C)c2ccccc2N(c2ccc3c4c2-n2c5ccc6ccccc6c5c5c6ccccc6cc(c52)B4c2cc4ccccc4c4c5c6ccccc6ccc5n-3c24)c2ccccc21 ; c1ccc2c(c1)ccc1c2c2c3ccccc3cc3c2n1-c1c(-n2c4ccccc4c4ccccc42)cc(-n2c4ccccc4c4ccccc42)c2c1B3c1cc3ccccc3c3c4c5ccccc5ccc4n-2c13]

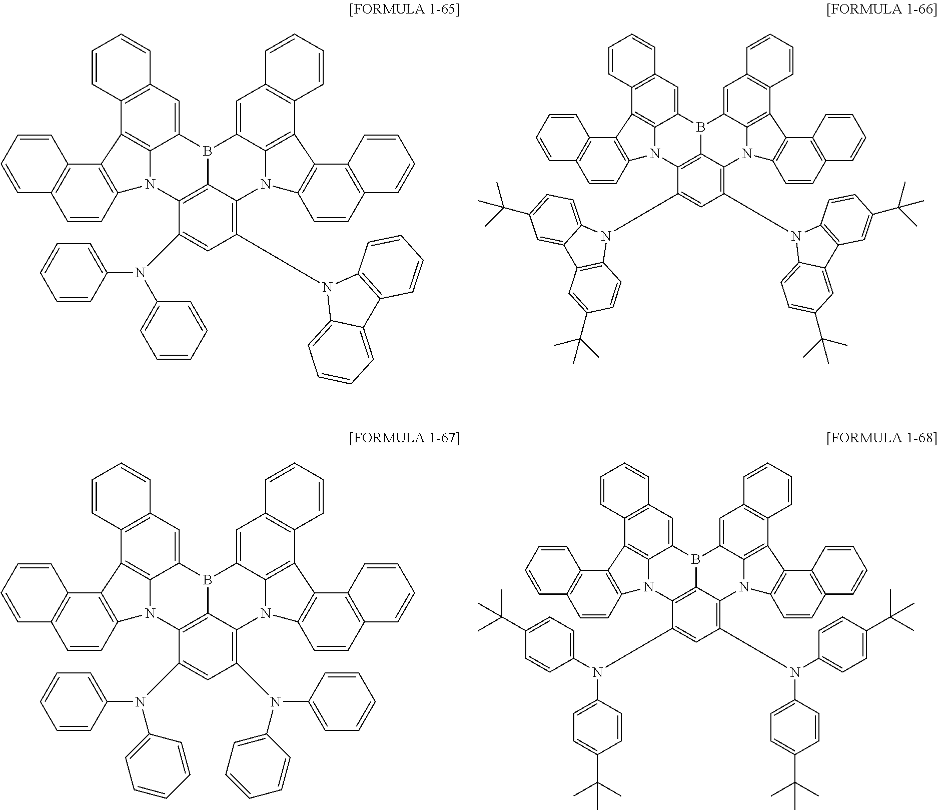

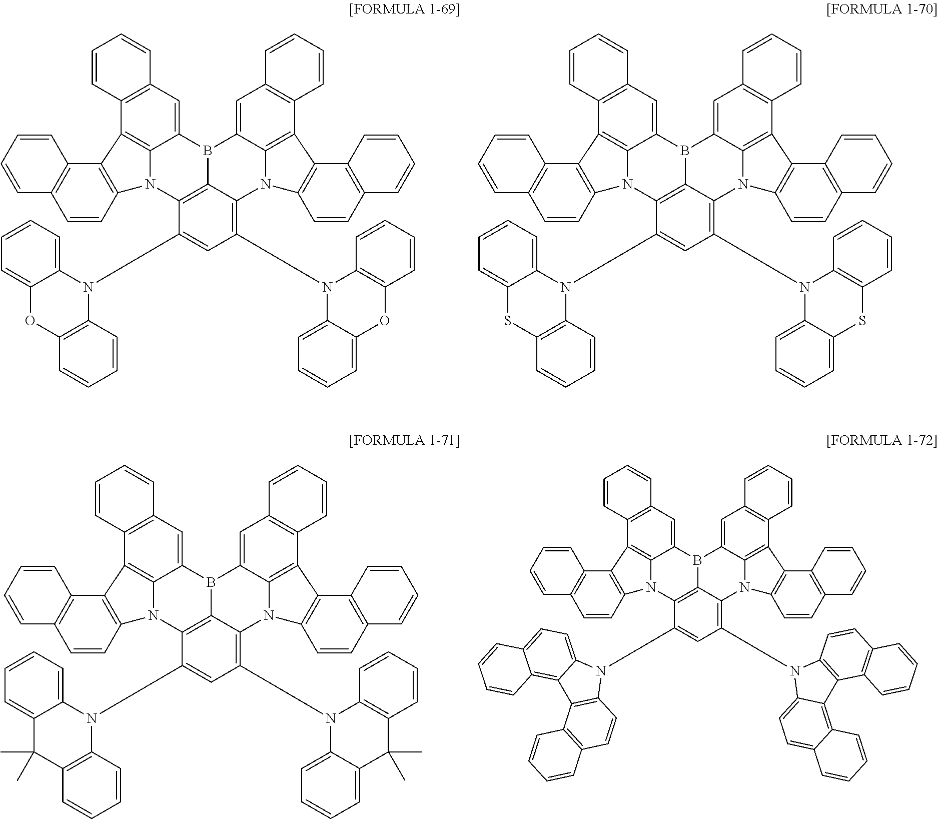

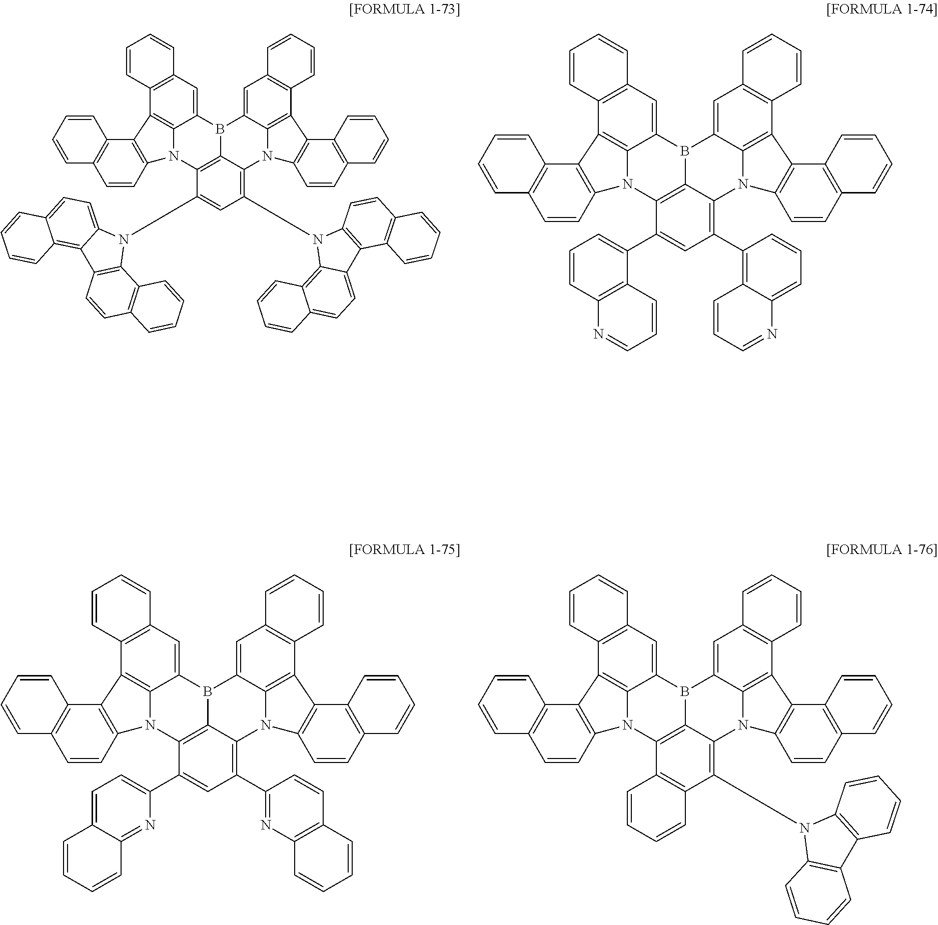 [SMILES: c1ccc2c(c1)ccc1c2c2c3ccccc3cc3c2n1-c1c(-n2c4ccc5ccccc5c4c4ccc5ccccc5c42)cc(-n2c4ccc5ccccc5c4c4ccc5ccccc5c42)c2c1B3c1cc3ccccc3c3c4c5ccccc5ccc4n-2c13 ; c1ccc2c(c1)ccc1c2c2c3ccccc3cc3c2n1-c1c(-c2cccc4ncccc24)cc(-c2cccc4ncccc24)c2c1B3c1cc3ccccc3c3c4c5ccccc5ccc4n-2c13 ; c1ccc2nc(-c3cc(-c4ccc5ccccc5n4)c4c5c3-n3c6ccc7ccccc7c6c6c7ccccc7cc(c63)B5c3cc5ccccc5c5c6c7ccccc7ccc6n-4c35)ccc2c1 ; c1ccc2c(c1)ccc1c2c2c3ccccc3cc3c2n1-c1c2c(c4ccccc4c1-n1c4ccccc4c4ccccc41)-n1c4ccc5ccccc5c4c4c5ccccc5cc(c41)B23]

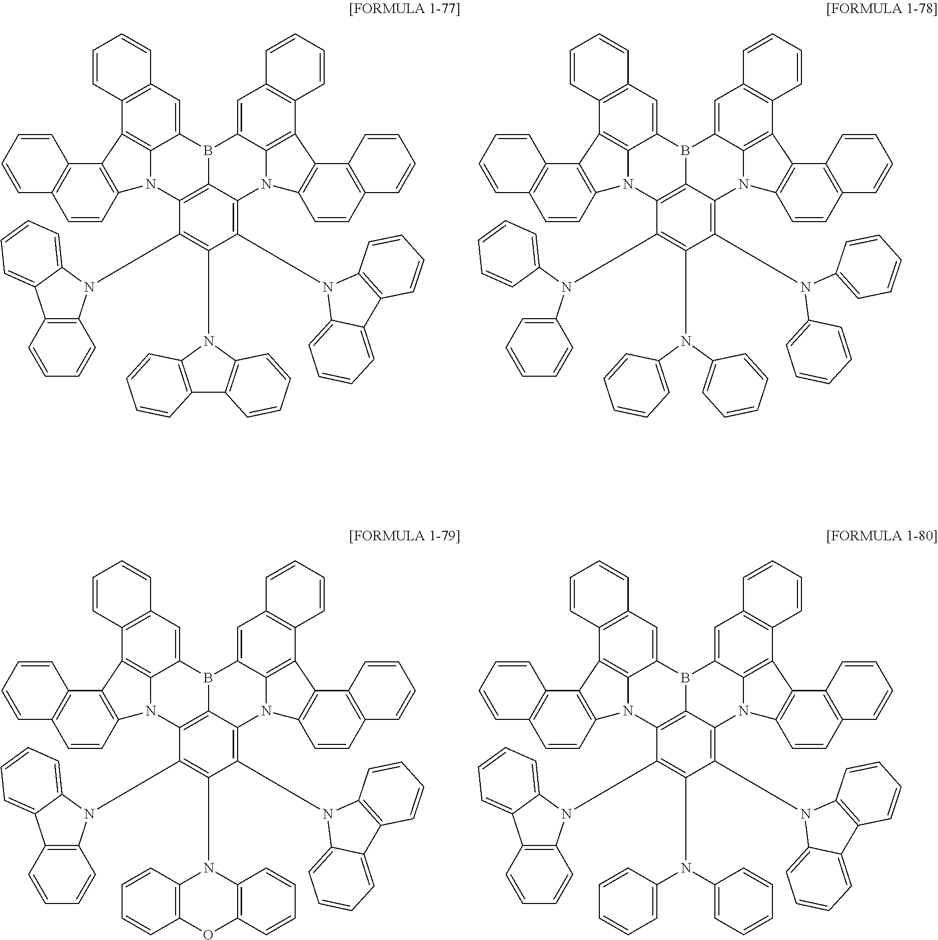

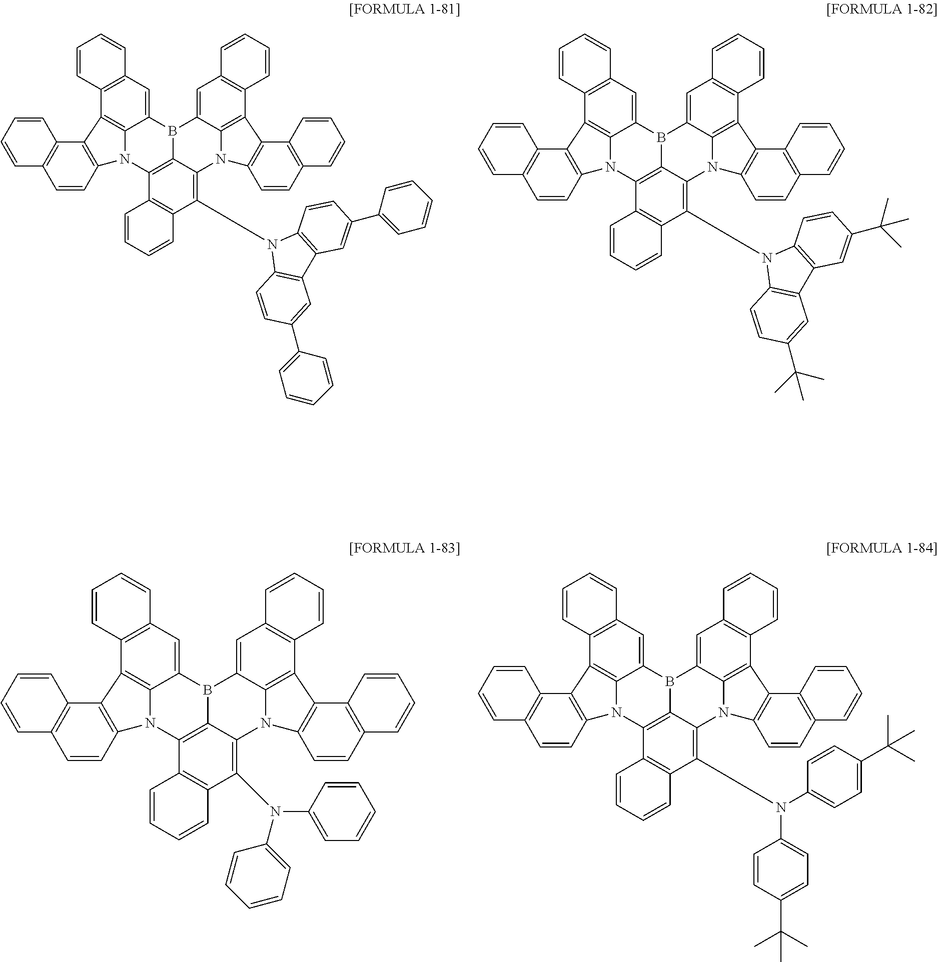

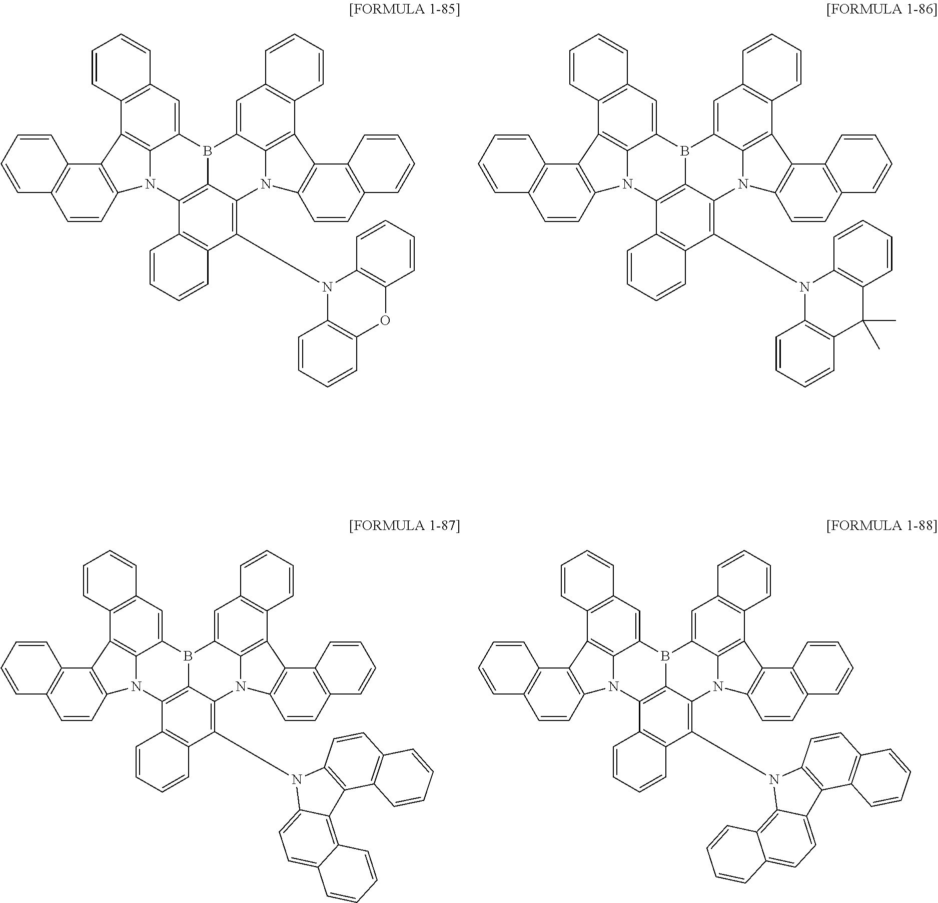 [SMILES: c1ccc2c(c1)Oc1ccccc1N2c1c2c3c(c4ccccc14)-n1c4ccc5ccccc5c4c4c5ccccc5cc(c41)B3c1cc3ccccc3c3c4c5ccccc5ccc4n-2c13 ; CC1(C)c2ccccc2N(c2c3c4c(c5ccccc25)-n2c5ccc6ccccc6c5c5c6ccccc6cc(c52)B4c2cc4ccccc4c4c5c6ccccc6ccc5n-3c24)c2ccccc21 ; c1ccc2c(c1)ccc1c2c2c3ccccc3ccc2n1-c1c2c3c(c4ccccc14)-n1c4ccc5ccccc5c4c4c5ccccc5cc(c41)B3c1cc3ccccc3c3c4c5ccccc5ccc4n-2c13 ; c1ccc2c(c1)ccc1c2c2c3ccccc3cc3c2n1-c1c2c(c4ccccc4c1-n1c4ccc5ccccc5c4c4ccc5ccccc5c41)-n1c4ccc5ccccc5c4c4c5ccccc5cc(c41)B23]

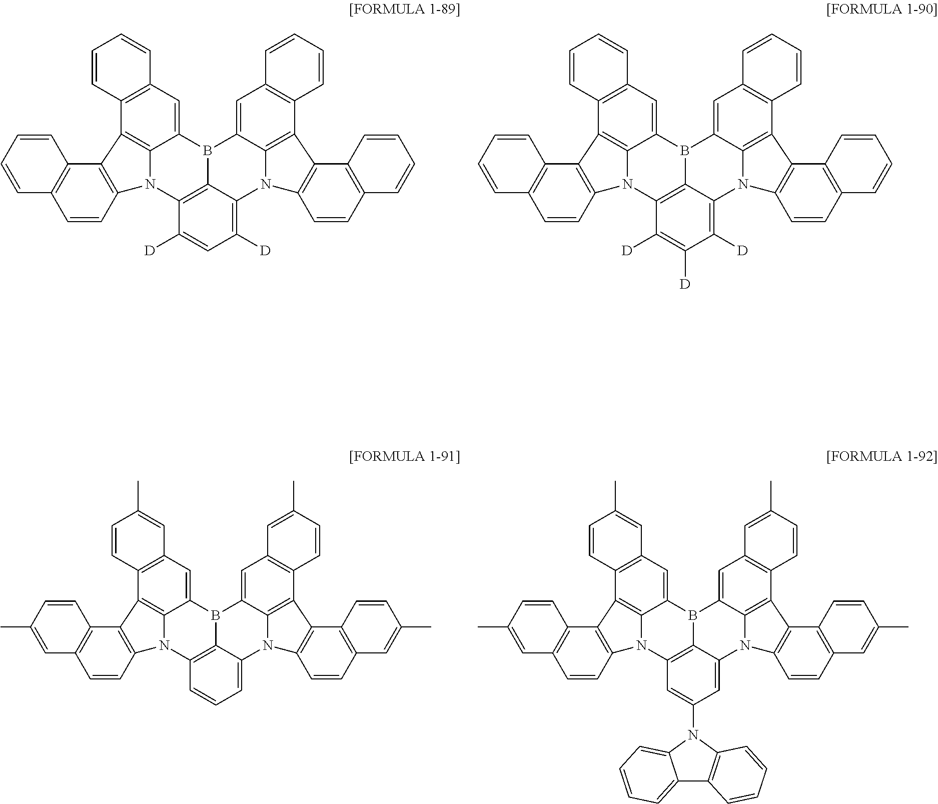

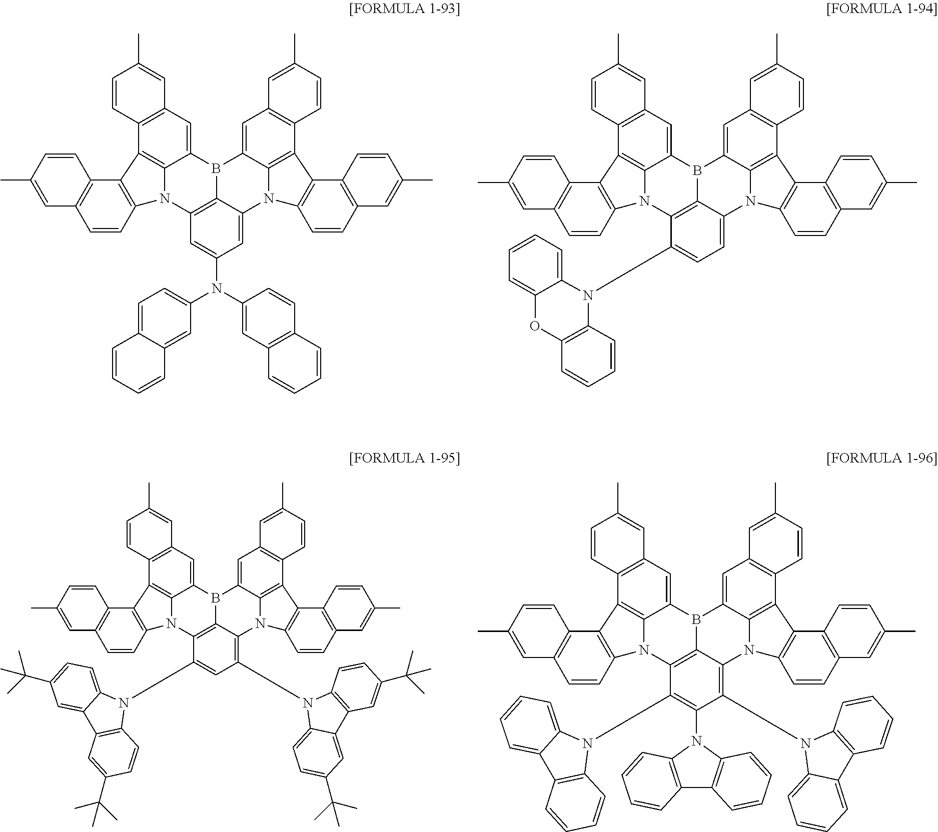

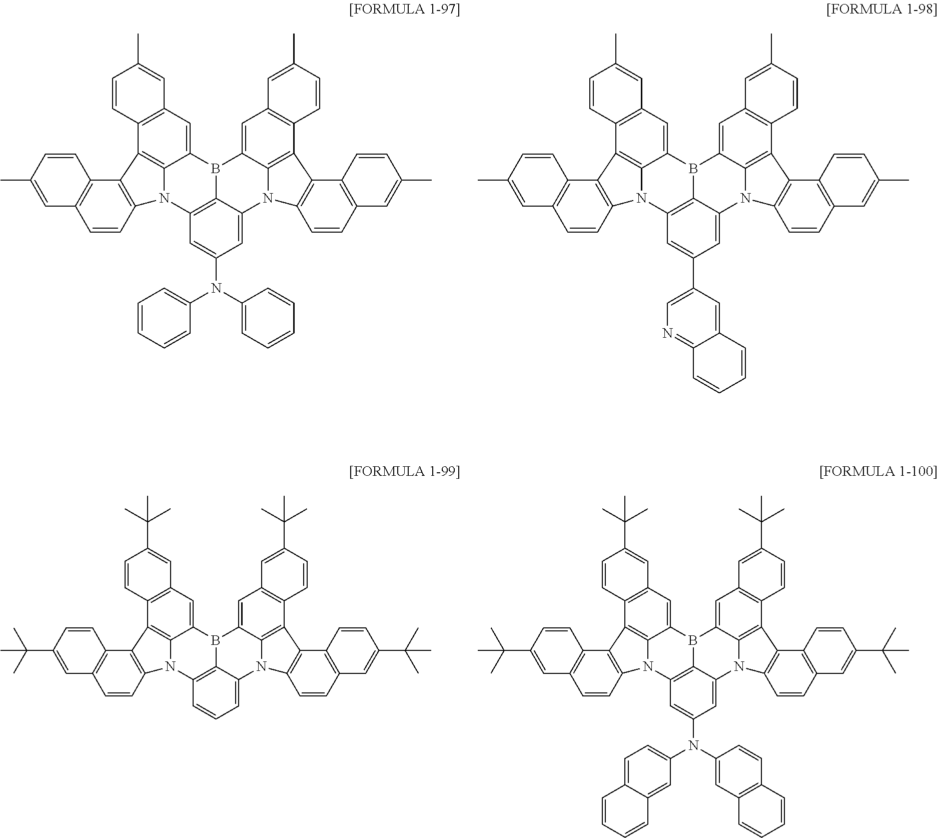

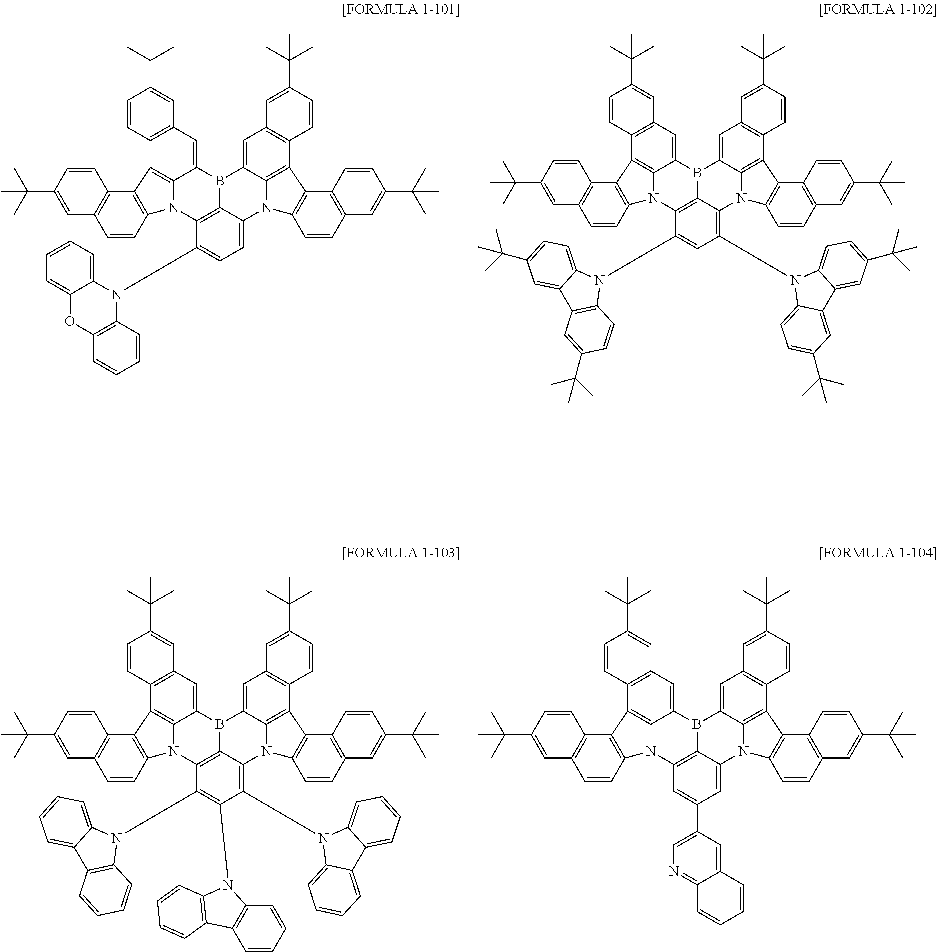

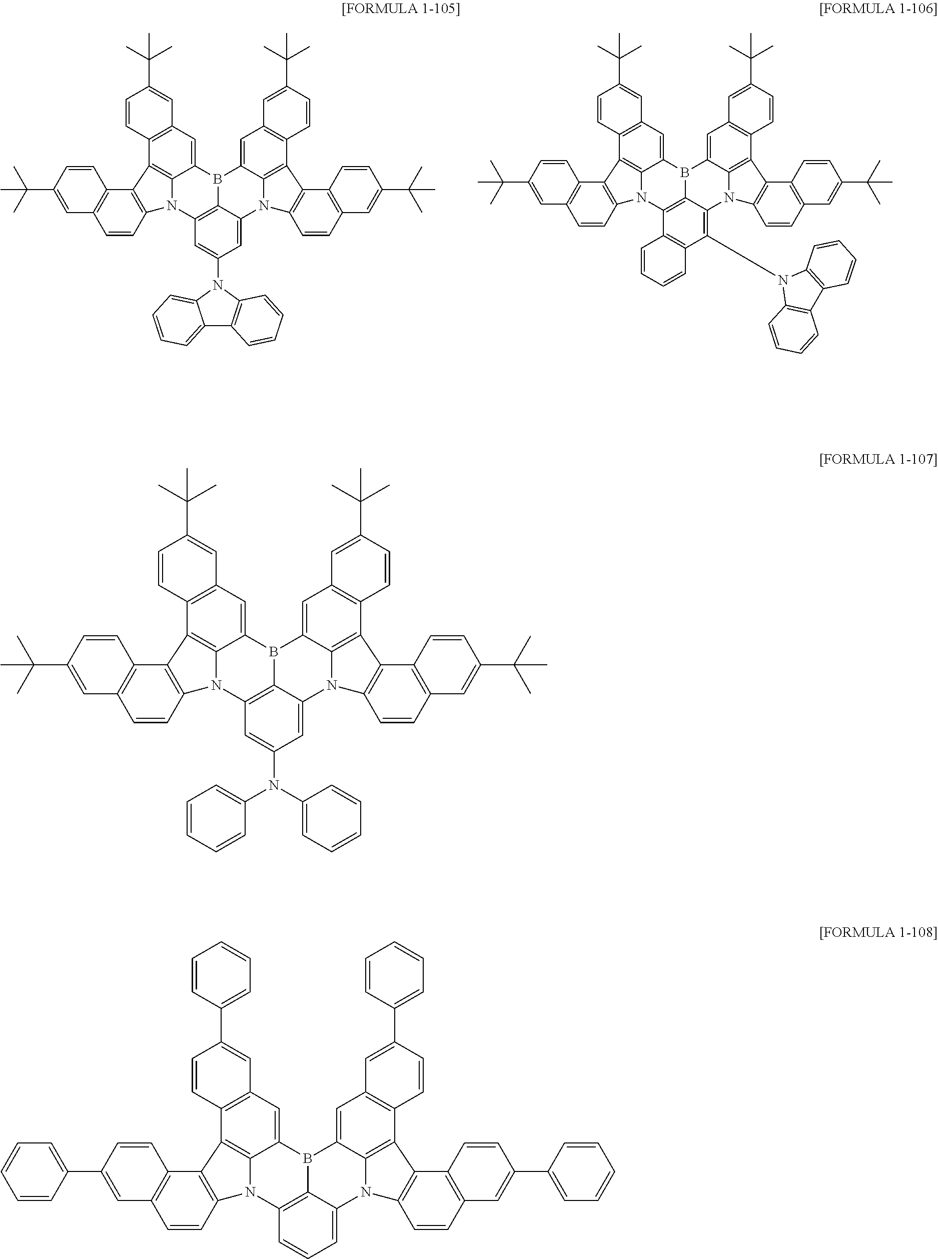

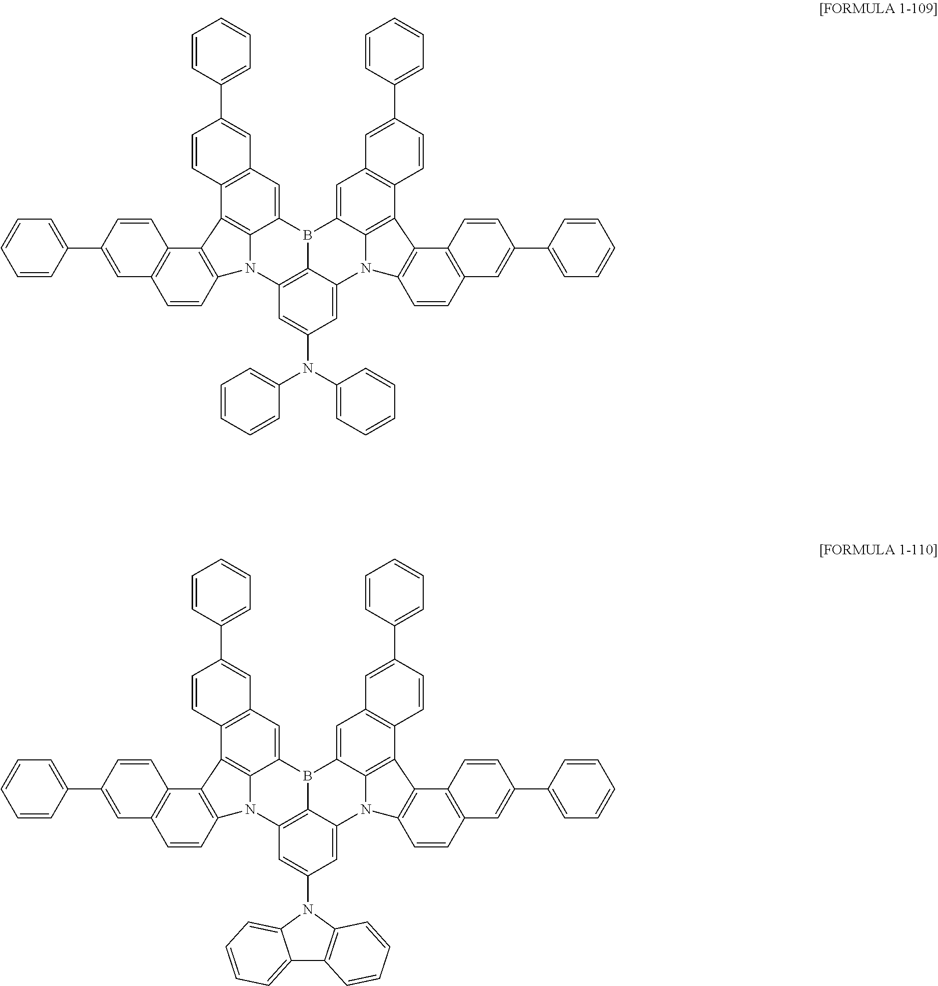 [SMILES: c1ccc(-c2ccc3c(ccc4c3c3c5ccc(-c6ccccc6)cc5cc5c3n4-c3cc(N(c4ccccc4)c4ccccc4)cc4c3B5c3cc5cc(-c6ccccc6)ccc5c5c6c7ccc(-c8ccccc8)cc7ccc6n-4c35)c2)cc1 ; c1ccc(-c2ccc3c(ccc4c3c3c5ccc(-c6ccccc6)cc5cc5c3n4-c3cc(-n4c6ccccc6c6ccccc64)cc4c3B5c3cc5cc(-c6ccccc6)ccc5c5c6c7ccc(-c8ccccc8)cc7ccc6n-4c35)c2)cc1]

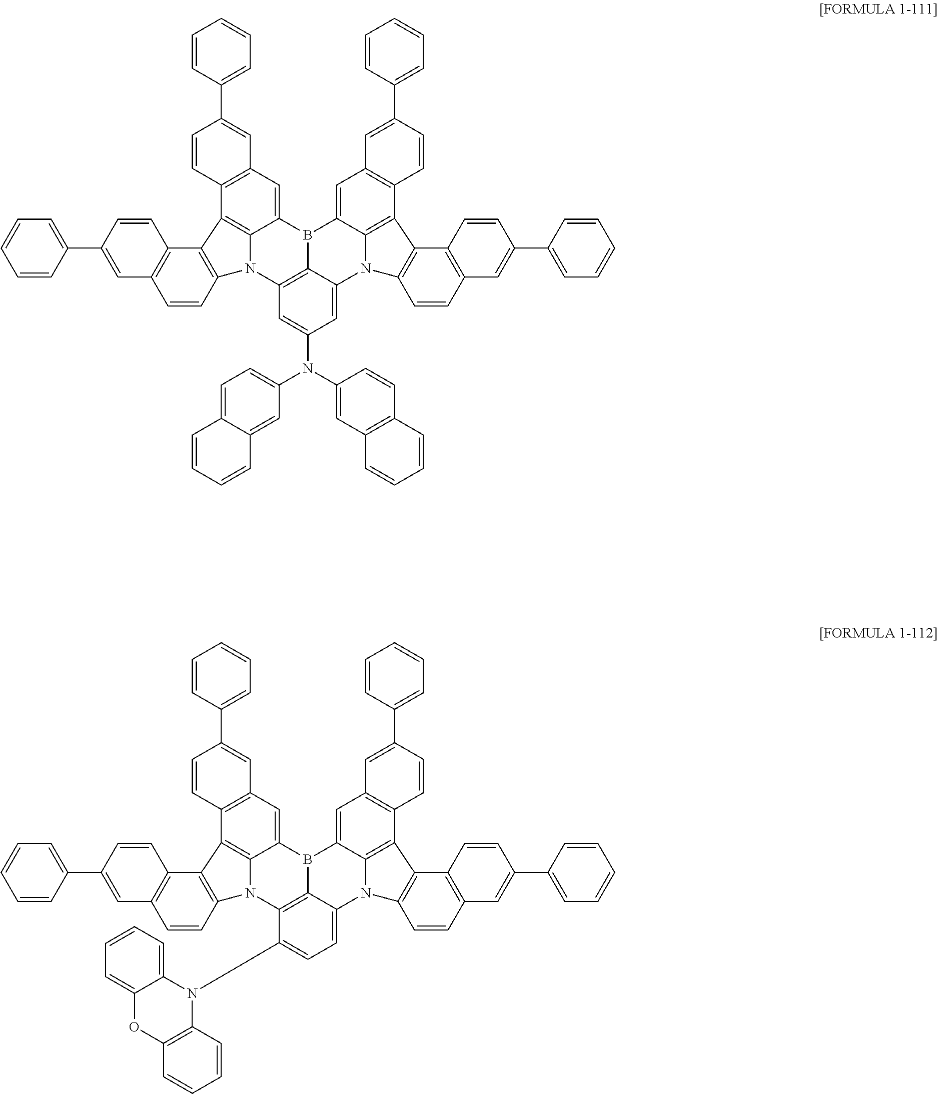 [SMILES: c1ccc(-c2ccc3c(ccc4c3c3c5ccc(-c6ccccc6)cc5cc5c3n4-c3cc(N(c4ccc6ccccc6c4)c4ccc6ccccc6c4)cc4c3B5c3cc5cc(-c6ccccc6)ccc5c5c6c7ccc(-c8ccccc8)cc7ccc6n-4c35)c2)cc1 ; c1ccc(-c2ccc3c(ccc4c3c3c5ccc(-c6ccccc6)cc5cc5c3n4-c3ccc(N4c6ccccc6Oc6ccccc64)c4c3B5c3cc5cc(-c6ccccc6)ccc5c5c6c7ccc(-c8ccccc8)cc7ccc6n-4c35)c2)cc1]

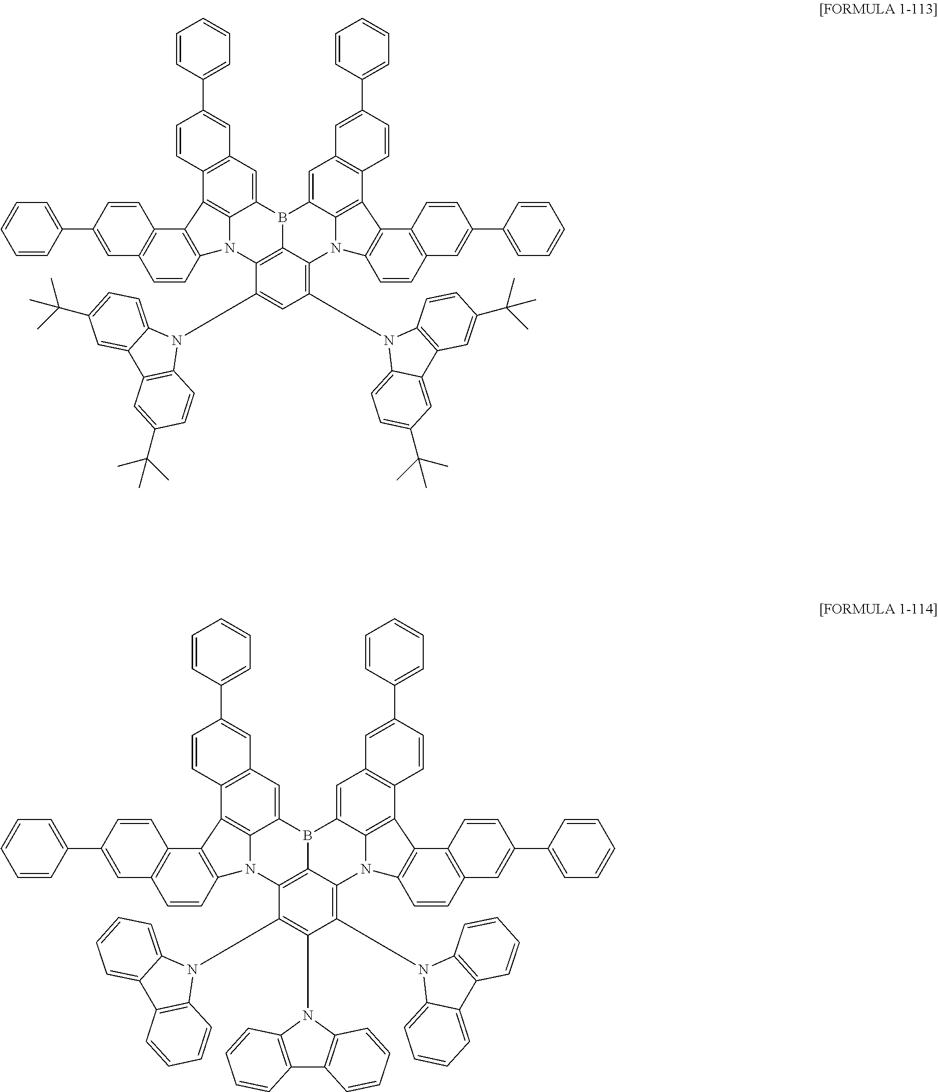 [SMILES: CC(C)(C)c1ccc2c(c1)c1cc(C(C)(C)C)ccc1n2-c1cc(-n2c3ccc(C(C)(C)C)cc3c3cc(C(C)(C)C)ccc32)c2c3c1-n1c4ccc5cc(-c6ccccc6)ccc5c4c4c5ccc(-c6ccccc6)cc5cc(c41)B3c1cc3cc(-c4ccccc4)ccc3c3c4c5ccc(-c6ccccc6)cc5ccc4n-2c13 ; c1ccc(-c2ccc3c(ccc4c3c3c5ccc(-c6ccccc6)cc5cc5c3n4-c3c4c(c(-n6c7ccccc7c7ccccc76)c(-n6c7ccccc7c7ccccc76)c3-n3c6ccccc6c6ccccc63)-n3c6ccc7cc(-c8ccccc8)ccc7c6c6c7ccc(-c8ccccc8)cc7cc(c63)B45)c2)cc1]

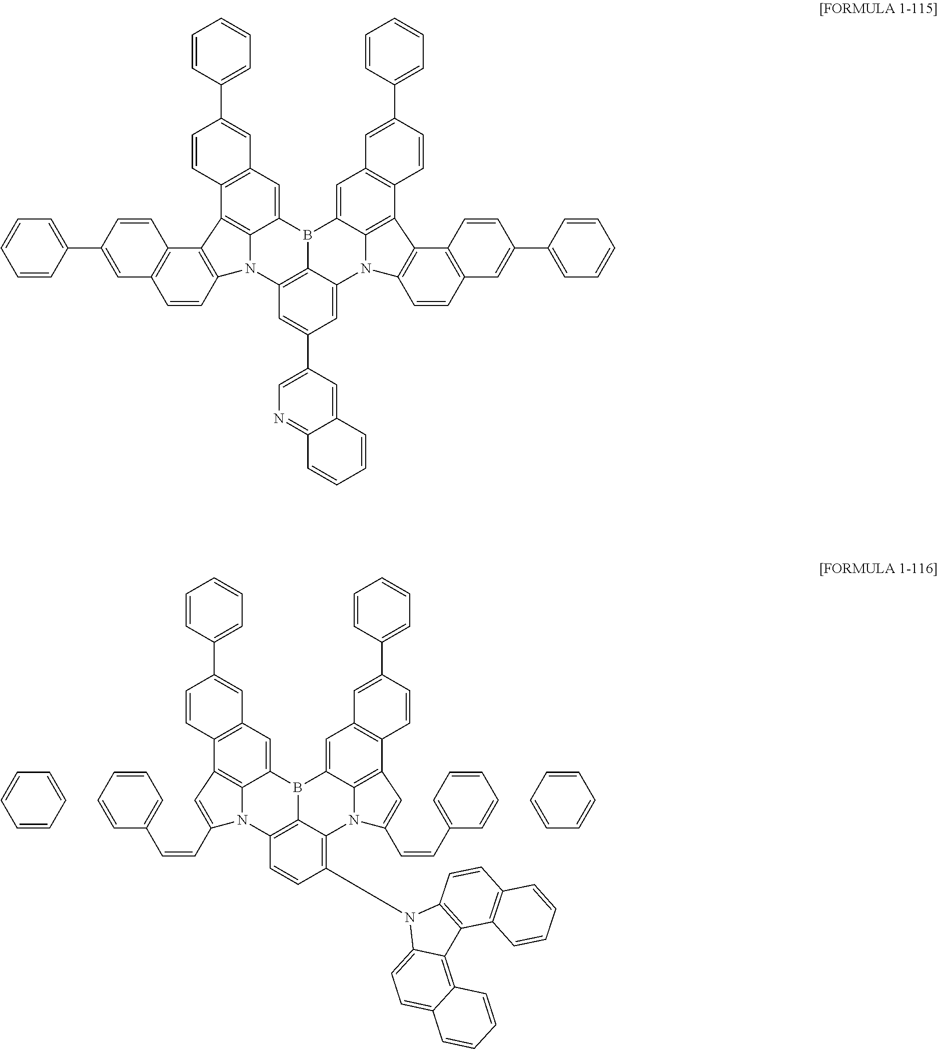

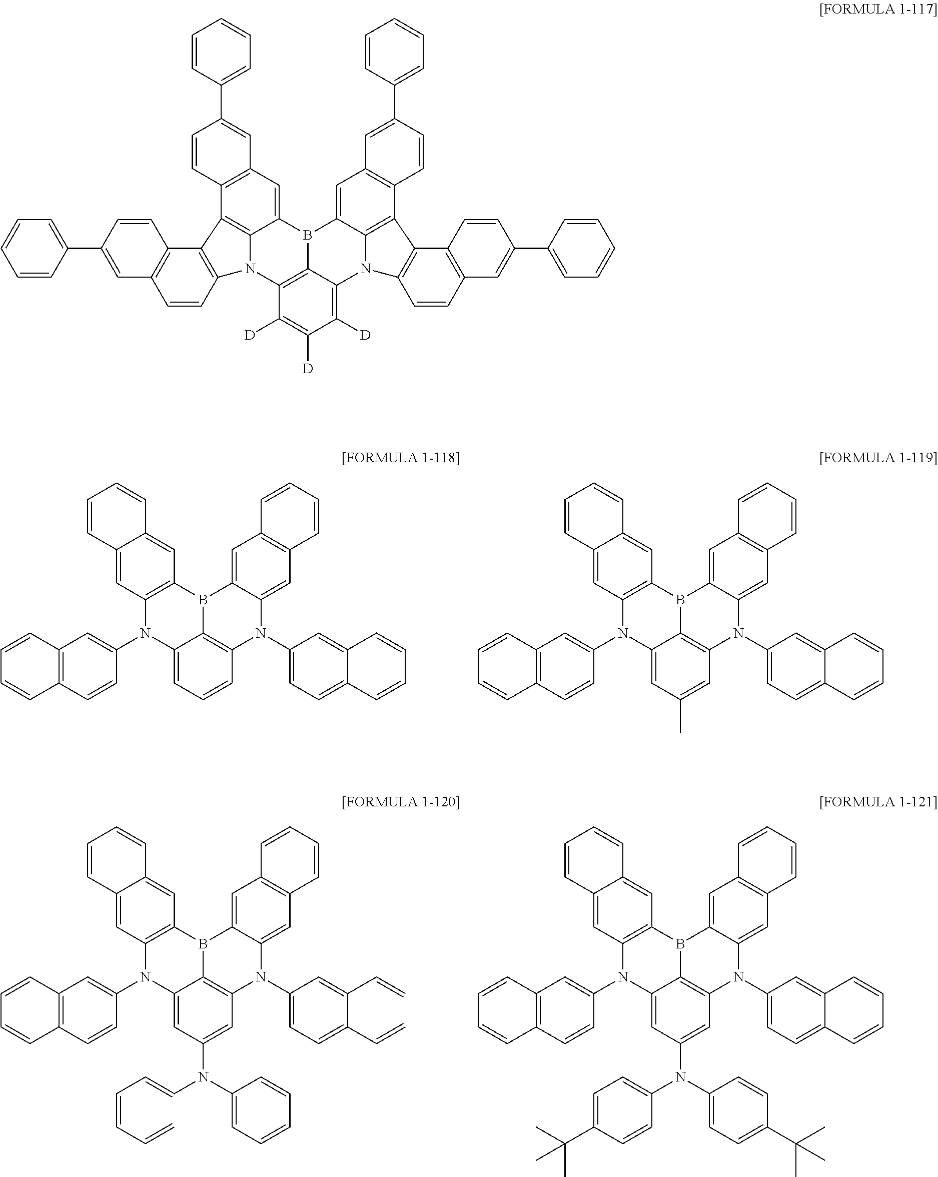

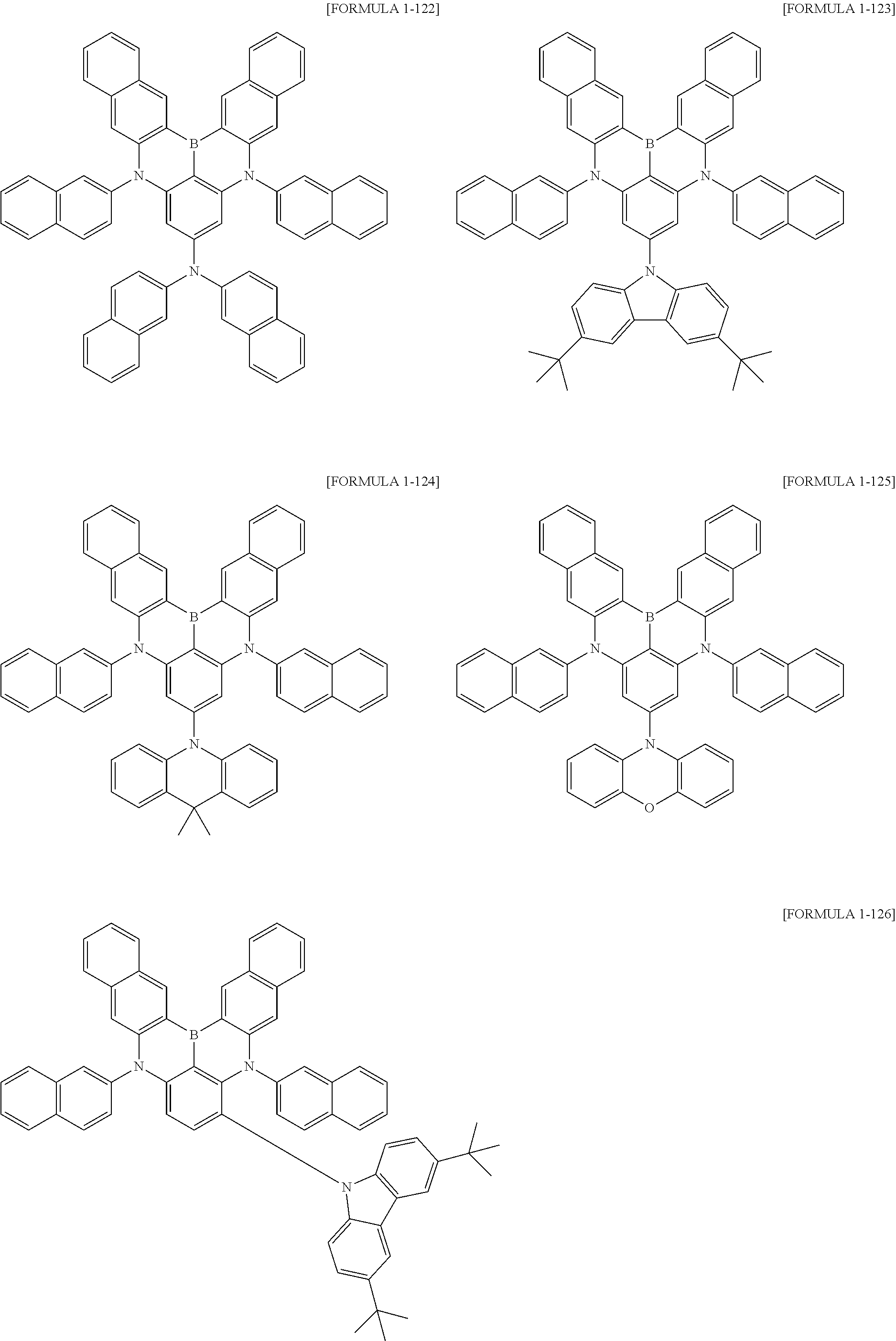

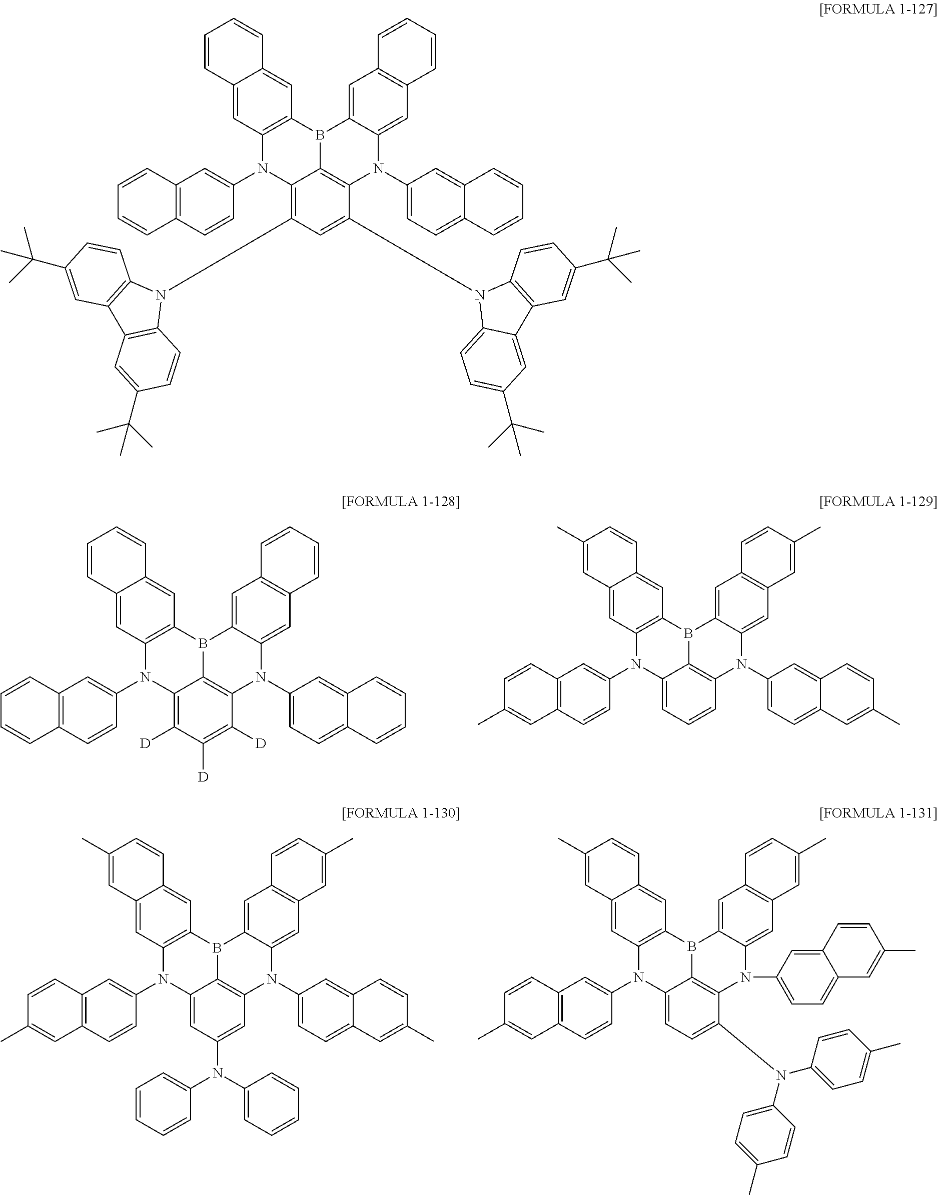

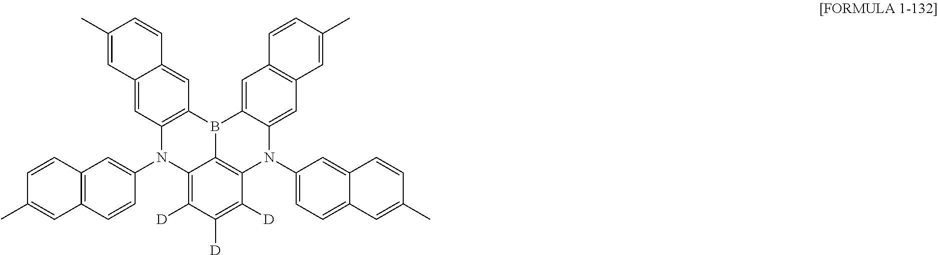

The compound may have a peak in an emission spectrum ranging from 450 to 600 nm, for example, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, or any value between two of the aforementioned values. For example, the compound may emit green light around 490 to 570 nm.

The compound may have a full width at half maximum of 40 nm or less, for example, 40 nm, 35 nm, 30 nm, 25 nm, 20 nm, 15 nm, 10 nm, 5 nm, or any value between two of the aforementioned values. As the full width at half maximum is reduced, excellent color purity may be realized.

The compound may have a singlet-triplet energy gap (ΔEst) of 0.20 eV or less, for example, 0.20 eV, 0.15 eV, 0.10 eV, 0.05 eV, or any value between two of the aforementioned values. As the energy gap is smaller, reverse intersystem crossing (RISC) between the singlet and triplet becomes easier, and thus the use as a delayed fluorescence material may be excellent.

The compound may have a photoluminescence quantum yield (PLQY) of 0.90 or more, for example, 0.90 or more, 0.925 or more, 0.95 or more, or 0.975 or more. As the PLQY value increases, the efficiency of the organic light-emitting device may be improved.

These characteristic values may be attributed to the aforementioned structural properties of the compound.

### Organic Light-Emitting Device

An organic light-emitting device according to another aspect of the present invention may include a first electrode; a second electrode provided to face the first electrode; and one or more organic material layers interposed between the first electrode and the second electrode, and the one or more organic material layers may include at least one of the aforementioned compounds.

The organic light-emitting device may realize a narrow full width at half maximum and high efficiency by including the organic material layer containing the aforementioned compound. Furthermore, when the boron compound exhibits delayed fluorescence properties, the device may be a delayed fluorescence organic light-emitting device.

In an example, the organic material layer may include one or more host compounds; a delayed fluorescent or phosphorescent compound; and a light-emitting layer including the aforementioned boron compound. The characteristics of the organic light-emitting device may depend on the host and dopant material composition of the light-emitting layer, and when a delayed fluorescent dopant or a phosphorescent dopant is applied as a host, 100% of singlet energy may be transferred to the fluorescent dopant. Therefore, when the light-emitting layer includes a host, a delayed fluorescence or phosphorescent host, and a fluorescence dopant, the device may be a delayed fluorescence photosensitive or phosphorescence photosensitive hyperfluorescent device that realizes higher efficiency than that of existing fluorescence dopant devices and high color purity of the fluorescence dopant.

As the host compound, the delayed fluorescent compound, and the phosphorescent compound, various well-known compounds may be used, and the above-described boron compound may be included in a device having such delayed fluorescence or phosphorescence properties to significantly improve its properties. For example, the delayed fluorescent compound or phosphorescent compound may be a dopant that realizes sky blue or green, but is not limited thereto.

Based on 100 parts by weight of the host compound, the content of the delayed fluorescent compound or phosphorescent compound may be in the range of 0.1 to 50 parts by weight, for example, 0.1 parts by weight, 5 parts by weight, 10 parts by weight, 15 parts by weight, 20 parts by weight, or 25 parts by weight, 30 parts by weight, 35 parts by weight, 40 parts by weight, 45 parts by weight, 50 parts by weight, or any value between two of the aforementioned values.

Based on 100 parts by weight of the delayed fluorescent compound or the phosphorescent compound, the content of the boron compound may be in the range of 0.1 to 50 parts by weight, for example, 0.1 parts by weight, 5 parts by weight, 10 parts by weight, 15 parts by weight, 20 parts by weight, 25 parts by weight, 30 parts by weight, 35 parts by weight, 40 parts by weight, 45 parts by weight, 50 parts by weight, or any value between two of the aforementioned values. The characteristics may be improved by adding a small amount of a boron compound compared to the delayed fluorescent or phosphorescent dopant.

In another example, the organic light-emitting device may include a variety of well-known hosts for a green light-emitting layer and the compound.

The first electrode may be an anode, the second electrode may be a cathode, and the organic material layer may include: a light-emitting layer containing one or more of the above-described compounds; a hole transport region interposed between the first electrode and the light-emitting layer and including at least one of a hole injection layer, a hole transport layer, and an electron blocking layer; and an electron transport region interposed between the light-emitting layer and the second electrode and including at least one of a hole blocking layer, an electron transport layer, and an electron injection layer.

A substrate may be additionally disposed below the first electrode or above the second electrode. As the substrate, a substrate used in a general organic light-emitting device may be used, and a glass substrate or a transparent plastic substrate having excellent mechanical strength, thermal stability, transparency, surface smoothness, ease of handling and water resistance may be used.

The first electrode may be a reflective electrode, a transflective electrode or a transmissive electrode. The first electrode may be formed, for example, on a substrate by depositing or sputtering a material for the first electrode. The material for the first electrode may be selected from materials having a high work function to facilitate hole injection, and examples of the material for the first electrode may include indium tin oxide (ITO), indium zinc oxide (IZO), tin oxide (SnO2), zinc oxide (ZnO), magnesium (Mg), aluminum (Al), aluminum-lithium (Al—Li), calcium (Ca), magnesium-indium (Mg—In), magnesium-silver (Mg—Ag), etc.

The hole injection layer may be formed on the first electrode using various methods such as a vacuum deposition method, a spin coating method, a cast method, an LB method and the like. When the hole injection layer is formed by the vacuum deposition method, deposition conditions vary depending on the compound used as a material for the hole injection layer, the desired structure and thermal characteristics of the hole injection layer and the like, but for example, the deposition temperature may be in the range of about 100° C. to about 500° C., a degree of vacuum may be in the range of about 10⁻⁸ to about 10⁻³ torr, and a deposition rate may be in the range of about 0.01 to about 100 Å/sec, but the present invention is not limited thereto.

When the hole injection layer is formed by the spin coating method, coating conditions vary depending on the compound used as a material for the hole injection layer, the desired structure and thermal characteristics of the hole injection layer, and a coating speed may be in the range of about 2,000 to about 5,000 rpm, a heat treatment temperature for removing a solvent after coating may be in the range of about 80° C. to 200° C., but the present invention is not limited thereto.

Conditions for forming the hole transport layer and the electron blocking layer may refer to conditions for forming the hole injection layer.

Each layer may have a thickness in the range of about 100 Å to about 10,000 Å, for example, about 100 Å to about 1,000 Å.

When the light-emitting layer includes a host and a dopant, the content of the dopant may be typically in the range of about 0.01 to about 15 parts by weight based on about 100 parts by weight of the host, but is not limited thereto.

The maximum external quantum efficiency (EQE) of the organic light-emitting device may be 20% or more, for example, 20% or more, 21% or more, 22% or more, 23% or more, 24% or more, 25% or more, 26% or more, 27% or more, 28% or more, 29% or more, or 30% or more. Unlike an existing light-emitting device having a maximum external quantum efficiency of about 10%, the organic light-emitting device may realize excellent external quantum efficiency by including the compound.

Hereinafter, the embodiments of the present invention will be described in more detail. However, the experimental results in the following show only representative experimental results of the examples, and the scope and contents of the present invention cannot be construed to be reduced or limited by the examples and the like. Each effect of the various embodiments of the present invention not expressly set forth below will be specifically described in a relevant section.

In the following, each compound n may correspond to Formula 1-n.

### Example 1: Synthesis of Compound 1

### 1) Synthesis of Intermediate 1-1

After 7H-dibenzo[c,g]carbazole (1.0 g, 3.74 mmol) and potassium carbonate (K₂CO₃, 1.2 g, 9.00 mmol) were dissolved in dimethylformamide (DMF, 10 mL), 2-chloro-1,3-difluorobenzene (222 mg, 1.50 mmol) was added thereto and stirred at 180° C. After 24 hours, the mixture was cooled to room temperature and extracted with water and dichloromethane (MC). An organic layer was dried over anhydrous magnesium sulfate, filtered, and concentrated, and then recrystallized using dichloromethane and methanol to obtain Intermediate 1-1 (820 mg, 85%).

The synthetic process of Intermediate 1-1 is briefly summarized in the following Scheme 1.

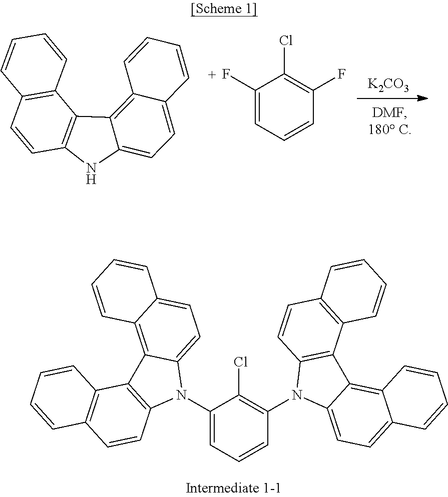

### 2) Synthesis of Compound 1

Tert-butyllithium (1.6M, 1.5 mL, 2.33 mmol) was slowly added to a tert-butylbenzene (20 mL) solution of Intermediate 1-1 (1.5 g, 1.17 mmol) at −40° C. After stirring at room temperature for 20 minutes, the mixture was further stirred at 60° C. for 2 hours. After cooling to −40° C., boron tribromide (BBr₃, 0.42 mL, 2.33 mmol) was slowly added, followed by stirring at room temperature for 30 minutes. N,N-diisopropylethylamine (1.16 mL, 3.58 mmol) was slowly added at 0° C., and the mixture was stirred at room temperature for 20 minutes, and then stirred at 120° C. overnight. The reaction mixture was cooled to room temperature, diluted with dichloromethane, filtered over magnesium silicate, and concentrated. The residue was purified by column chromatography to obtain Compound 1 (0.2 g, 15%).

The synthetic process of Compound 1 is briefly summarized in the following Scheme 2.

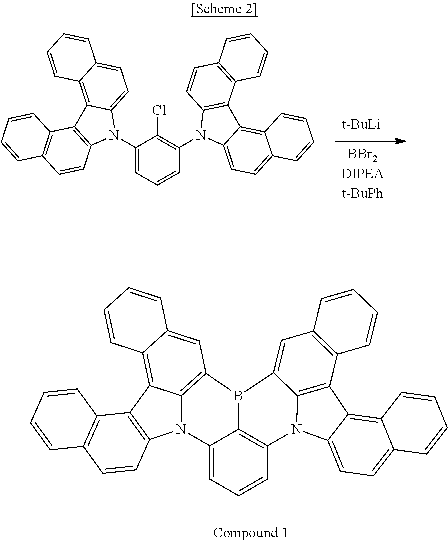 [SMILES: "t-BuLi" ; Clc1c(-n2c3ccc4ccccc4c3c3c4ccccc4ccc32)cccc1-n1c2ccc3ccccc3c2c2c3ccccc3ccc21 ; c1cc2c3c(c1)-n1c4ccc5ccccc5c4c4c5ccccc5cc(c41)B3c1cc3ccccc3c3c4c5ccccc5ccc4n-2c13]

### Example 2: Synthesis of Compound 3

### 1) Synthesis of Intermediate 2-1

After 7H-dibenzo[c,g]carbazole (1.0 g, 3.74 mmol) and potassium carbonate (K₂CO₃, 1.2 g, 9.00 mmol) were dissolved in dimethylformamide (DMF, 10 mL), 2,5-dibromo-1,3-difluorobenzene (408 mg, 1.50 mmol) was added thereto, and the mixture was stirred at 180° C. After 24 hours, the mixture was cooled to room temperature and extracted with water and methylene chloride (MC). The organic layer was dried over anhydrous magnesium sulfate, filtered and concentrated, and recrystallized using dichloromethane and methanol to obtain Intermediate 2-1 (920 mg, 80%).

The synthetic process of Intermediate 2-1 is briefly summarized in the following Scheme 3.

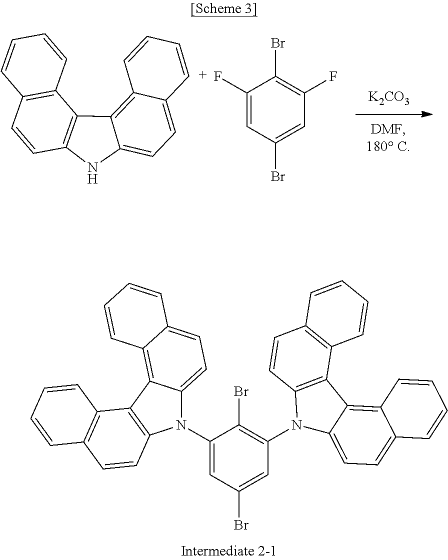

### 2) Synthesis of Intermediate 2-2

Intermediate 2-1 (1.0 g, 1.30 mmol), bis(4-(tert-butyl)phenyl)amine (370 mg, 1.30 mmol) and tert-butoxy sodium (250 mg, 2.61 mmol) were mixed in toluene (15 mL), and the atmosphere was replaced with argon. Pd(OAc)₂ (29 mg, 0.13 mmol) and tributylphosphine (50% toluene solution, 0.12 mL, 0.26 mmol) were added thereto and stirred at 110 degrees for 20 hours. After cooling to room temperature, the mixture was diluted with dichloromethane, filtered through silica gel/Celite, and concentrated. The residue was purified by column chromatography to obtain Intermediate 2-2 (460 mg, 36%).

The synthetic process of Intermediate 2-2 is briefly summarized in the following Scheme 4.

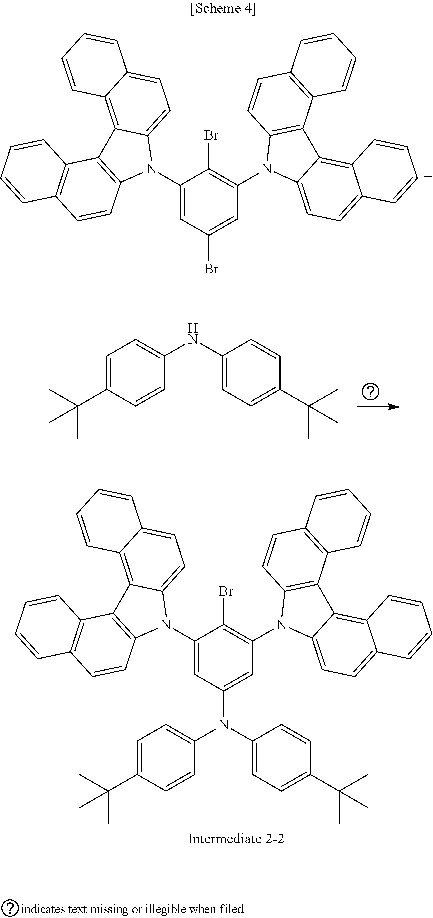 [SMILES: Brc1cc(-n2c3ccc4c(c3c3c5ccccc5ccc32)C=C[C+]=C4)c(Br)c(-n2c3ccc4ccccc4c3c3c4ccccc4ccc32)c1 ; CC(C)(C)c1ccc(Nc2ccc(C(C)(C)C)cc2)cc1 ; CC(C)(C)c1ccc(N(c2ccc(C(C)(C)C)cc2)c2cc(-n3c4ccc5ccccc5c4c4c5ccccc5ccc43)c(Br)c(-n3c4ccc5ccccc5c4c4c5ccccc5ccc43)c2)cc1]

### 3) Synthesis of Compound 3

Compound 3 was synthesized using Intermediate 2-2 instead of Intermediate 1-1 through a method similar to the synthetic method of Compound 1 of Example 1, and the synthetic process is briefly summarized in the following Scheme 5.

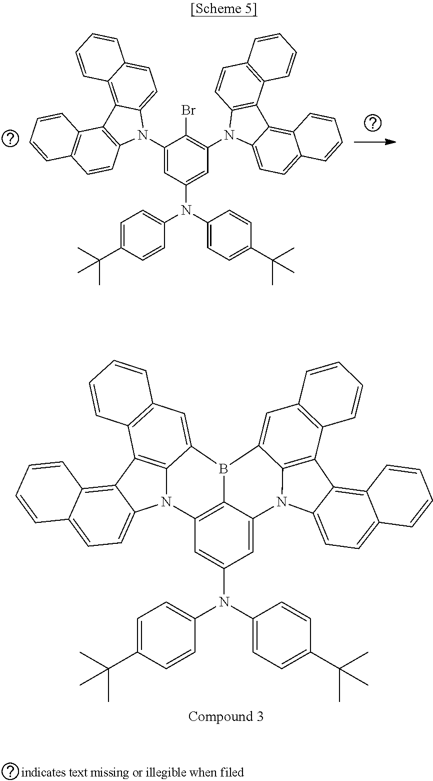 [SMILES: CC(C)(C)c1ccc(N(c2ccc(C(C)(C)C)cc2)c2cc(-n3c4ccc5ccccc5c4c4c5ccccc5ccc43)c(Br)c(-n3c4ccc5ccccc5c4c4c5ccccc5ccc43)c2)cc1 ; CC(C)(C)c1ccc(N(c2ccc(C(C)(C)C)cc2)c2cc3c4c(c2)-n2c5ccc6ccccc6c5c5c6ccccc6cc(c52)B4c2cc4ccccc4c4c5c6ccccc6ccc5n-3c24)cc1]

### Example 3: Synthesis of Compound 105

Intermediate 3-1 was synthesized using 3,11-di-tertiarybutyl-7H-dibenzo[c,g]carbazole instead of 7H-dibenzo[c,g]carbazole through a method similar to the synthetic method of Compound 3, and the synthetic process is briefly summarized in the following Scheme 6.

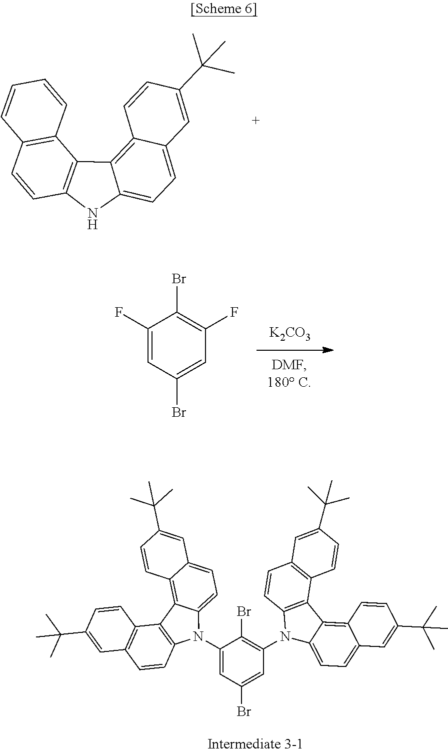

Intermediate 3-2 was synthesized using Intermediate 3-1 instead of Intermediate 2-1 through a method similar to the synthetic method of Compound 3, and the synthetic process is briefly summarized in the following Scheme 7.

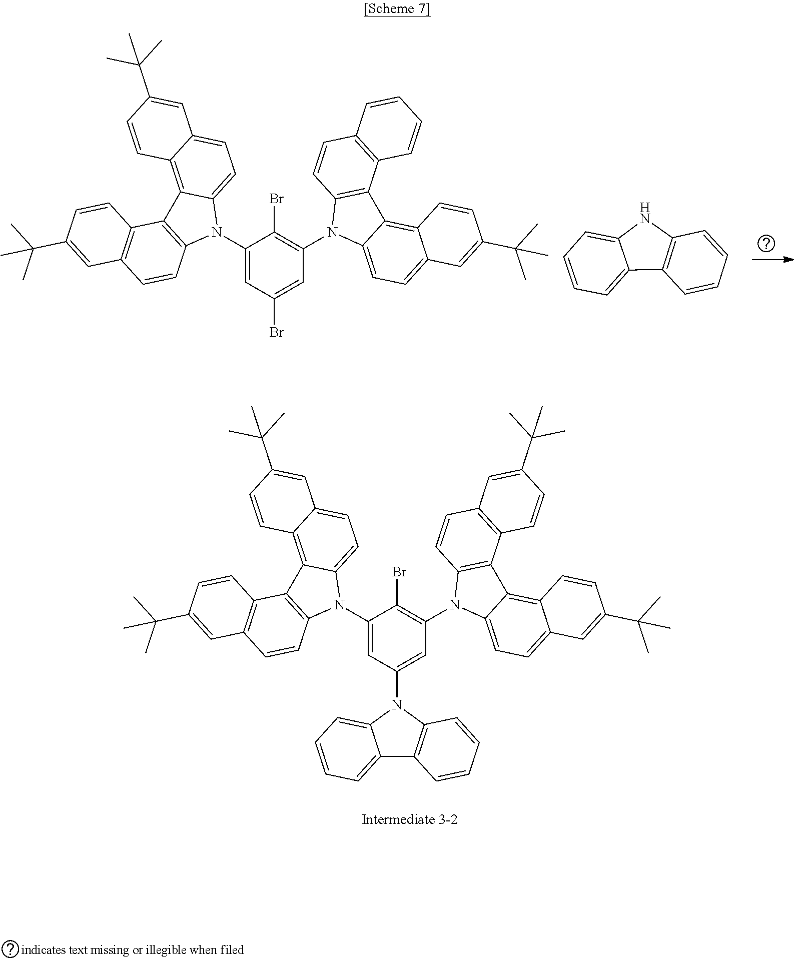

Compound 105 was synthesized using Intermediate 3-2 instead of Intermediate 1-1 through a method similar to the synthetic method of Compound 1, and the synthetic process is briefly summarized in the following Scheme 8.

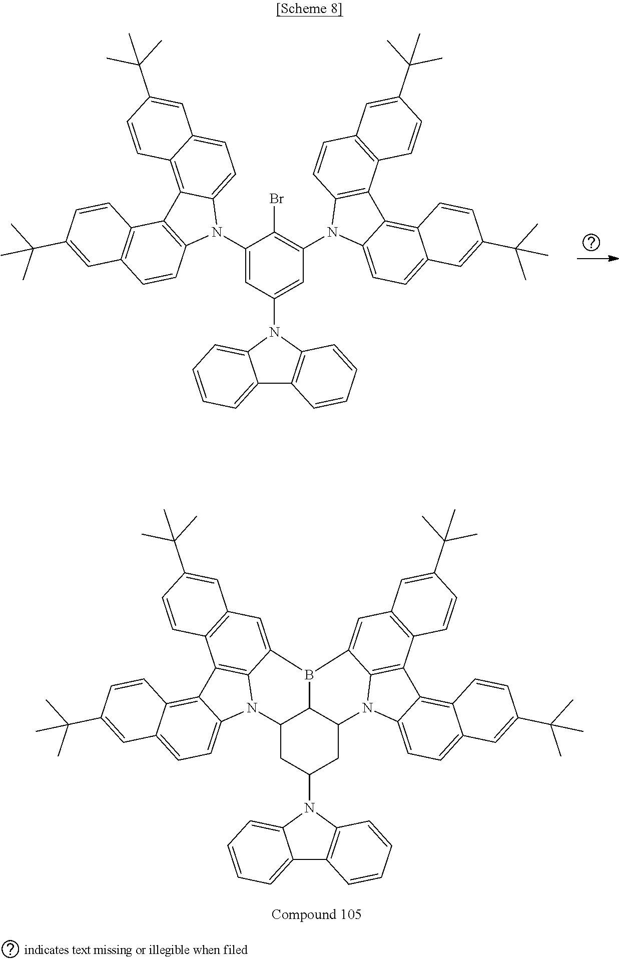

### Example 4: Synthesis of Compound 122

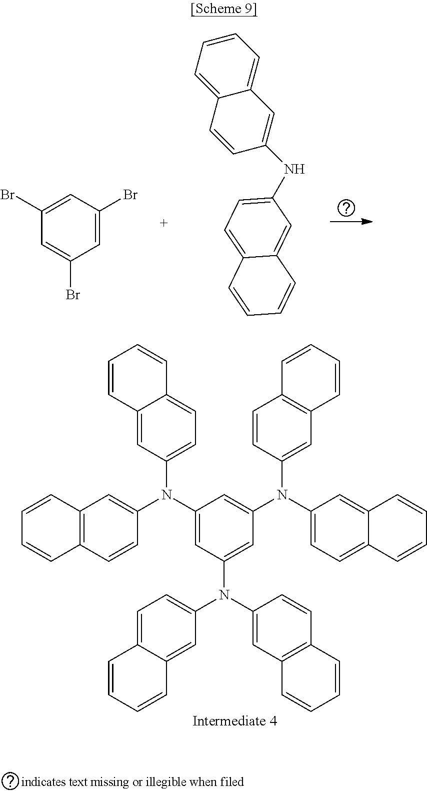

1,3,5-tribromobenzene (1 g, 3.18 mmol), di(naphthalen-2-yl)amine (2.74 g, 10.17 mmol), P(t-Bu)₃ (0.8 ml, 3.17 mmol), and NaOBu^{t} (1.84 g, 19.15 mmol) were mixed in anhydrous toluene (60 mL), and the atmosphere was replaced with argon gas. Pd₂(dba)₃ (0.26 g, 0.28 mmol) was added to the mixture, and the mixture was stirred at 160° C. for 18 hours. Upon completion of the reaction, the compound was filtered, washed with dichloromethane and hexane, concentrated, and recrystallized using dichloromethane and hexane to obtain Intermediate 4 (2.6 g, 93%).

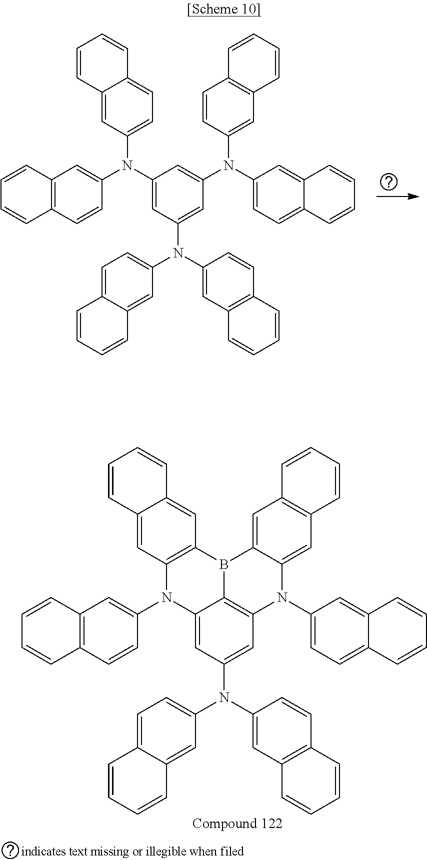 [SMILES: c1ccc2cc(N(c3cc(N(c4ccc5ccccc5c4)c4ccc5ccccc5c4)cc(N(c4ccc5ccccc5c4)c4ccc5ccccc5c4)c3)c3ccc4ccccc4c3)ccc2c1 ; c1ccc2cc(N(c3cc4c5c(c3)N(c3ccc6ccccc6c3)c3cc6ccccc6cc3B5c3cc5ccccc5cc3N4c3ccc4ccccc4c3)c3ccc4ccccc4c3)ccc2c1]

After intermediate 4 (1 g, 1.14 mmol) and o-dichlorobenzene (15 ml) were mixed, the atmosphere was replaced with argon gas, and BBr₃ (0.31 ml, 2.5 mmol) was slowly added dropwise to the mixture at room temperature. After 10 minutes, the reaction product was refluxed at 200° C. for 20 hours. When the reaction was completed, the reaction product was diluted with toluene, filtered through a silica pad, and concentrated. The residue was purified using column chromatography with hexane and dichloromethane to obtain Compound 122 (0.2 g, 20%).

### Experimental Example

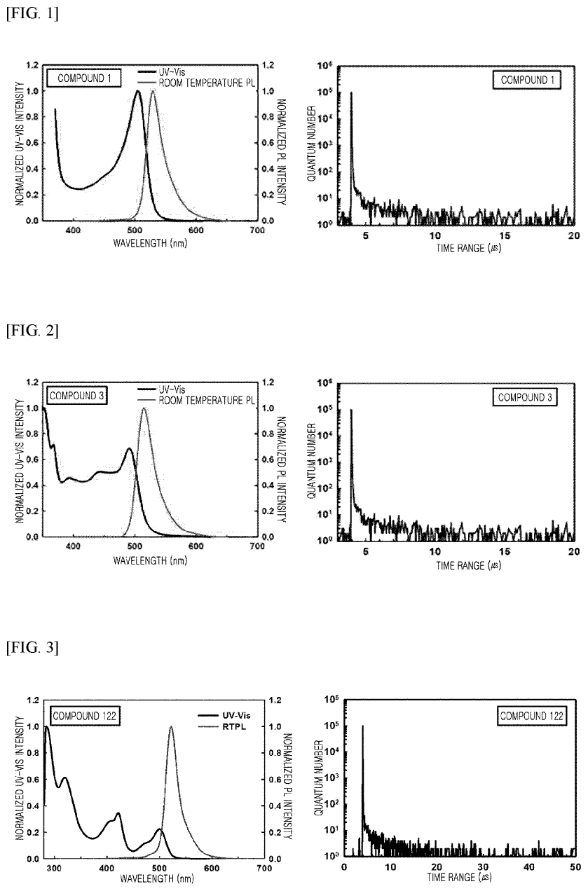

The physical properties of Compounds 1 and 3 prepared according to Examples 1 and 2 were evaluated. The measured physical properties were a UV-Vis absorption spectrum and a room temperature photoluminescence spectrum, and the UV-Vis absorption spectrum was measured by diluting in a toluene solvent to a concentration of 10×⁻⁴ M using JASCO V-750. The room temperature photoluminescence spectrum was measured using JASCO-FP 8500 equipment under the same conditions. The absolute photoluminescence quantum yield (PLQY) value was measured using an integrating sphere built in JASCO-FP 8500 equipment after preparing a thin film doped with 1 wt % of PBICT (12,12′-(6-phenyl-1,3,5-triazine-2,4-diyl)bis(11-phenyl-11,12-dihydroindolo[2,3-a]carbazole)). Time-resolved photoluminescence (TRPL) was measured by diluting to a concentration of 10×⁻⁴ M in a toluene solvent using a Hamamatsu C11367 instrument. The measurement results are shown in Table 1 and FIGS. 1 to 3.

TABLE 1

| | Comparative | | | | | | | |
|---|---|---|---|---|---|---|---|---|
| Classification | Example 1 | | Example 1 | | Example 2 | | Example 3 | |
| Compound | C545T | | Compound 1 | | Compound 3 | | Compound 122 | |
| Maximum | 473 | nm | 501 | nm | 490 | nm | 500 | nm |
| absorption | | | | | | | | |
| spectrum | | | | | | | | |
| Maximum | 506 | nm | 529 | nm | 515 | nm | 522 | nm |
| emission | | | | | | | | |
| spectrum | | | | | | | | |
| Stokes shift | 33 | nm | 28 | nm | 25 | nm | 22 | nm |
| Full width at | 74 | nm | 37 | nm | 34 | nm | 27 | nm |
| half maximum | | | | | | | | |
| Singlet-triplet | 1.03 | eV | 0.16 | eV | 0.15 | eV | 0.26 | eV |

| energy | | | | | | | |
|---|---|---|---|---|---|---|---|
| PLQY | 0.92 | 0.90 | | 0.95 | | 0.93 | |
| Triplet exciton | — | 0.13 | μs | 0.11 | μs | 0.07 | μs |

lifetime

The ITO glass substrate was cut into a size of 50 mm×5 mm×0.7 mm, washed with acetone, isopropyl alcohol and distilled water for 10 minutes each, irradiated with ultraviolet rays for 10 minutes, exposed to ozone and cleaned, and then the ITO glass substrate was mounted in a vacuum deposition device.

HATCN (7 nm)/NPB (53 nm)/TCTA (20 nm)/PBICT (host) and 1 wt % of Compound 1 or Compound 3 (dopant)(20 nm)/TmPyPB (40 nm)/LiF (1.5 nm)/Al (100 nm) were sequentially laminated to manufacture an organic light-emitting device. The measurement results of the devices are shown in Table 2.

TABLE 2

| | Comparative | | |
|---|---|---|---|
| Classification | Example 1 | Example 1 | Example 2 |
| Compound | C545T | Compound 1 | Compound 3 |
| Maximum EQE (%) | 3.6 | 4.9 | 12.7 |
| Full width at half | 76 | 57 | 45 |
| maximum (nm) | | | |
| Maximum | 506 | 535 | 521 |
| electroluminescence | | | |
| wavelength (nm) | | | |
| CIE coordinates | (0.26, 0.60) | (0.30, 0.59) | (0.19, 0.72) |

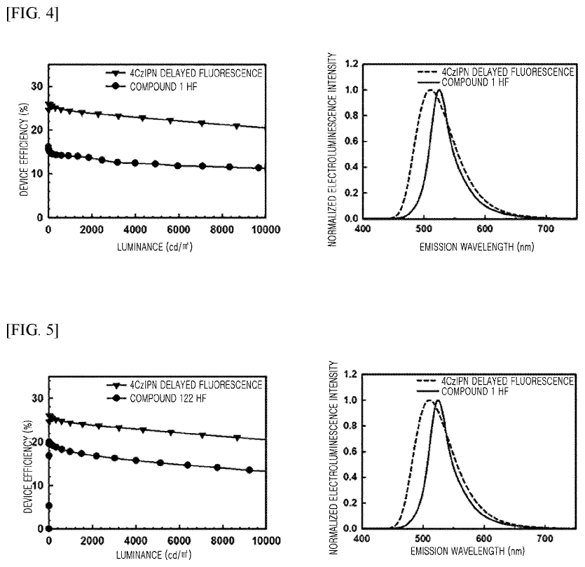

HATCN (7 nm)/NPB (53 nm)/TCTA (20 nm)/PBICT (host) and 20 wt % of 4CzIPN (delayed fluorescence host) and 1 wt % of Compound 1, Compound 3 or Compound 122 (dopant)(20 nm)/TmPyPB (40 nm)/LiF (1.5 nm)/Al (100 nm) were sequentially laminated on the ITO glass substrate to manufacture a delayed fluorescence photosensitive organic light-emitting device. The measurement results of the devices are shown in Table 3 and FIGS. 4 and 5.

TABLE 3

| | Comparative | | | |
|---|---|---|---|---|
| Classification | Example 1 | Example 1 | Example 2 | Example 3 |
| Compound | C545T | Compound 1 | Compound 3 | Compound 122 |
| Maximum EQE (%) | 13.6 | 16.1 | 22.8 | 19.9 |
| Full width at half | 85 | 59 | 48 | 45 |
| maximum (nm) | | | | |
| Maximum | 506 | 537 | 523 | 525 |
| electroluminescence | | | | |
| wavelength (nm) | | | | |
| CIE coordinates | (0.28, 0.58) | (0.34, 0.61) | (0.21, 0.75) | (0.27, 0.65) |

While the present invention includes specific embodiments, it will be apparent to those of ordinary skill to which the present invention pertains that various changes in form and details may be made in these embodiments without departing from the spirit and scope of the claims and their equivalents. Therefore, the embodiments described herein are to be considered in a descriptive sense only, and not for purposes of limitation. For example, each component described as a single type may be implemented to be distributed and similarly, components described to be distributed may also be implemented in a combined form.

The scope of the present invention is defined not by the detailed description, but by the claims and their equivalents, and all variations within the scope of the claims and their equivalents are to be construed as being included in the present invention.

1. A boron compound represented by the following Formula 1: 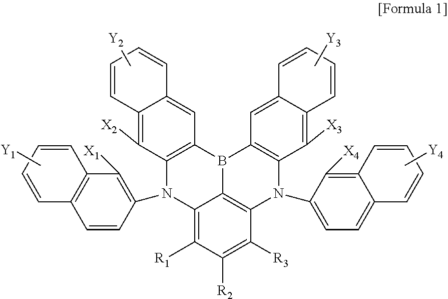
in Formula 1,
Y₁ to Y₄ each independently represent hydrogen, deuterium, a nitrile group, a substituted or unsubstituted alkyl group, a substituted or unsubstituted cycloalkyl group, a substituted or unsubstituted alkoxy group, a substituted or unsubstituted silyl group, a substituted or unsubstituted amine group, a substituted or unsubstituted aryl group, a substituted or unsubstituted heteroaryl group, a substituted or unsubstituted diarylamino group, a substituted or unsubstituted diheteroarylamino group, or a substituted or unsubstituted arylheteroarylamino group;
X₁ to X₄ each independently represent hydrogen or are mutually bonded to form a ring; and
R₁ to R₃ each independently represent hydrogen, deuterium, a nitrile group, a halogen group, a substituted or unsubstituted alkyl group, a substituted or unsubstituted cycloalkyl group, a substituted or unsubstituted alkoxy group, a substituted or unsubstituted silyl group, a substituted or unsubstituted amine group, a substituted or unsubstituted aryl group, a substituted or unsubstituted heteroaryl group, a substituted or unsubstituted diarylamino group, a substituted or unsubstituted diheteroarylamino group, or a substituted or unsubstituted arylheteroarylamino group, or a ring structure formed by mutually bonding R₁ and R₂ or R₂ and R₃.

2. The boron compound according to claim 1, wherein at least one of R₁ to R₃ is represented by one of the following Formulas 2 to 3: 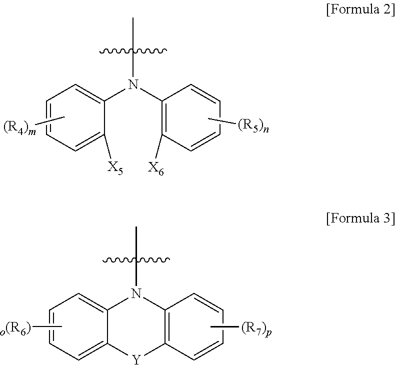
in Formula 2 or 3,
X₅ to X₆ each independently represent hydrogen or are mutually bonded to form a ring;
R₄ to R₇ each independently represent hydrogen, deuterium, a nitrile group, a halogen group, a substituted or unsubstituted aromatic ring, a substituted or unsubstituted alkyl group, a substituted or unsubstituted cycloalkyl group, a substituted or unsubstituted alkoxy group, a substituted or unsubstituted silyl group, a substituted or unsubstituted amine group, a substituted or unsubstituted aryl group, a substituted or unsubstituted heteroaryl group, a substituted or unsubstituted diarylamino group, a substituted or unsubstituted diheteroarylamino group, or a substituted or unsubstituted arylheteroarylamino group;
Y is sulfur, oxygen, carbon to which one or more alkyl or aryl groups are bonded; and
m, n, o and p each independently represent an integer of 0 to 4.

3. The boron compound according to claim 1, wherein the boron compound is represented by one of the following Formulas 1-1 to 1-132:

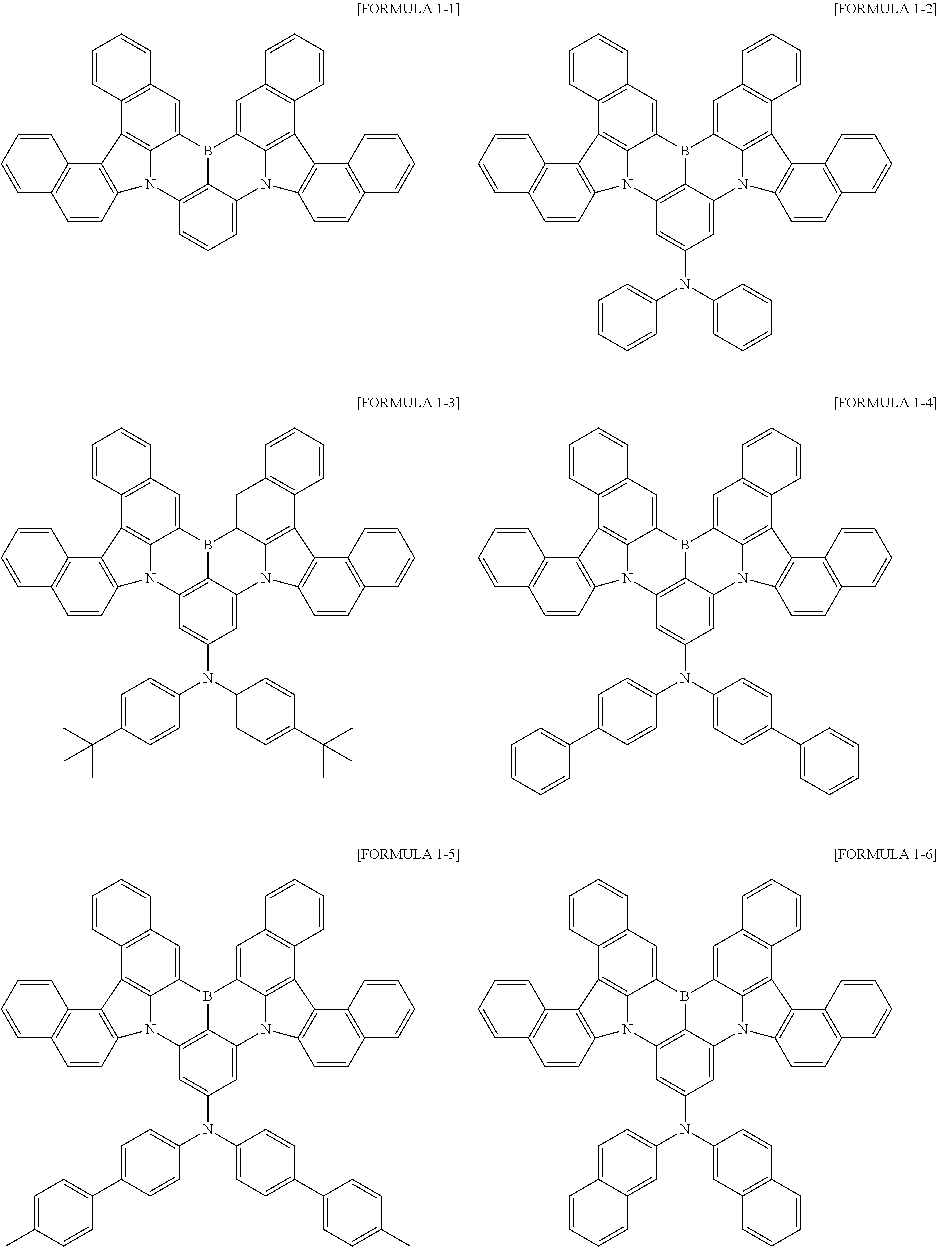

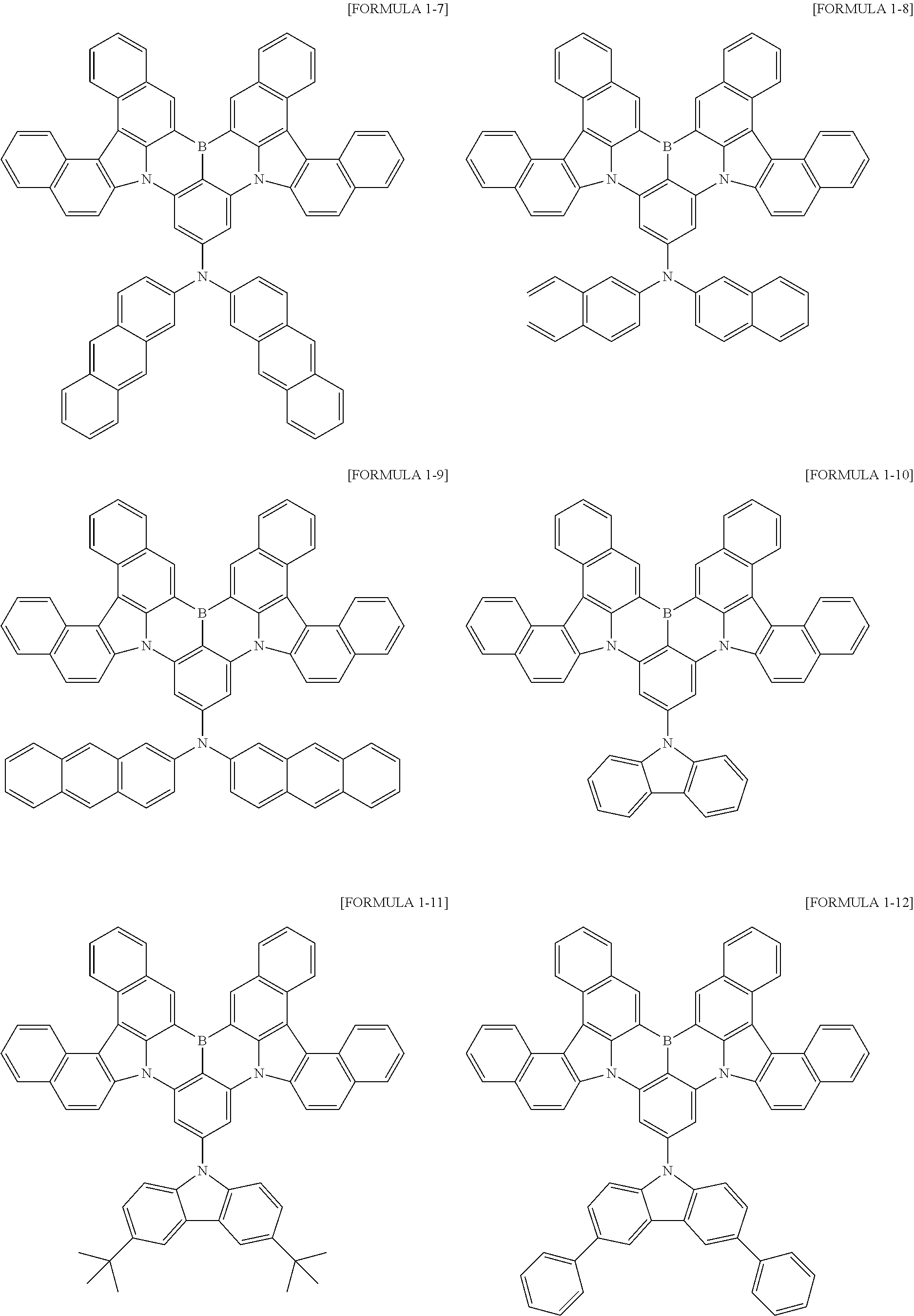

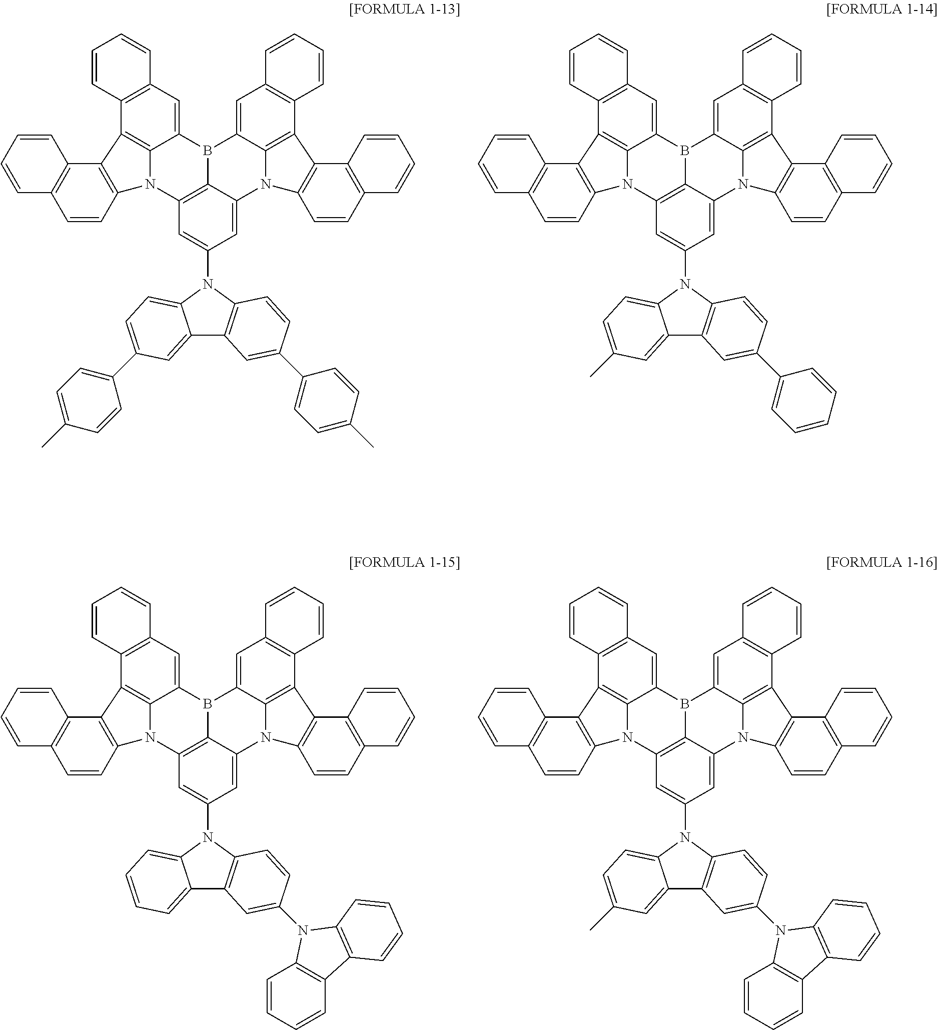

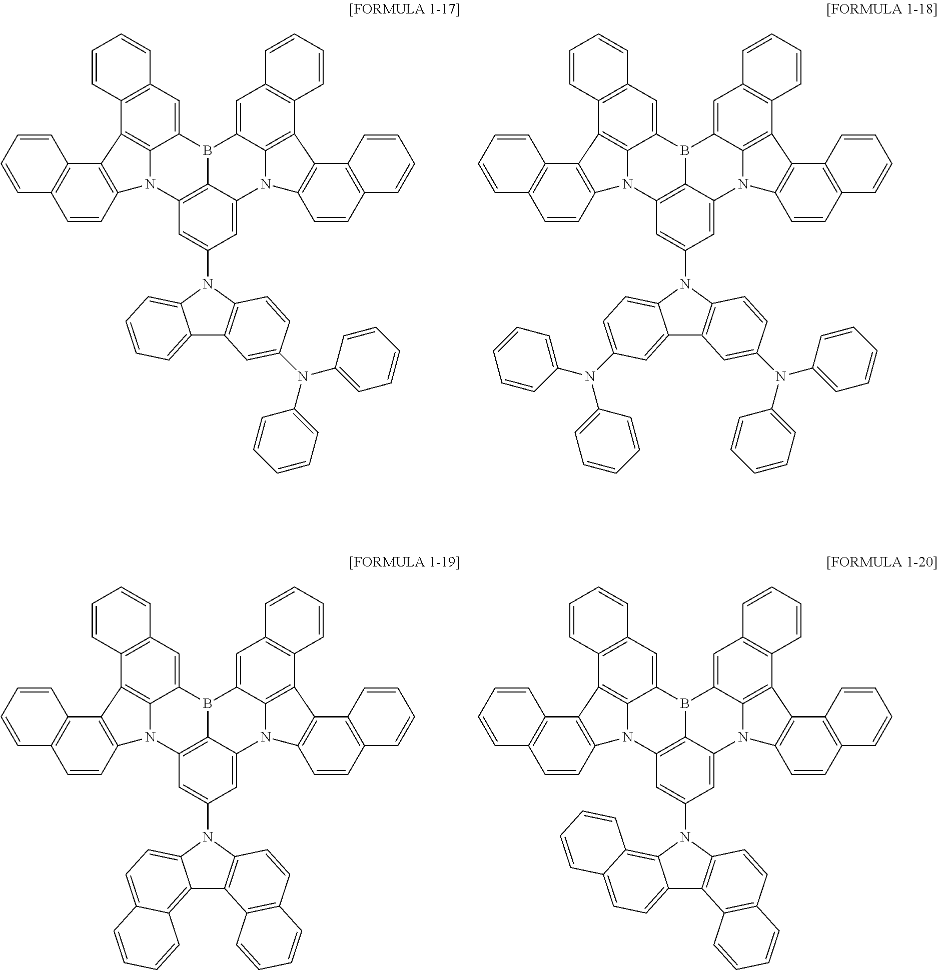

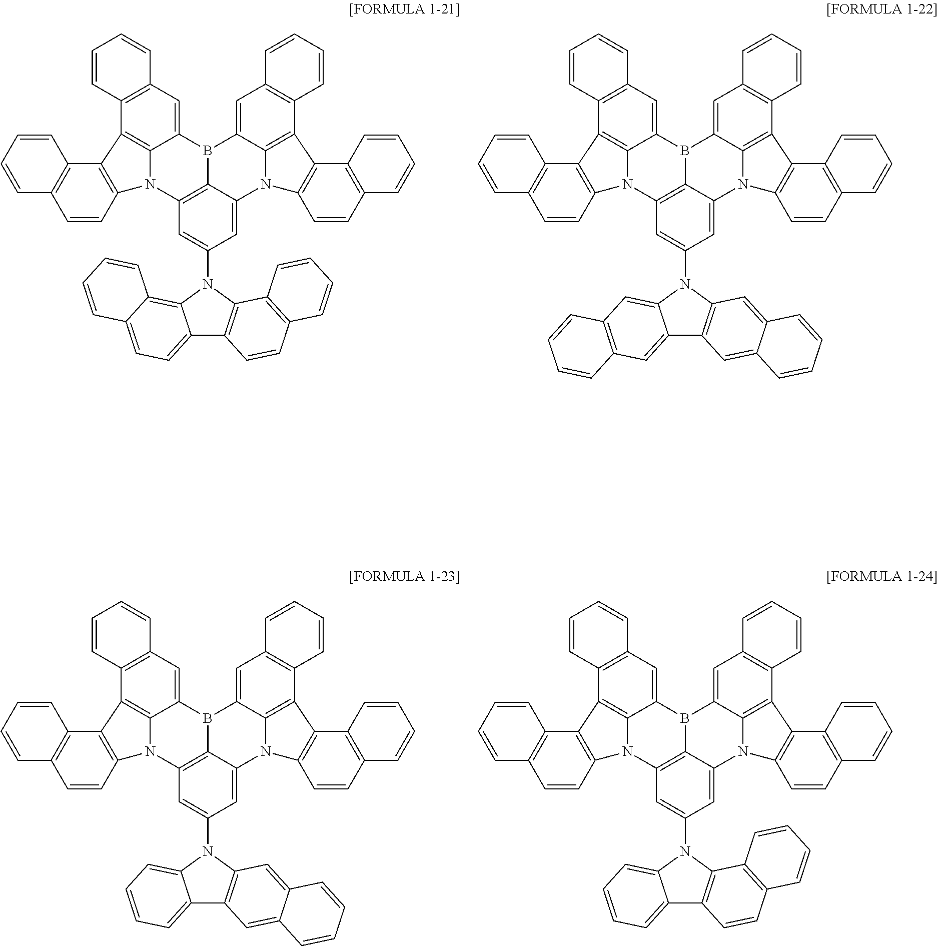 [SMILES: c1ccc2c(c1)ccc1c2c2c3ccccc3cc3c2n1-c1cc(-n2c4c5ccccc5ccc4c4ccc5ccccc5c42)cc2c1B3c1cc3ccccc3c3c4c5ccccc5ccc4n-2c13 ; c1ccc2cc3c(cc2c1)c1cc2ccccc2cc1n3-c1cc2c3c(c1)-n1c4ccc5ccccc5c4c4c5ccccc5cc(c41)B3c1cc3ccccc3c3c4c5ccccc5ccc4n-2c13 ; c1ccc2cc3c(cc2c1)c1ccccc1n3-c1cc2c3c(c1)-n1c4ccc5ccccc5c4c4c5ccccc5cc(c41)B3c1cc3ccccc3c3c4c5ccccc5ccc4n-2c13 ; c1ccc2c(c1)ccc1c2c2c3ccccc3cc3c2n1-c1cc(-n2c4ccccc4c4ccc5ccccc5c42)cc2c1B3c1cc3ccccc3c3c4c5ccccc5ccc4n-2c13]

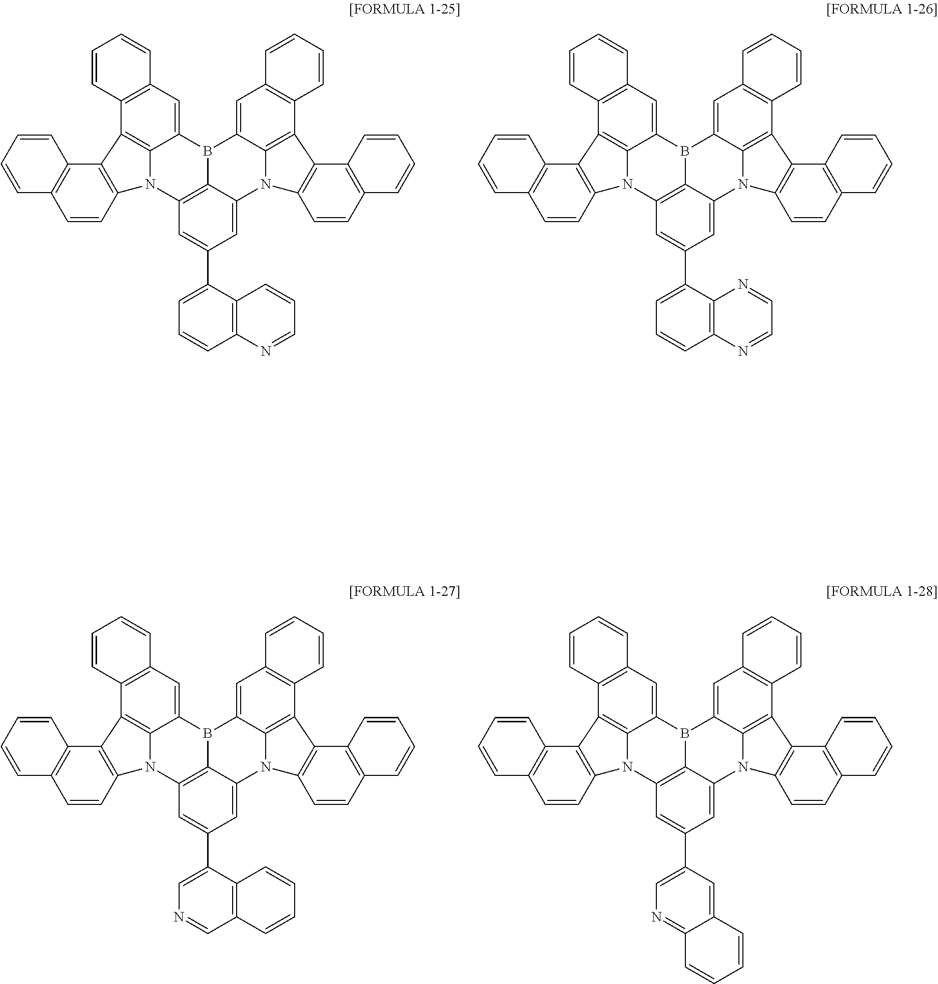 [SMILES: c1ccc2c(c1)ccc1c2c2c3ccccc3cc3c2n1-c1cc(-c2cccc4ncccc24)cc2c1B3c1cc3ccccc3c3c4c5ccccc5ccc4n-2c13 ; c1ccc2c(c1)ccc1c2c2c3ccccc3cc3c2n1-c1cc(-c2cccc4nccnc24)cc2c1B3c1cc3ccccc3c3c4c5ccccc5ccc4n-2c13 ; c1ccc2c(-c3cc4c5c(c3)-n3c6ccc7ccccc7c6c6c7ccccc7cc(c63)B5c3cc5ccccc5c5c6c7ccccc7ccc6n-4c35)cncc2c1 ; c1ccc2ncc(-c3cc4c5c(c3)-n3c6ccc7ccccc7c6c6c7ccccc7cc(c63)B5c3cc5ccccc5c5c6c7ccccc7ccc6n-4c35)cc2c1]

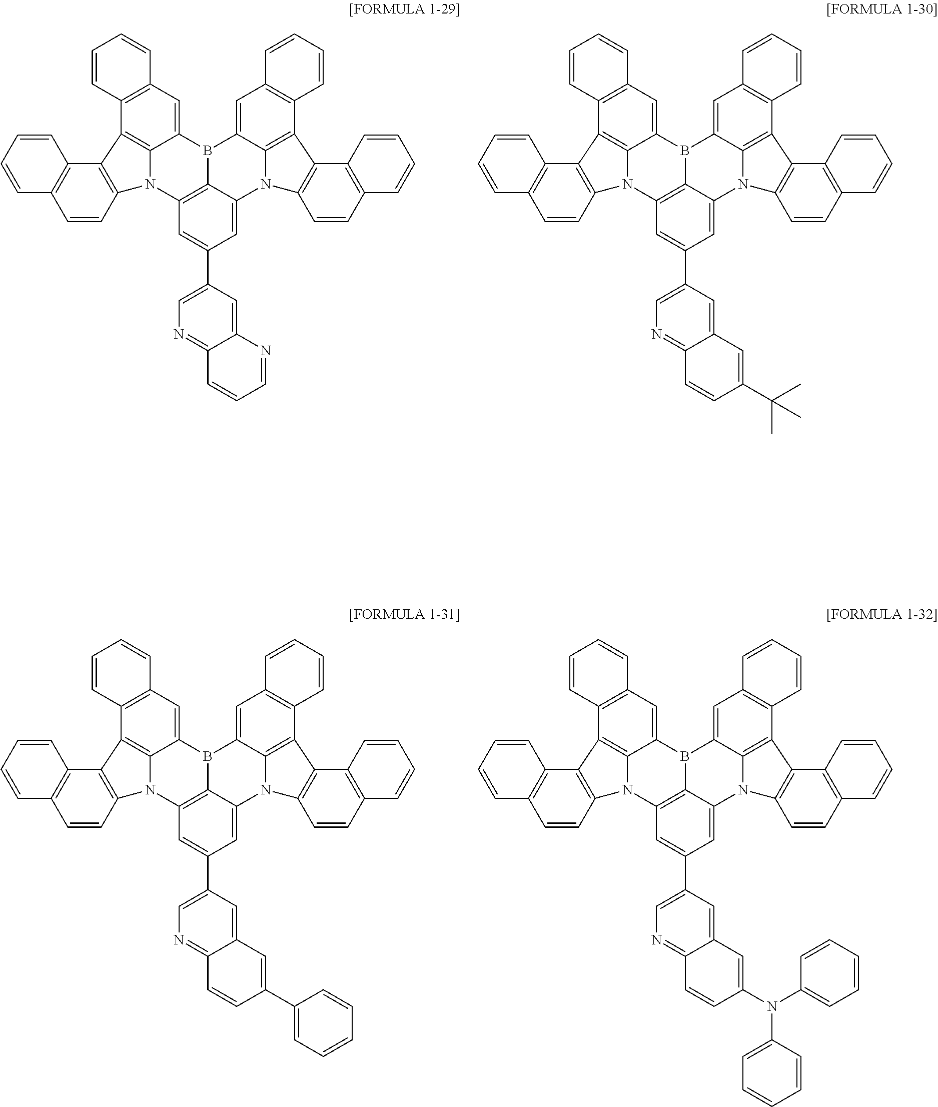 [SMILES: c1ccc2c(c1)ccc1c2c2c3ccccc3cc3c2n1-c1cc(-c2cnc4cccnc4c2)cc2c1B3c1cc3ccccc3c3c4c5ccccc5ccc4n-2c13 ; CC(C)(C)c1ccc2ncc(-c3cc4c5c(c3)-n3c6ccc7ccccc7c6c6c7ccccc7cc(c63)B5c3cc5ccccc5c5c6c7ccccc7ccc6n-4c35)cc2c1 ; c1ccc(-c2ccc3ncc(-c4cc5c6c(c4)-n4c7ccc8ccccc8c7c7c8ccccc8cc(c74)B6c4cc6ccccc6c6c7c8ccccc8ccc7n-5c46)cc3c2)cc1 ; c1ccc(N(c2ccccc2)c2ccc3ncc(-c4cc5c6c(c4)-n4c7ccc8ccccc8c7c7c8ccccc8cc(c74)B6c4cc6ccccc6c6c7c8ccccc8ccc7n-5c46)cc3c2)cc1]

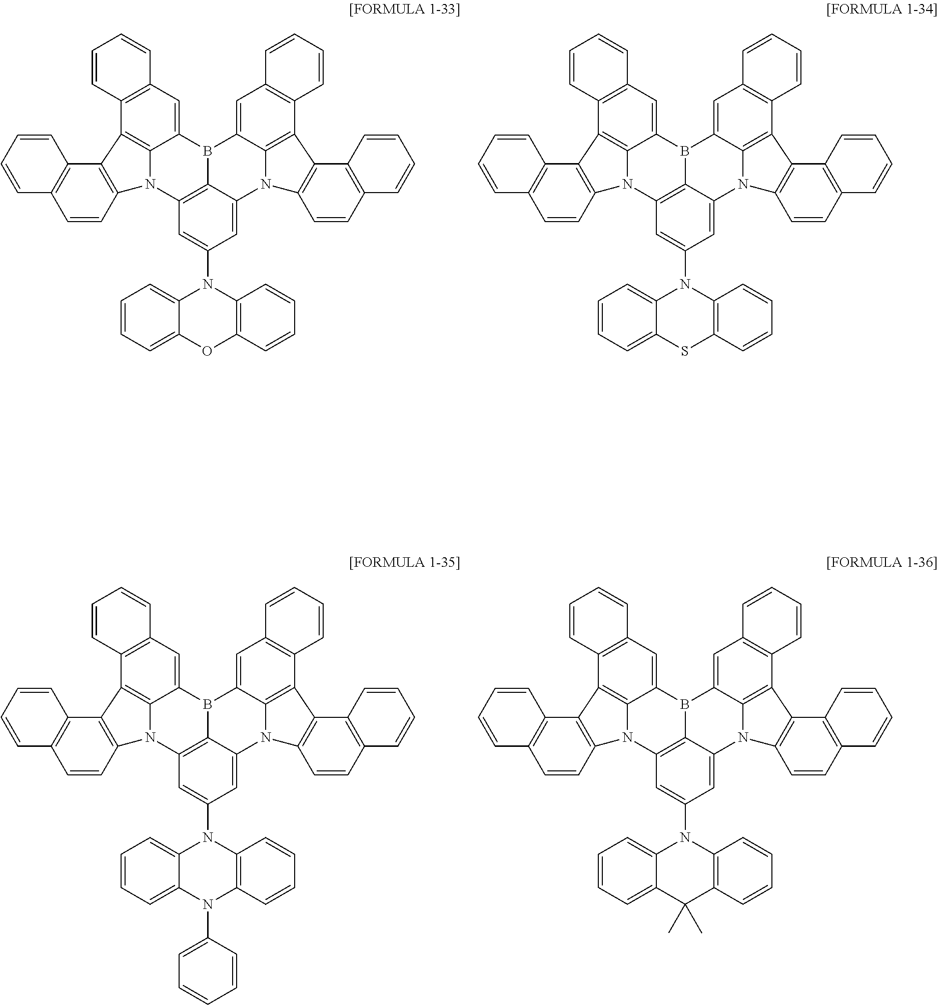 [SMILES: c1ccc2c(c1)Oc1ccccc1N2c1cc2c3c(c1)-n1c4ccc5ccccc5c4c4c5ccccc5cc(c41)B3c1cc3ccccc3c3c4c5ccccc5ccc4n-2c13 ; c1ccc2c(c1)Sc1ccccc1N2c1cc2c3c(c1)-n1c4ccc5ccccc5c4c4c5ccccc5cc(c41)B3c1cc3ccccc3c3c4c5ccccc5ccc4n-2c13 ; c1ccc(N2c3ccccc3N(c3cc4c5c(c3)-n3c6ccc7ccccc7c6c6c7ccccc7cc(c63)B5c3cc5ccccc5c5c6c7ccccc7ccc6n-4c35)c3ccccc32)cc1 ; CC1(C)c2ccccc2N(c2cc3c4c(c2)-n2c5ccc6ccccc6c5c5c6ccccc6cc(c52)B4c2cc4ccccc4c4c5c6ccccc6ccc5n-3c24)c2ccccc21]

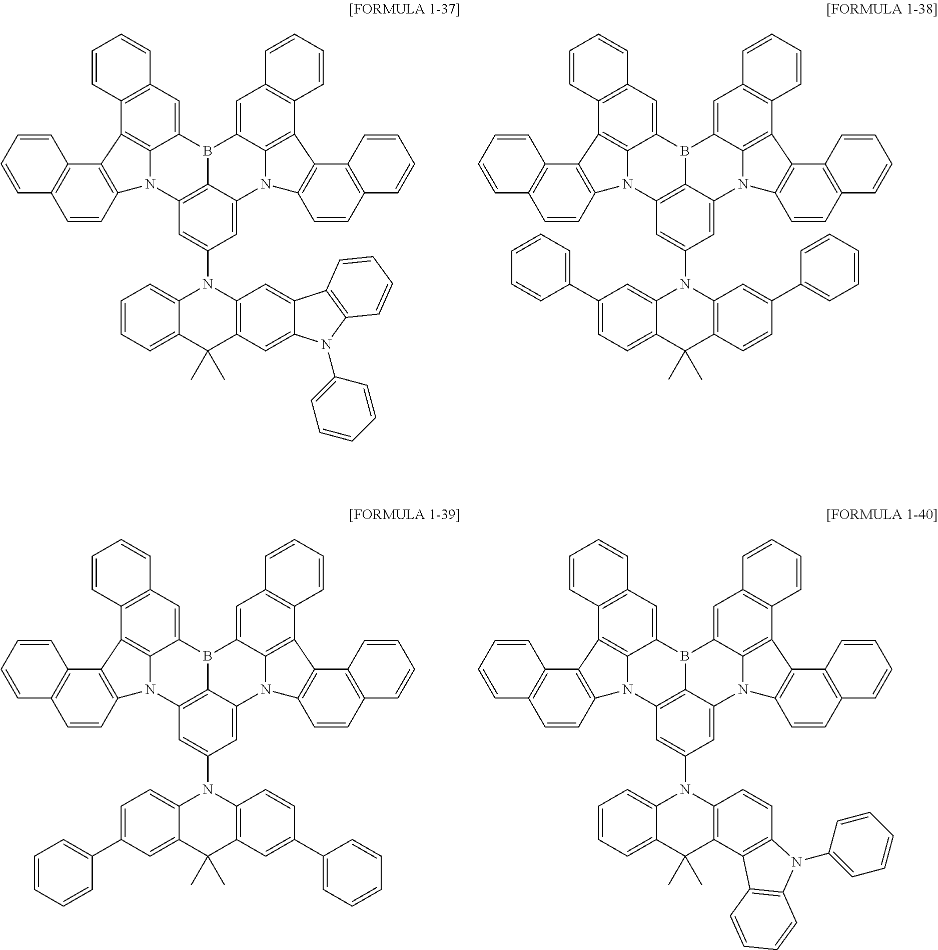

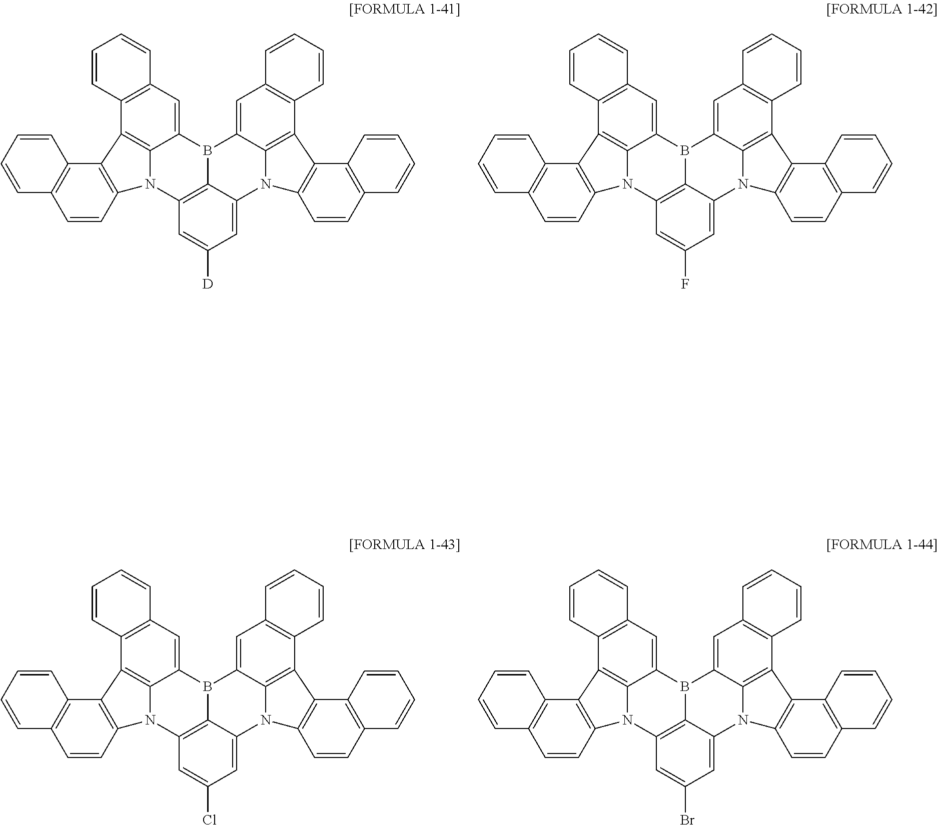 [SMILES: [2H]c1cc2c3c(c1)-n1c4ccc5ccccc5c4c4c5ccccc5cc(c41)B3c1cc3ccccc3c3c4c5ccccc5ccc4n-2c13 ; Fc1cc2c3c(c1)-n1c4ccc5ccccc5c4c4c5ccccc5cc(c41)B3c1cc3ccccc3c3c4c5ccccc5ccc4n-2c13 ; Clc1cc2c3c(c1)-n1c4ccc5ccccc5c4c4c5ccccc5cc(c41)B3c1cc3ccccc3c3c4c5ccccc5ccc4n-2c13 ; Brc1cc2c3c(c1)-n1c4ccc5ccccc5c4c4c5ccccc5cc(c41)B3c1cc3ccccc3c3c4c5ccccc5ccc4n-2c13]

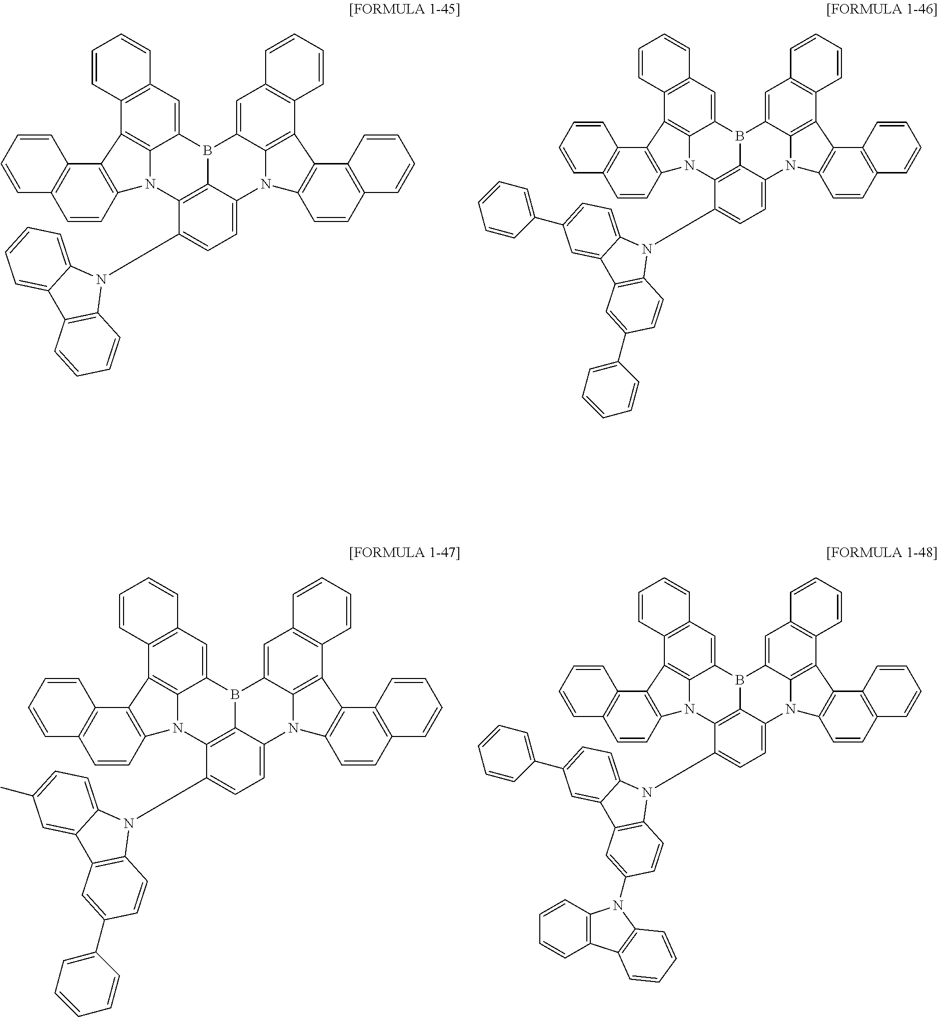 [SMILES: c1ccc2c(c1)ccc1c2c2c3ccccc3cc3c2n1-c1ccc(-n2c4ccccc4c4ccccc42)c2c1B3c1cc3ccccc3c3c4c5ccccc5ccc4n-2c13 ; c1ccc(-c2ccc3c(c2)c2cc(-c4ccccc4)ccc2n3-c2ccc3c4c2-n2c5ccc6ccccc6c5c5c6ccccc6cc(c52)B4c2cc4ccccc4c4c5c6ccccc6ccc5n-3c24)cc1 ; Cc1ccc2c(c1)c1cc(-c3ccccc3)ccc1n2-c1ccc2c3c1-n1c4ccc5ccccc5c4c4c5ccccc5cc(c41)B3c1cc3ccccc3c3c4c5ccccc5ccc4n-2c13 ; c1ccc(-c2ccc3c(c2)c2cc(-n4c5ccccc5c5ccccc54)ccc2n3-c2ccc3c4c2-n2c5ccc6ccccc6c5c5c6ccccc6cc(c52)B4c2cc4ccccc4c4c5c6ccccc6ccc5n-3c24)cc1]

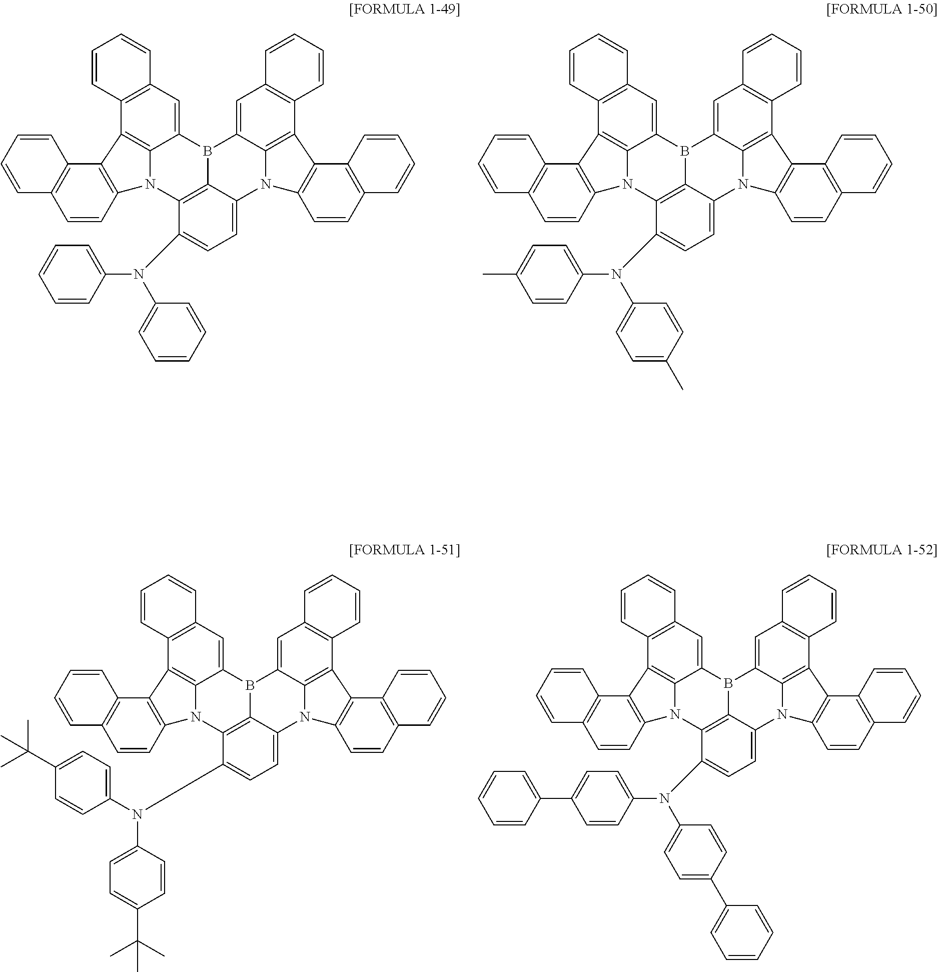 [SMILES: c1ccc(N(c2ccccc2)c2ccc3c4c2-n2c5ccc6ccccc6c5c5c6ccccc6cc(c52)B4c2cc4ccccc4c4c5c6ccccc6ccc5n-3c24)cc1 ; Cc1ccc(N(c2ccc(C)cc2)c2ccc3c4c2-n2c5ccc6ccccc6c5c5c6ccccc6cc(c52)B4c2cc4ccccc4c4c5c6ccccc6ccc5n-3c24)cc1 ; CC(C)(C)c1ccc(N(c2ccc(C(C)(C)C)cc2)c2ccc3c4c2-n2c5ccc6ccccc6c5c5c6ccccc6cc(c52)B4c2cc4ccccc4c4c5c6ccccc6ccc5n-3c24)cc1 ; c1ccc(-c2ccc(N(c3ccc(-c4ccccc4)cc3)c3ccc4c5c3-n3c6ccc7ccccc7c6c6c7ccccc7cc(c63)B5c3cc5ccccc5c5c6c7ccccc7ccc6n-4c35)cc2)cc1]

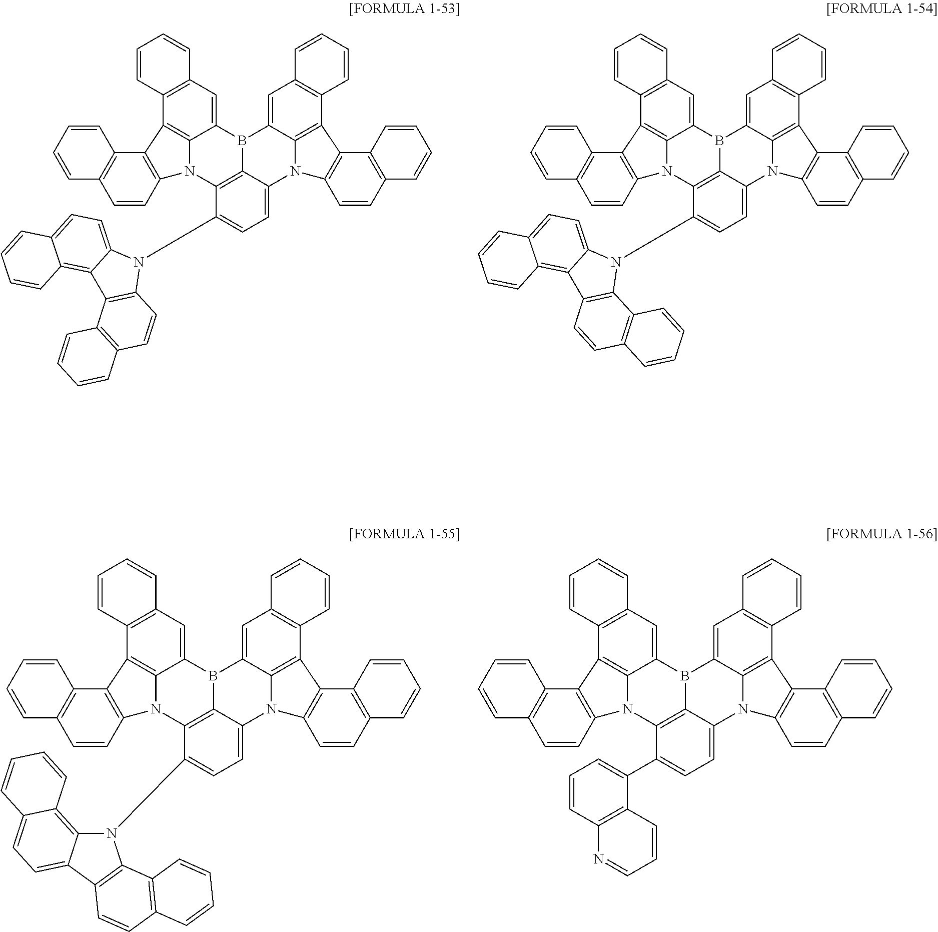 [SMILES: c1ccc2c(c1)ccc1c2c2c3ccccc3ccc2n1-c1ccc2c3c1-n1c4ccc5ccccc5c4c4c5ccccc5cc(c41)B3c1cc3ccccc3c3c4c5ccccc5ccc4n-2c13 ; c1ccc2c(c1)ccc1c2c2c3ccccc3cc3c2n1-c1ccc(-n2c4ccc5ccccc5c4c4ccc5ccccc5c42)c2c1B3c1cc3ccccc3c3c4c5ccccc5ccc4n-2c13 ; c1ccc2c(c1)ccc1c2c2c3ccccc3cc3c2n1-c1ccc(-n2c4c5ccccc5ccc4c4ccc5ccccc5c42)c2c1B3c1cc3ccccc3c3c4c5ccccc5ccc4n-2c13 ; c1ccc2c(c1)ccc1c2c2c3ccccc3cc3c2n1-c1ccc(-c2cccc4ncccc24)c2c1B3c1cc3ccccc3c3c4c5ccccc5ccc4n-2c13]

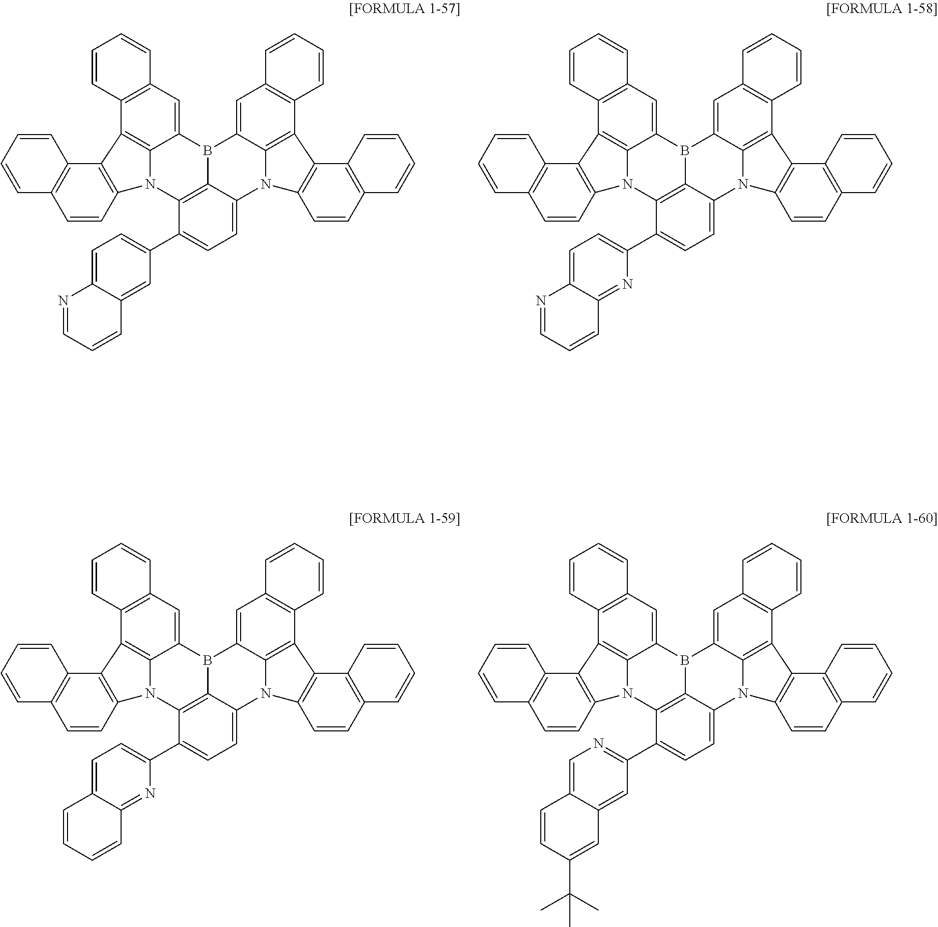 [SMILES: c1cnc2ccc(-c3ccc4c5c3-n3c6ccc7ccccc7c6c6c7ccccc7cc(c63)B5c3cc5ccccc5c5c6c7ccccc7ccc6n-4c35)cc2c1 ; c1ccc2c(c1)ccc1c2c2c3ccccc3cc3c2n1-c1ccc(-c2ccc4ncccc4n2)c2c1B3c1cc3ccccc3c3c4c5ccccc5ccc4n-2c13 ; c1ccc2nc(-c3ccc4c5c3-n3c6ccc7ccccc7c6c6c7ccccc7cc(c63)B5c3cc5ccccc5c5c6c7ccccc7ccc6n-4c35)ccc2c1 ; CC(C)(C)c1ccc2cnc(-c3ccc4c5c3-n3c6ccc7ccccc7c6c6c7ccccc7cc(c63)B5c3cc5ccccc5c5c6c7ccccc7ccc6n-4c35)cc2c1]

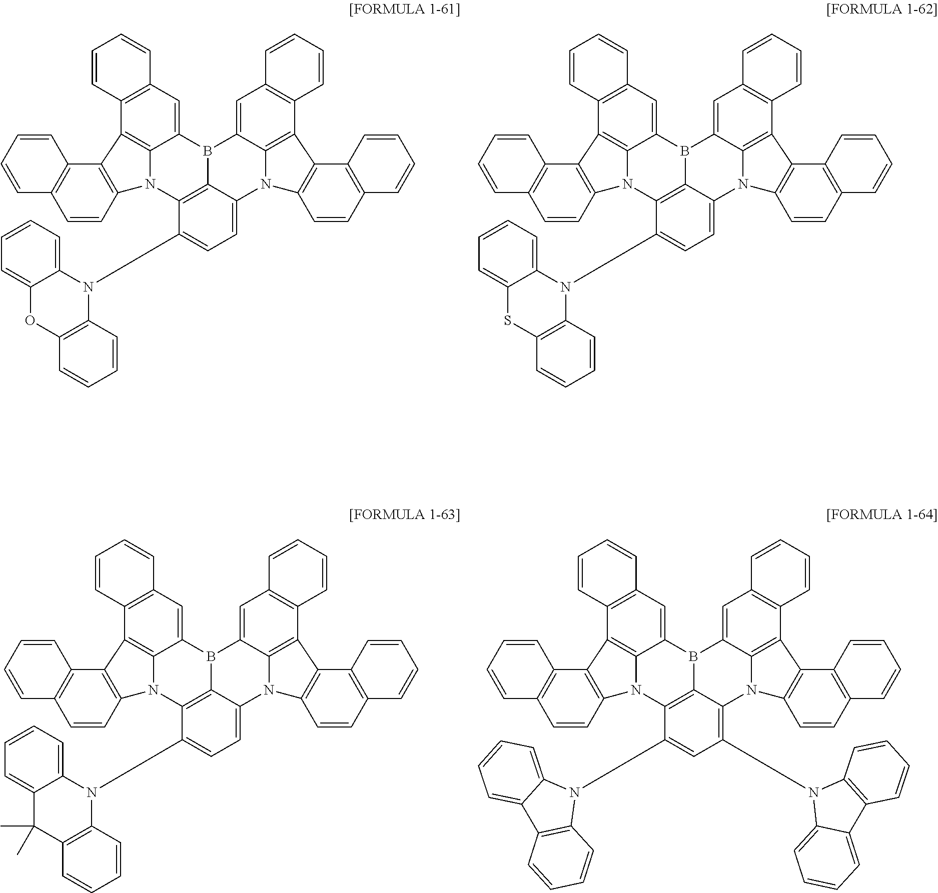 [SMILES: c1ccc2c(c1)Oc1ccccc1N2c1ccc2c3c1-n1c4ccc5ccccc5c4c4c5ccccc5cc(c41)B3c1cc3ccccc3c3c4c5ccccc5ccc4n-2c13 ; c1ccc2c(c1)Sc1ccccc1N2c1ccc2c3c1-n1c4ccc5ccccc5c4c4c5ccccc5cc(c41)B3c1cc3ccccc3c3c4c5ccccc5ccc4n-2c13 ; CC1(C)c2ccccc2N(c2ccc3c4c2-n2c5ccc6ccccc6c5c5c6ccccc6cc(c52)B4c2cc4ccccc4c4c5c6ccccc6ccc5n-3c24)c2ccccc21 ; c1ccc2c(c1)ccc1c2c2c3ccccc3cc3c2n1-c1c(-n2c4ccccc4c4ccccc42)cc(-n2c4ccccc4c4ccccc42)c2c1B3c1cc3ccccc3c3c4c5ccccc5ccc4n-2c13]

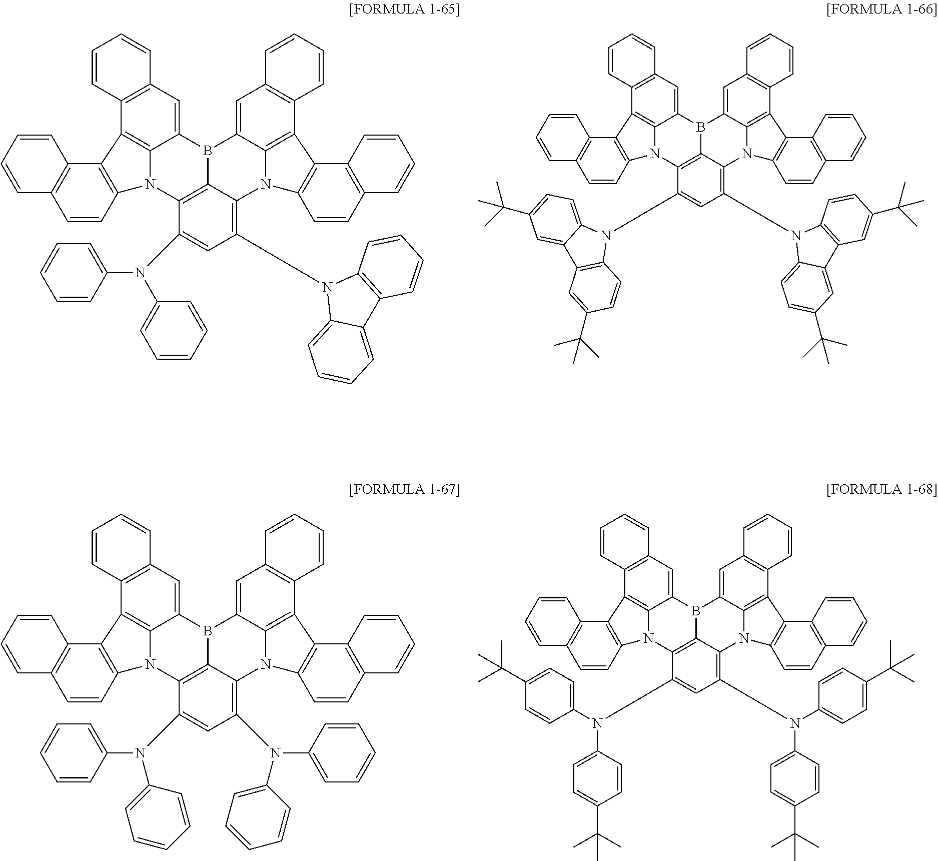

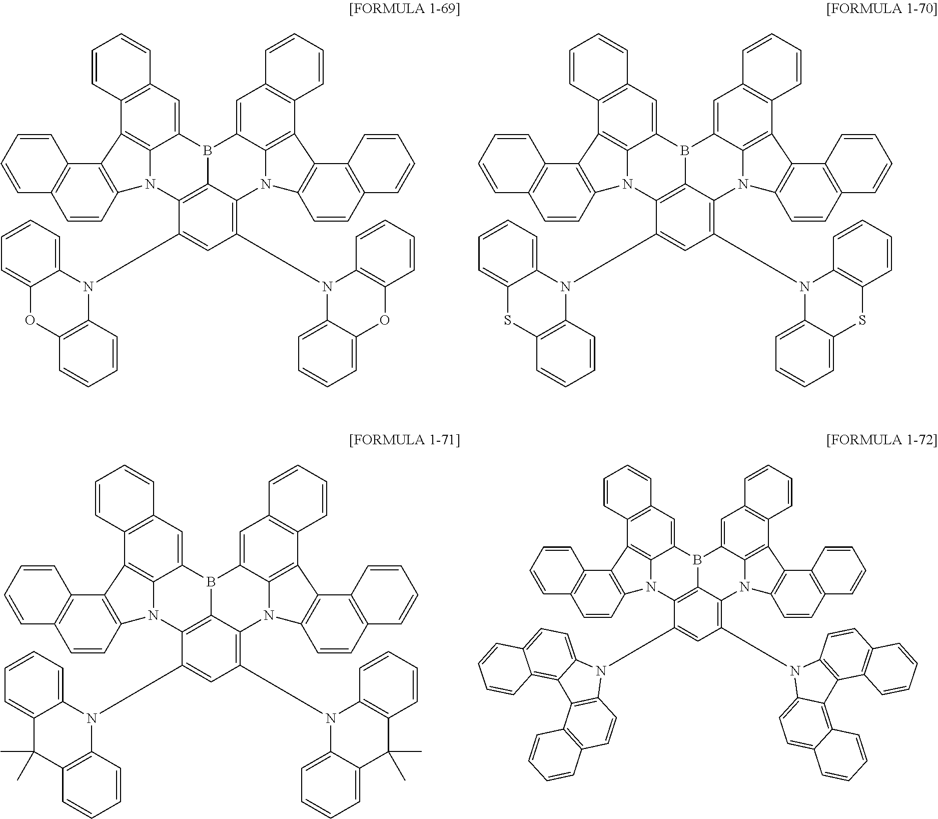

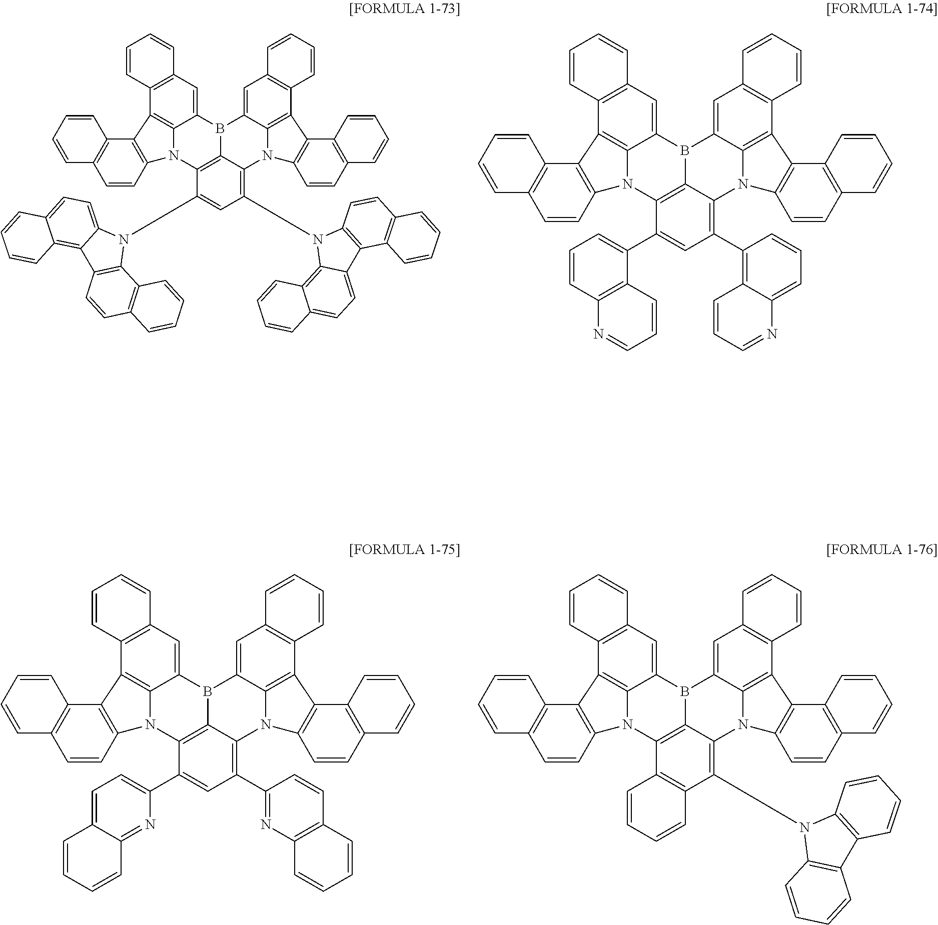 [SMILES: c1ccc2c(c1)ccc1c2c2c3ccccc3cc3c2n1-c1c(-n2c4ccc5ccccc5c4c4ccc5ccccc5c42)cc(-n2c4ccc5ccccc5c4c4ccc5ccccc5c42)c2c1B3c1cc3ccccc3c3c4c5ccccc5ccc4n-2c13 ; c1ccc2c(c1)ccc1c2c2c3ccccc3cc3c2n1-c1c(-c2cccc4ncccc24)cc(-c2cccc4ncccc24)c2c1B3c1cc3ccccc3c3c4c5ccccc5ccc4n-2c13 ; c1ccc2nc(-c3cc(-c4ccc5ccccc5n4)c4c5c3-n3c6ccc7ccccc7c6c6c7ccccc7cc(c63)B5c3cc5ccccc5c5c6c7ccccc7ccc6n-4c35)ccc2c1 ; c1ccc2c(c1)ccc1c2c2c3ccccc3cc3c2n1-c1c2c(c4ccccc4c1-n1c4ccccc4c4ccccc41)-n1c4ccc5ccccc5c4c4c5ccccc5cc(c41)B23]

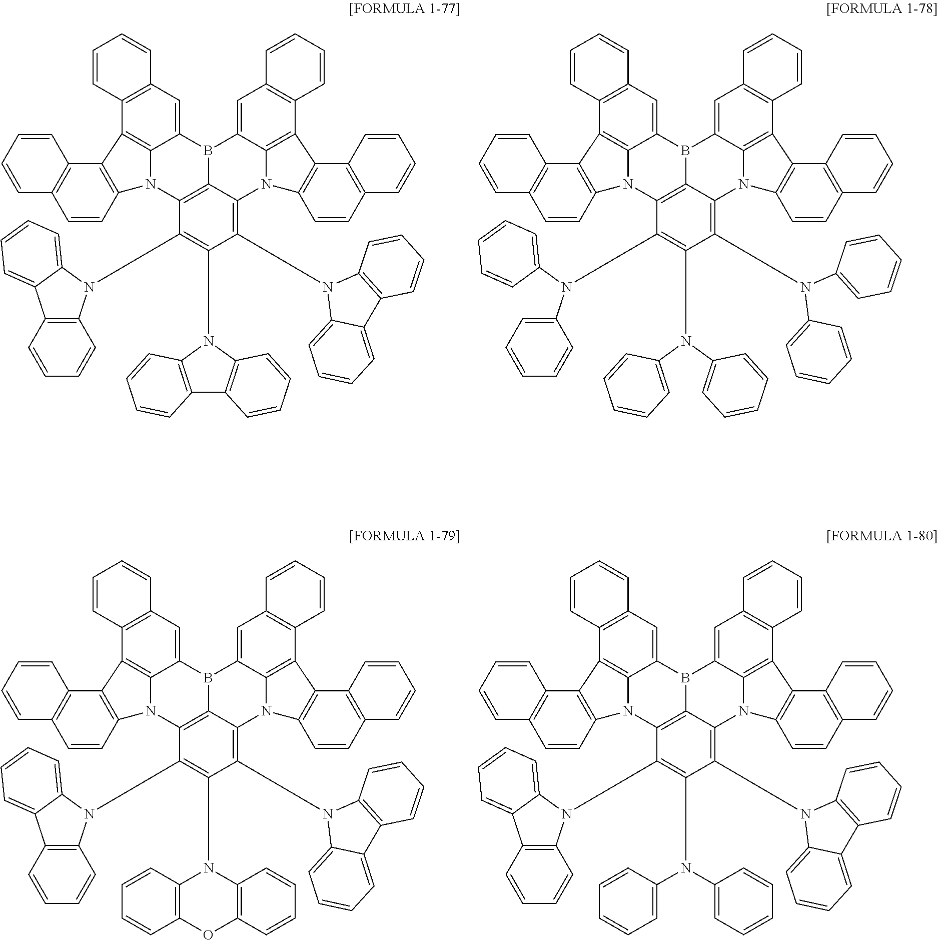

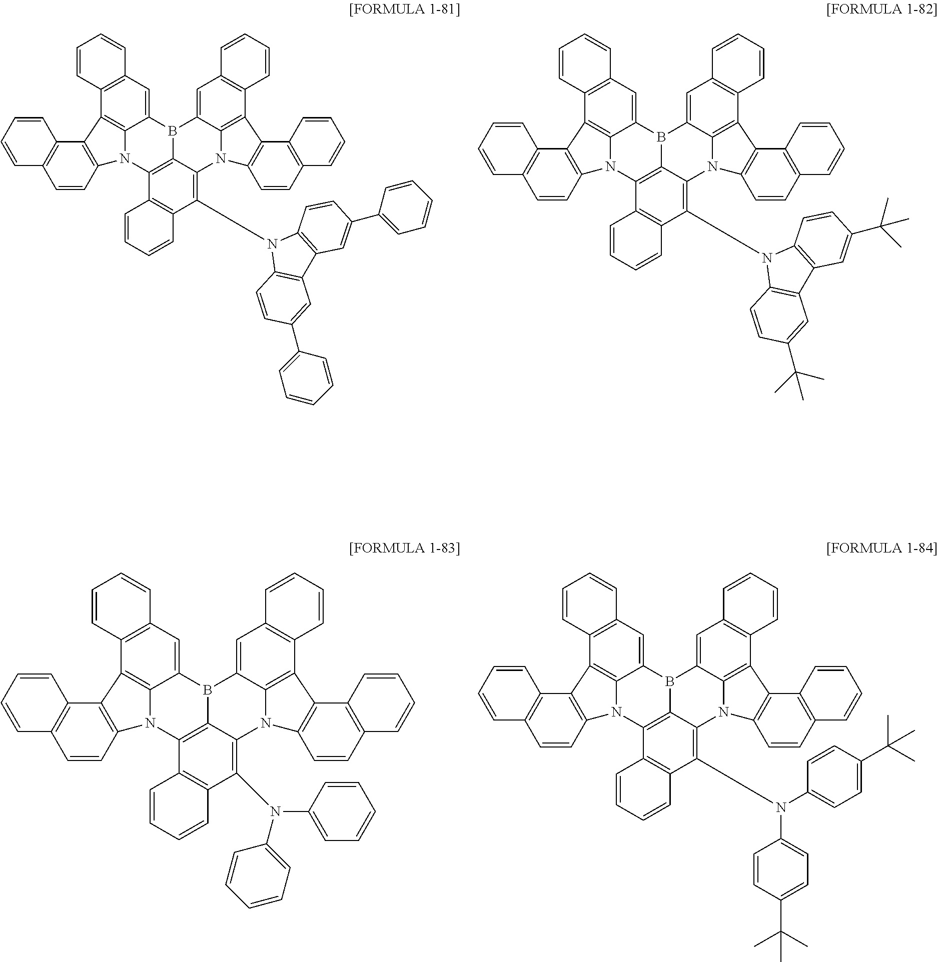

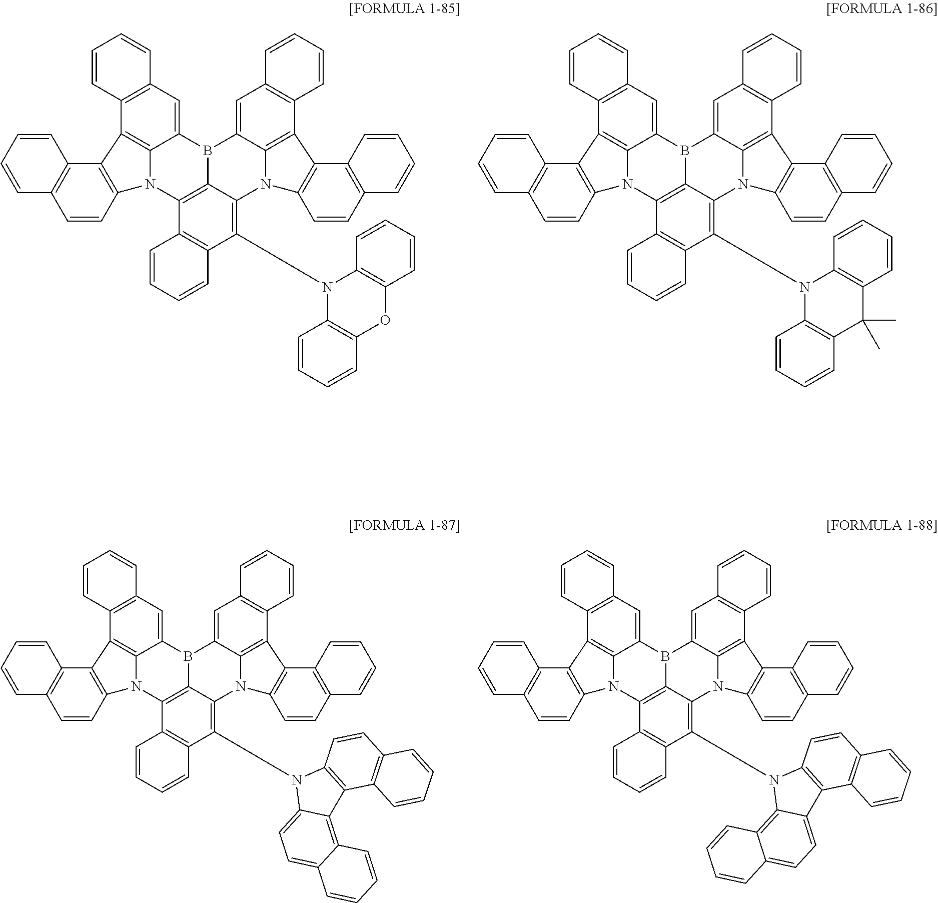 [SMILES: c1ccc2c(c1)Oc1ccccc1N2c1c2c3c(c4ccccc14)-n1c4ccc5ccccc5c4c4c5ccccc5cc(c41)B3c1cc3ccccc3c3c4c5ccccc5ccc4n-2c13 ; CC1(C)c2ccccc2N(c2c3c4c(c5ccccc25)-n2c5ccc6ccccc6c5c5c6ccccc6cc(c52)B4c2cc4ccccc4c4c5c6ccccc6ccc5n-3c24)c2ccccc21 ; c1ccc2c(c1)ccc1c2c2c3ccccc3ccc2n1-c1c2c3c(c4ccccc14)-n1c4ccc5ccccc5c4c4c5ccccc5cc(c41)B3c1cc3ccccc3c3c4c5ccccc5ccc4n-2c13 ; c1ccc2c(c1)ccc1c2c2c3ccccc3cc3c2n1-c1c2c(c4ccccc4c1-n1c4ccc5ccccc5c4c4ccc5ccccc5c41)-n1c4ccc5ccccc5c4c4c5ccccc5cc(c41)B23]

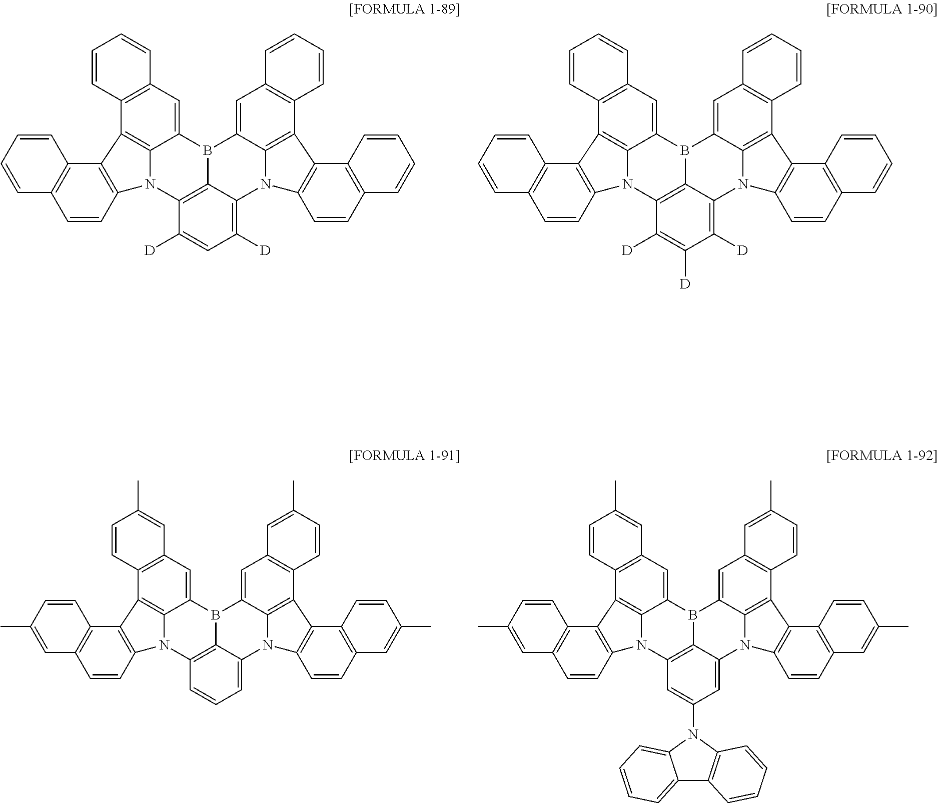

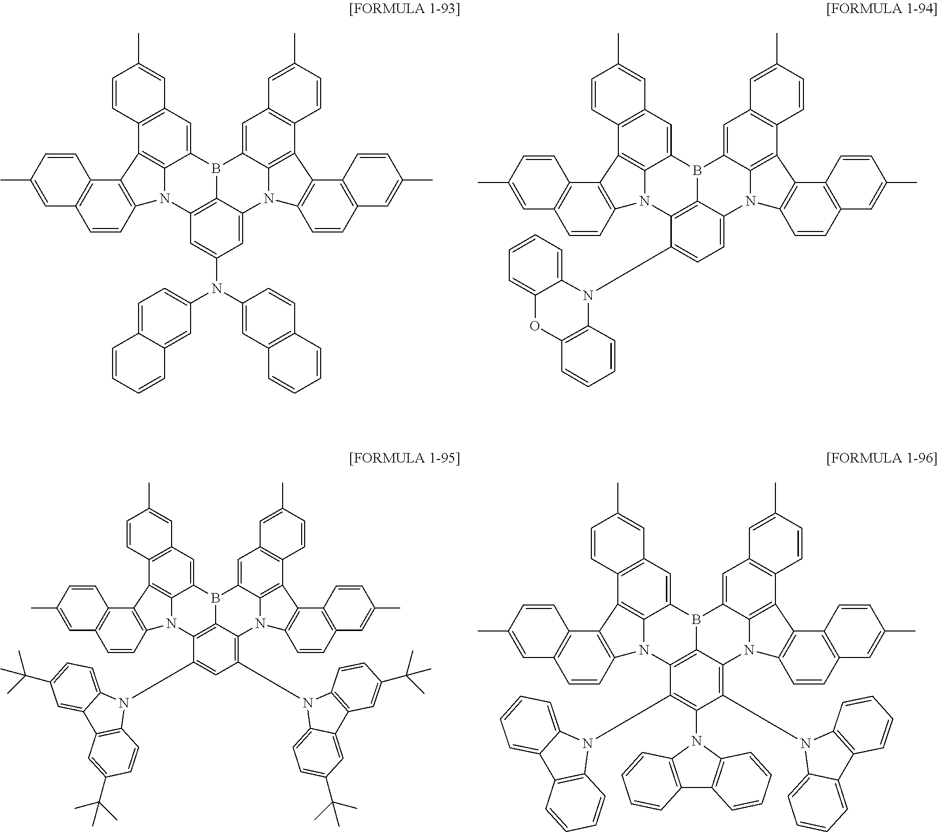

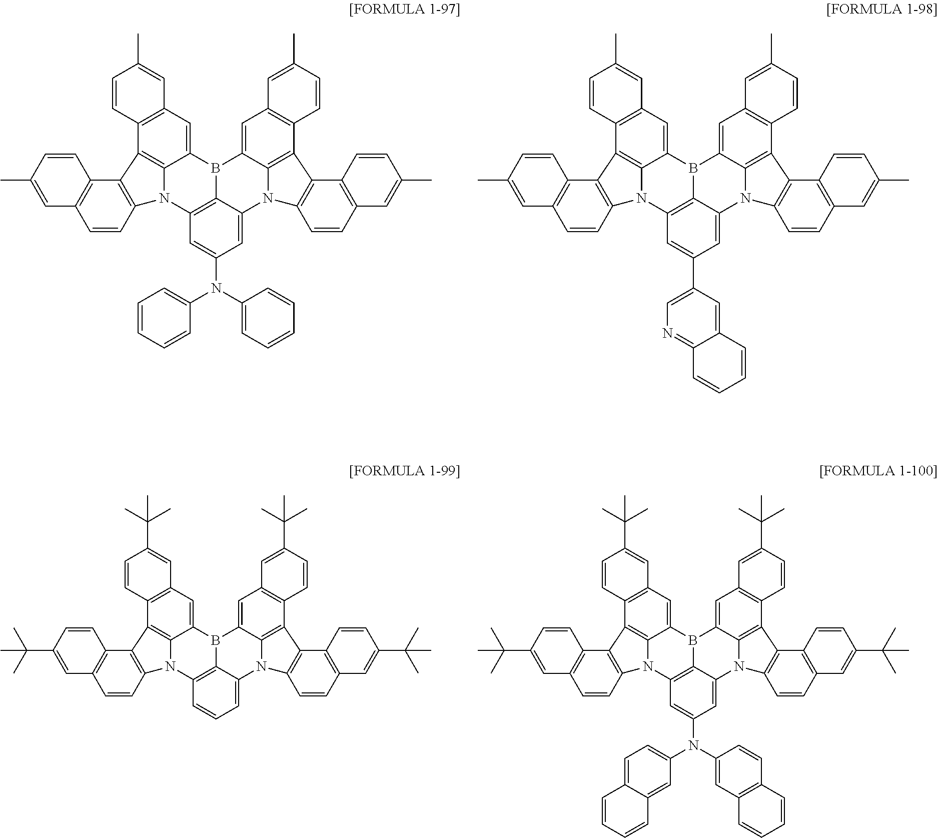

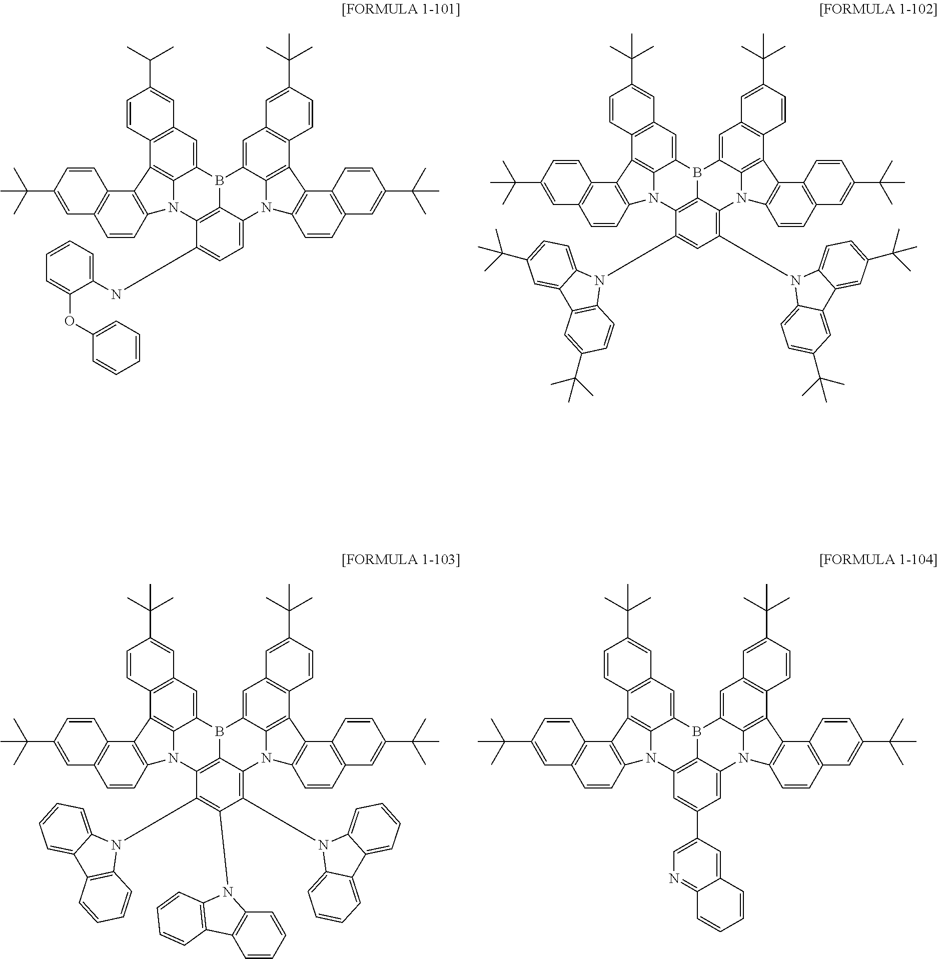

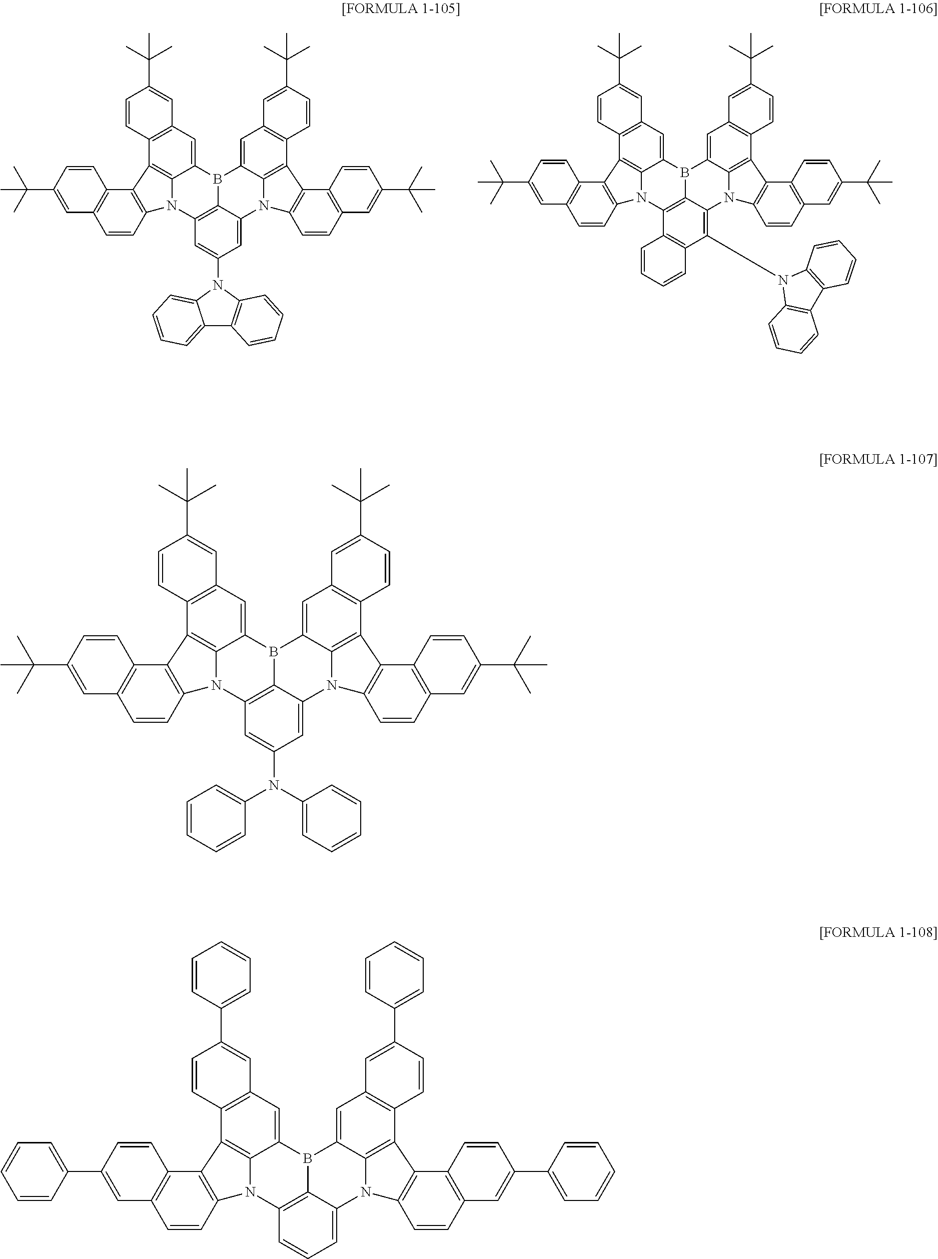

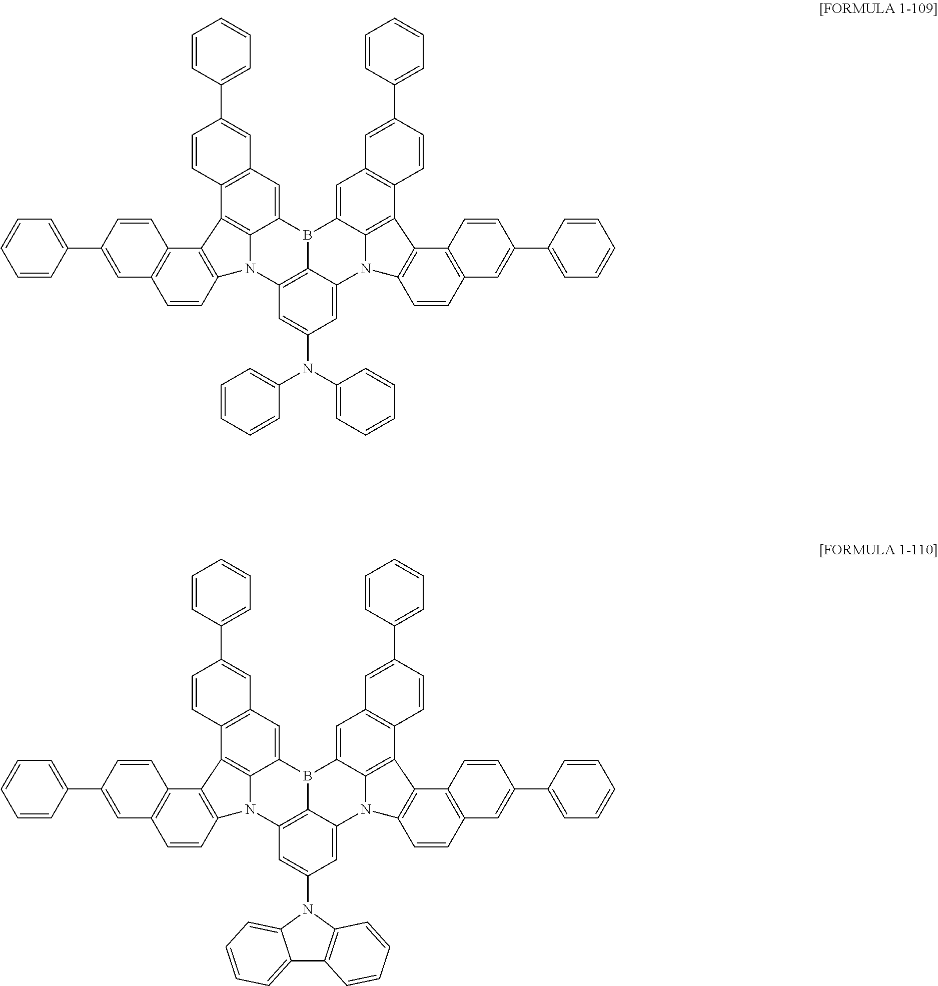 [SMILES: c1ccc(-c2ccc3c(ccc4c3c3c5ccc(-c6ccccc6)cc5cc5c3n4-c3cc(N(c4ccccc4)c4ccccc4)cc4c3B5c3cc5cc(-c6ccccc6)ccc5c5c6c7ccc(-c8ccccc8)cc7ccc6n-4c35)c2)cc1 ; c1ccc(-c2ccc3c(ccc4c3c3c5ccc(-c6ccccc6)cc5cc5c3n4-c3cc(-n4c6ccccc6c6ccccc64)cc4c3B5c3cc5cc(-c6ccccc6)ccc5c5c6c7ccc(-c8ccccc8)cc7ccc6n-4c35)c2)cc1]

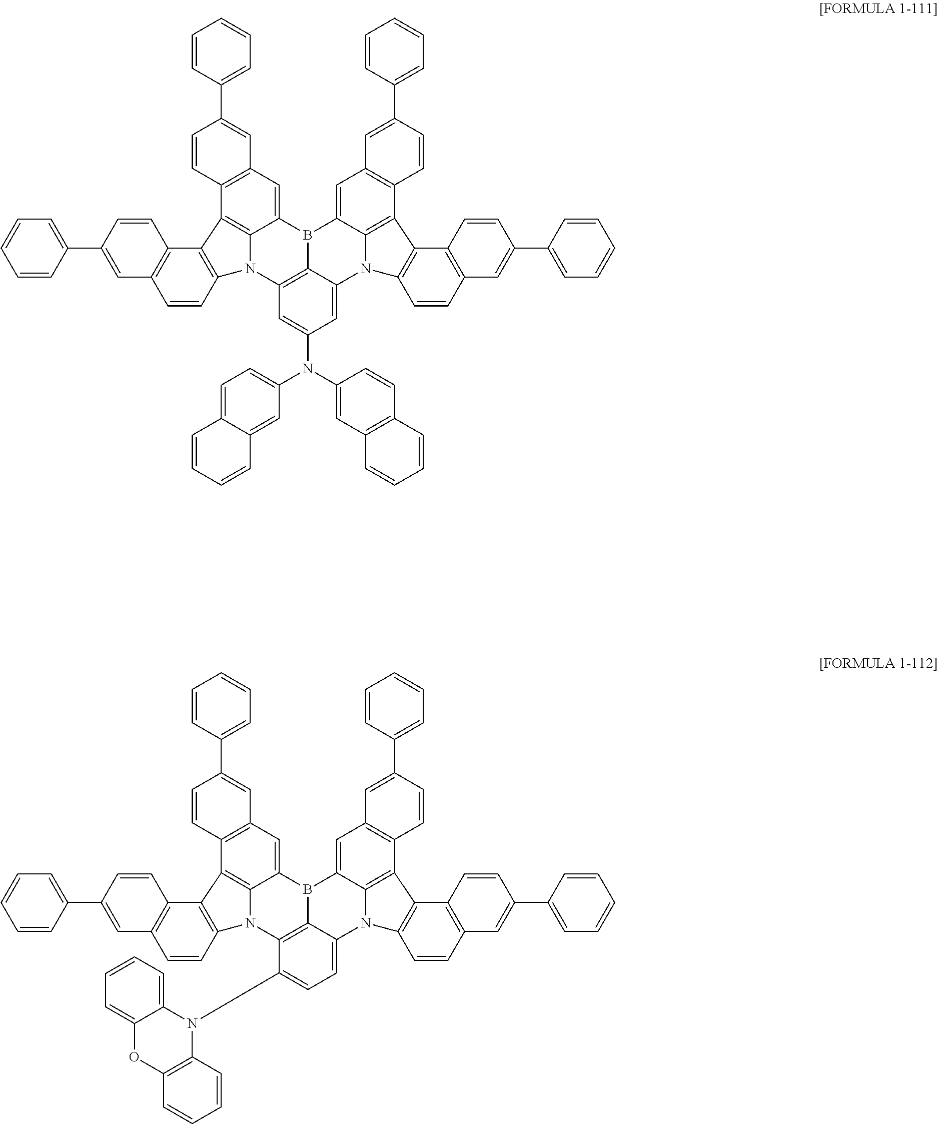 [SMILES: c1ccc(-c2ccc3c(ccc4c3c3c5ccc(-c6ccccc6)cc5cc5c3n4-c3cc(N(c4ccc6ccccc6c4)c4ccc6ccccc6c4)cc4c3B5c3cc5cc(-c6ccccc6)ccc5c5c6c7ccc(-c8ccccc8)cc7ccc6n-4c35)c2)cc1 ; c1ccc(-c2ccc3c(ccc4c3c3c5ccc(-c6ccccc6)cc5cc5c3n4-c3ccc(N4c6ccccc6Oc6ccccc64)c4c3B5c3cc5cc(-c6ccccc6)ccc5c5c6c7ccc(-c8ccccc8)cc7ccc6n-4c35)c2)cc1]

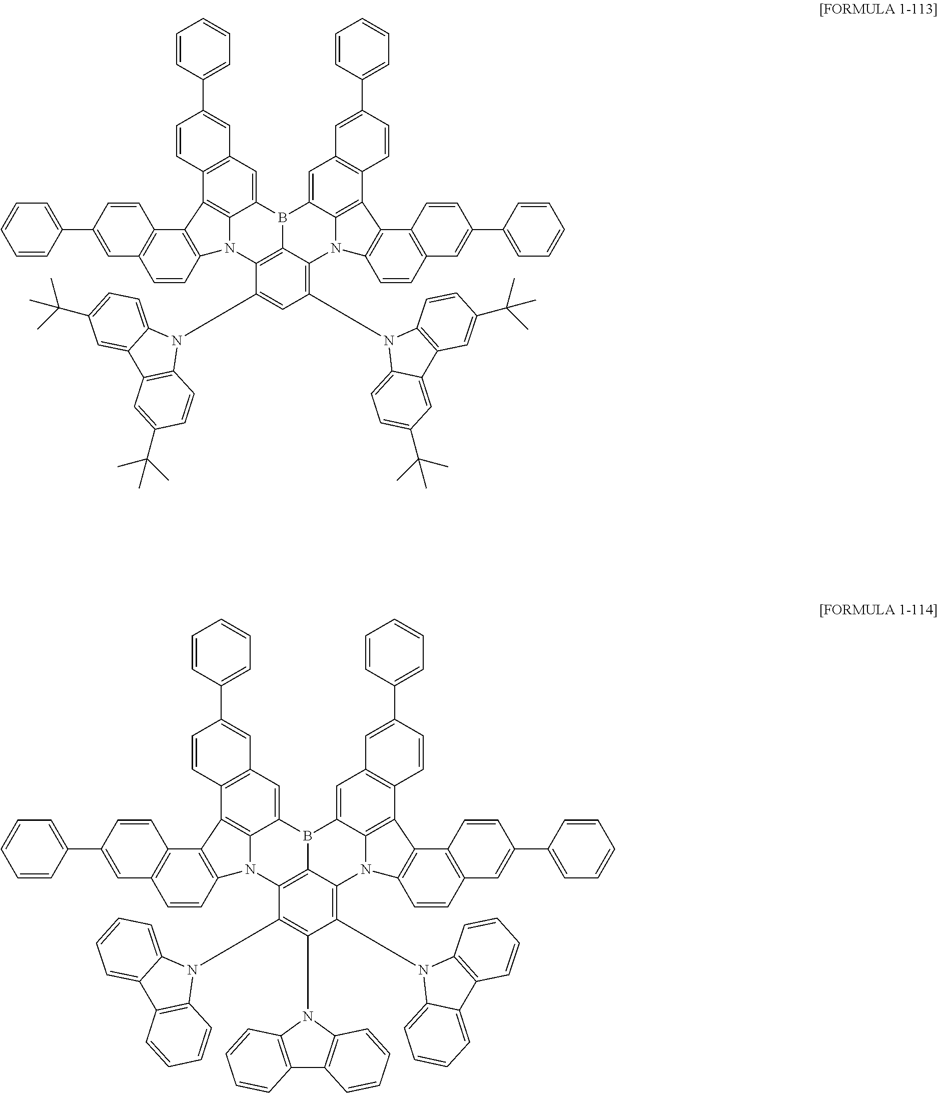 [SMILES: CC(C)(C)c1ccc2c(c1)c1cc(C(C)(C)C)ccc1n2-c1cc(-n2c3ccc(C(C)(C)C)cc3c3cc(C(C)(C)C)ccc32)c2c3c1-n1c4ccc5cc(-c6ccccc6)ccc5c4c4c5ccc(-c6ccccc6)cc5cc(c41)B3c1cc3cc(-c4ccccc4)ccc3c3c4c5ccc(-c6ccccc6)cc5ccc4n-2c13 ; c1ccc(-c2ccc3c(ccc4c3c3c5ccc(-c6ccccc6)cc5cc5c3n4-c3c4c(c(-n6c7ccccc7c7ccccc76)c(-n6c7ccccc7c7ccccc76)c3-n3c6ccccc6c6ccccc63)-n3c6ccc7cc(-c8ccccc8)ccc7c6c6c7ccc(-c8ccccc8)cc7cc(c63)B45)c2)cc1]

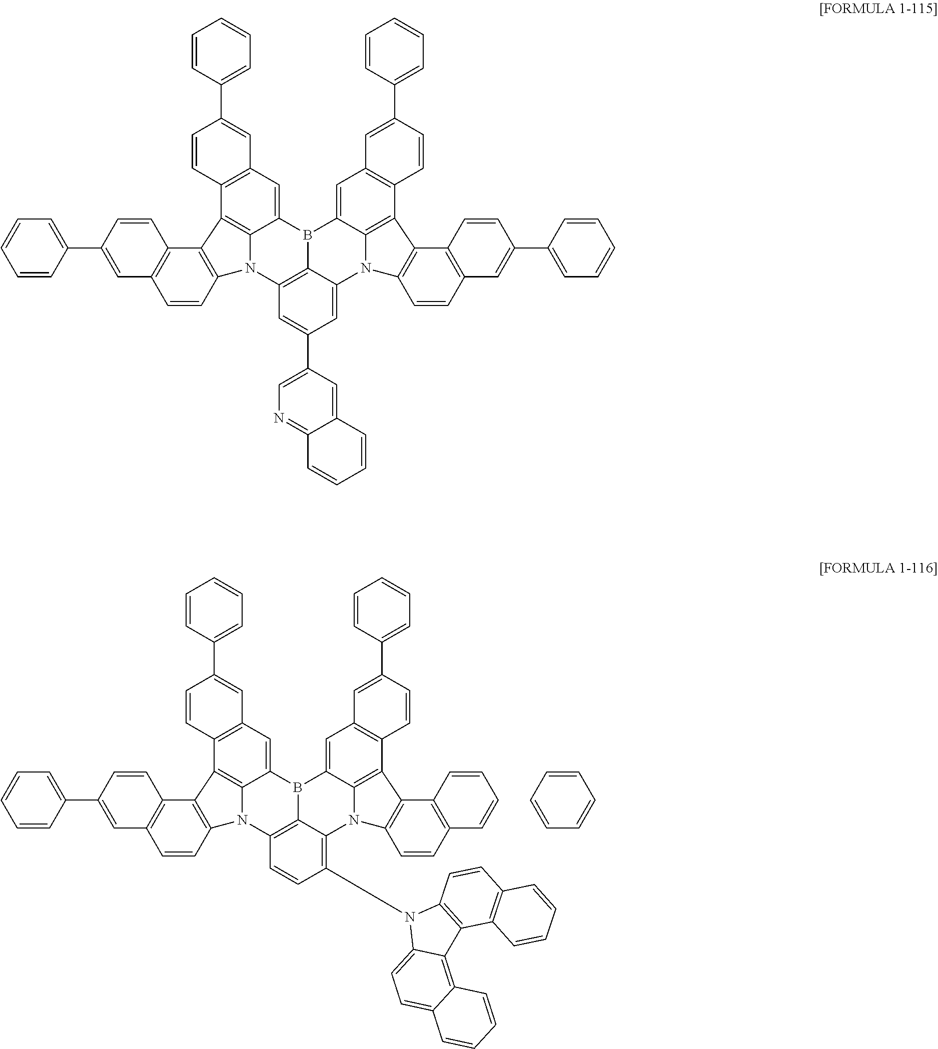

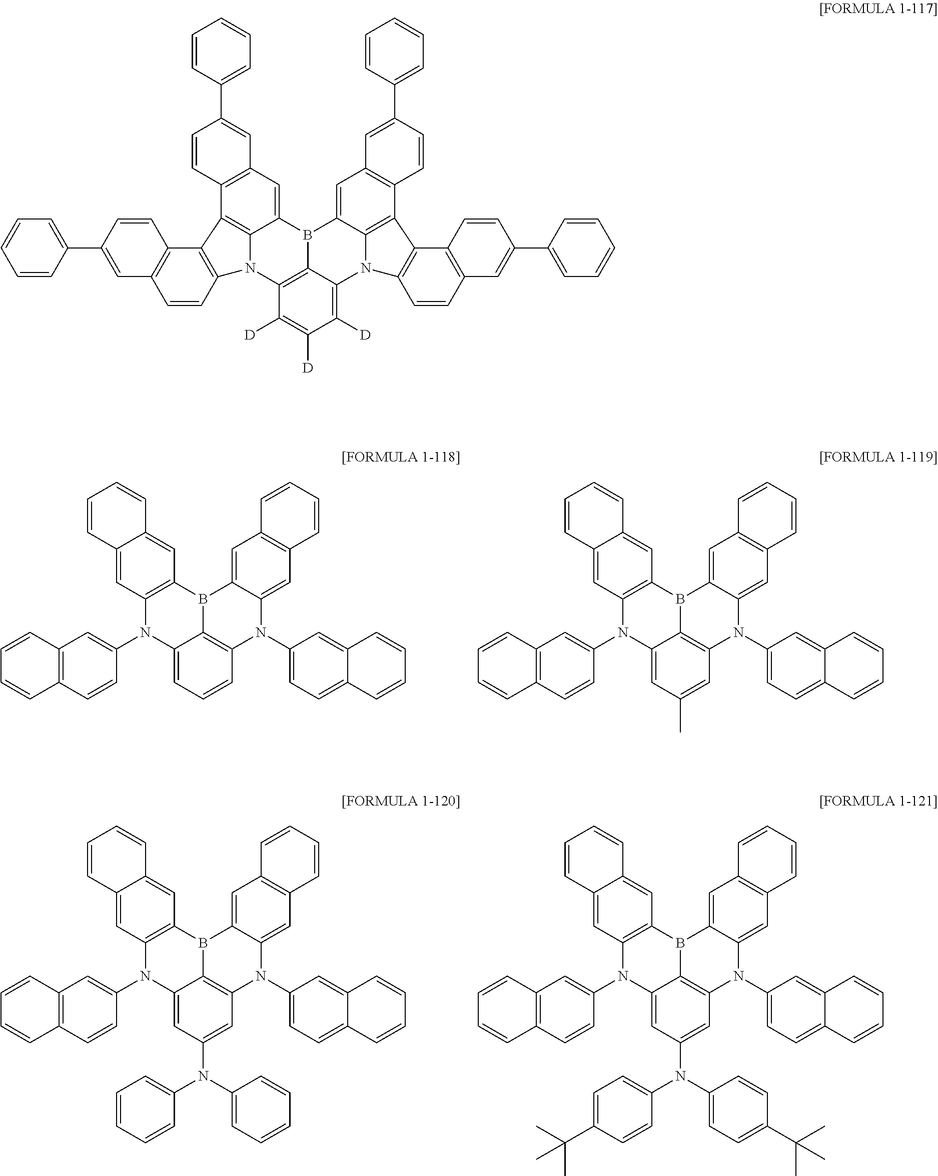

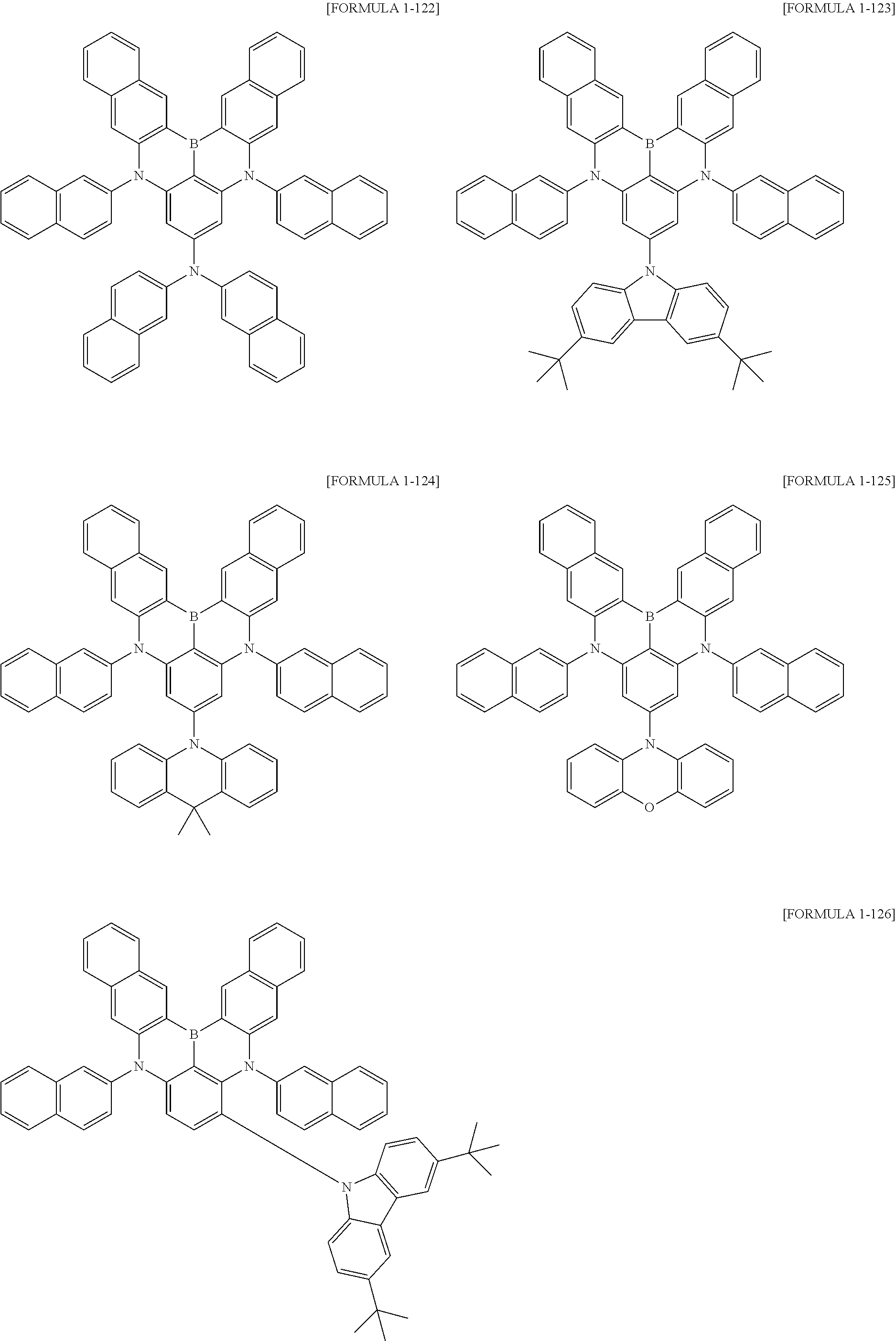

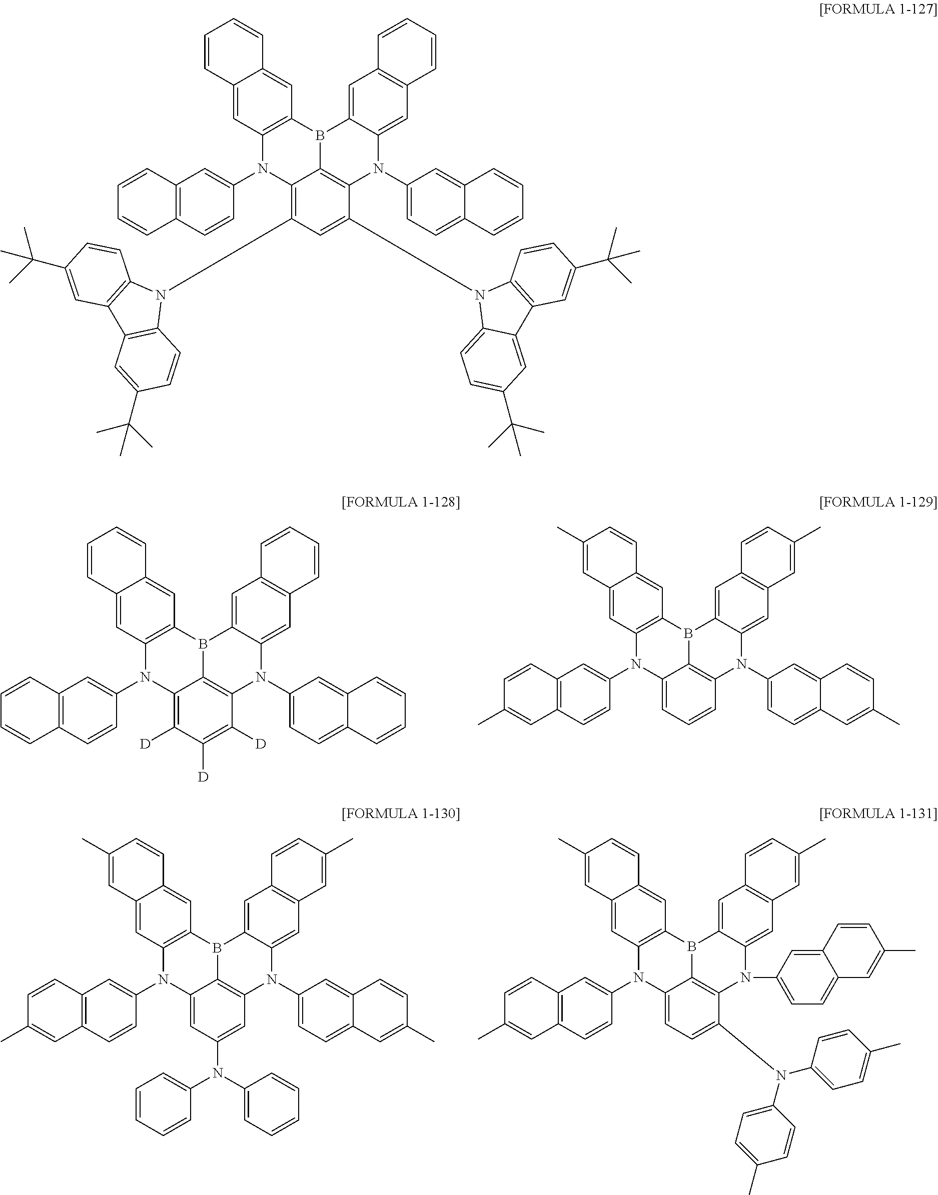

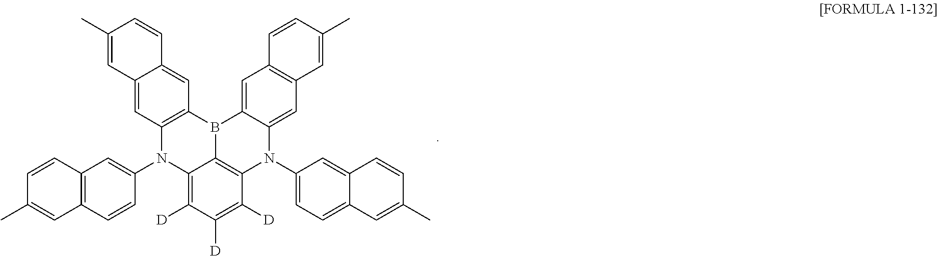

4. The boron compound according to claim 1, wherein an emission spectrum has a peak at 450 to 600 nm.

5. The boron compound according to claim 1, wherein a full width at half maximum of an emission spectrum is 40 nm or less.

6. The boron compound according to claim 1, wherein a photoluminescence quantum yield is 0.90 or more.

7. An organic light-emitting device, comprising:
a first electrode;
a second electrode provided to face the first electrode; and
one or more organic material layers interposed between the first electrode and the second electrode,
wherein at least one layer of the organic material layer comprises the boron compound according to claim 1.

8. The organic light-emitting device according to claim 7, wherein
the first electrode is an anode, the second electrode is a cathode, and the layer comprising the boron compound is a light-emitting layer, and
wherein the organic material layer further comprises:
a hole transport region interposed between the first electrode and the light-emitting layer and including at least one of a hole injection layer, a hole transport layer, and an electron blocking layer; and
an electron transport region interposed between the light-emitting layer and the second electrode and including at least one of a hole blocking layer, an electron transport layer, and an electron injection layer.

9. The organic light-emitting device according to claim 7, wherein the layer comprising the boron compound is a light-emitting layer, and
wherein the light-emitting layer further comprises:
one or more host compounds; and
a delayed fluorescent or phosphorescent compound.

10. An organic light-emitting device, comprising:
a first electrode;
a second electrode provided to face the first electrode; and
one or more organic material layers interposed between the first electrode and the second electrode,
wherein at least one layer of the organic material layer comprises the boron compound according to claim 2.

11. An organic light-emitting device, comprising:
a first electrode;
a second electrode provided to face the first electrode; and
one or more organic material layers interposed between the first electrode and the second electrode,
wherein at least one layer of the organic material layer comprises the boron compound according to claim 3.

12. An organic light-emitting device, comprising:
a first electrode;
a second electrode provided to face the first electrode; and
one or more organic material layers interposed between the first electrode and the second electrode,
wherein at least one layer of the organic material layer comprises the boron compound according to claim 4.

13. An organic light-emitting device, comprising:
a first electrode;
a second electrode provided to face the first electrode; and
one or more organic material layers interposed between the first electrode and the second electrode,
wherein at least one layer of the organic material layer comprises the boron compound according to claim 5.

14. An organic light-emitting device, comprising:
a first electrode;
a second electrode provided to face the first electrode; and
one or more organic material layers interposed between the first electrode and the second electrode,
wherein at least one layer of the organic material layer comprises the boron compound according to claim 6.
